(19) United States
(12) Patent Application Publication
(10) Pub. No.: US 2003/0087503 A1
(43) Pub. Date: May 8, 2003

(54) Process for production of semiconductor substrate

(75) Inventors: Kiyofumi Sakaguchi, Isehara-shi (JP); Takao Yonehara, Atsugi-shi (JP); Nobuhiko Sato, Yokohama-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/085,046

(22) Filed: Mar. 1, 2002

Related U.S. Application Data
(63) Continuation-in-part of application No. 09/161,775, filed on Sep. 29, 1998.
Application No. 09/161,775 is a division of application No. 08/863,717, filed on May 27, 1997, now Pat. No. 5,856,229.
Application No. 08/863,717 is a continuation of application No. 08/401,237, filed on Mar. 9, 1995, now abandoned.
(63) Continuation-in-part of application No. 09/734,667, filed on Dec. 13, 2000, now abandoned.
Application No. 09/734,667 is a division of application No. 09/212,432, filed on Dec. 16, 1998, now Pat. No. 6,246,068.
Application No. 09/212,432 is a division of application No. 08/729,722, filed on Oct. 7, 1996, now Pat. No. 5,854,123.
(63) Continuation-in-part of application No. 09/933,711, filed on Aug. 22, 2001, now abandoned.
Application No. 09/933,711 is a division of application No. 09/840,895, filed on Apr. 25, 2001, now Pat. No. 6,350,702.
Application No. 09/840,895 is a division of application No. 08/807,604, filed on Feb. 27, 1997, now Pat. No. 6,294,478.

(30) Foreign Application Priority Data
Mar. 10, 1994 (JP) 39389
Mar. 6, 1995 (JP) 45441
Oct. 6, 1995 (JP) 260100
Feb. 28, 1996 (JP) 41709
Oct. 4, 1996 (JP) 264386

(51) Int. Cl. H01L 21/76

(52) U.S. Cl. 438/406

(57) ABSTRACT

A method for making a thin film semiconductor. The method includes the steps of making a semiconductor substrate having one or more layers of different porosity, and subsequently separating the layers along a line of relative weakness. This method is particularly well adapted to manufacturing Silicon-on-Insulator (SOI) structures.

This application is a continuation-in-part of application Ser. No. 09/161,775 filed Sep. 29, 1998, pending, which was a division of application Ser. No. 08/863,717 filed May 27, 1997, now U.S. Pat. No. 5,856,229, which was a continuation of application Ser. No. 08/401,237 filed Mar. 9, 1995, abandoned. These applications also claim priority to Japanese patent applications 39389/94 and 45441/95 filed Mar. 10, 1994 and Mar. 6, 1995, respectively. This application is also a continuation-in-part of pending application Ser. No. 09/734,667 filed Dec. 13, 2000 which was a division of application Ser. No. 09/212,432, filed Dec. 16, 1998, now issued as U.S. Pat. No. 6,246,068, which was a division of application Ser. No. 08/729,722 filed Oct. 7, 1996, now U.S. Pat. No. 5,854,123. These applications claim priority to Japanese patent application 260100/95 filed Oct. 6, 1995.

This application is also a continuation-in-part of pending application Ser. No. 09/933,711, filed Aug. 22, 2001, which was a division of application Ser. No. 09/840,895 filed Apr. 25, 2001,now allowed, which was a division of application Ser. No. 08/807,604 filed Feb. 27, 1997, now issued as U.S. Pat. No. 6,294,478. These applications claim priority to Japanese application 41709/96 filed Feb. 28, 1996.

All the above applications and their disclosures are incorporated herein by reference.

### BACKGROUND OF THE INVENTION

1. Field of the Invention

The present invention relates to a process for producing a semiconductor substrate. More specifically, the present invention relates to a process for producing a monocrystalline semiconductor on a dielectric-isolated or insulative material, or a monocrystalline compound semiconductor on a semiconductor substrate. Further the present invention relates to a process for producing an electronic device or an integrated circuit formed on a single crystalline semiconductor layer.

The present invention relates to a semiconductor substrate and a producing method thereof. More specifically, the present invention relates to dielectric isolation or a producing method of a single-crystal semiconductor on an insulator and a single-crystal compound semiconductor on a Si substrate, and further relates to a method of producing a semiconductor substrate suitable for an electronic device or an integrated circuit formed at a single-crystal semiconductor layer.

The present invention relates to a fabrication process for a semiconductor substrate and, more particularly, to a process for fabricating a single-crystal semiconductor on a dielectric isolation or an insulator and a single-crystal compound semiconductor on a Si substrate and further to a process for fabricating a semiconductor substrate suitable for electronic devices and integrated circuits made in a single-crystal semiconductor layer.

2. Related Background Art

The technique of formation of monocrystalline Si (silicon) semiconductor on an insulative material is well known as silicon-on-insulator (SOI) technique. A device prepared by the SOI technique has various advantages which are not achievable by a bulk Si substrate in usual Si integrated circuits, as noted below:

1. Ease of dielectric isolation, and possibility of high degree of integration;

2. High resistance against radioactive ray;

3. Low floating capacity, and the possibility of high speed operation;

4. The welling process is unnecessary;

5. Preventability of latch-up; and

6. Possibility of producing a complete depletion type field-effect transistor to name a few.

The process of forming the SOI structure has been actively studied for several decades. The results of the studies are summarized, for example, in the paper: Special Issue; “Single-crystal silicon on non-single-crystal insulators”; edited by G. W. Cullen, Journal of Crystal Growth; Vol. 63, No.3, pp.429-590 (1983).

SOS (silicon on sapphire) is known and is produced by heteroepitaxial growth of silicon on monocrystalline sapphire by CVD (chemical vapor deposition). The SOS technique, which is successful as one of SOI techniques, is limited in its application, because of many crystal defects caused by mismatch of the lattice at the interface between the Si layer and the underlying sapphire, contamination of the Si layer with aluminum from the sapphire substrate, expense of the substrate, and the difficulty of large-area substrate formation.

Recently, studies are being made to produce the SOI structure without using a sapphire substrate. The studies are classified roughly into the two processes below:

1. A first process which includes surface oxidation of a monocrystalline Si substrate, local exposure of the Si substrate by opening a window, and epitaxial growth of Si laterally from the exposed portion as the seed to form an Si layer on SiO₂. (Si layer deposition on SiO₂.)

2. A second process including SiO₂ formation beneath a monocrystalline SiO₂ substrate, utilizing the SiO₂ substrate as the active layer. (No Si layer deposition.)

The device formed on a compound semiconductor exhibits performances, such as high speed, and luminescence, which are not achievable by Si. Such types of devices are formed by epitaxial growth on a compound semiconductor substrate such as GaAs. The compound semiconductor substrate, however, has disadvantages of high cost, low mechanical strength, and difficulty in the formation of a large-area wafer. Accordingly, heteroepitaxial growth of a compound semiconductor on an Si wafer is being studied to attain low cost, high mechanical strength, and ease of production of a large-area wafer.

The above-known process 1 (Si layer deposition on SiO₂) includes methods of direct lateral epitaxial growth of monocrystalline Si layer by CVD; deposition of amorphous Si and subsequent heat treatment to cause solid-phase lateral epitaxial growth; melting recrystallization to grow monocrystalline layer on an SiO₂ by irradiation of amorphous or polycrystalline Si layer with a focused energy beam such as an electron beam and laser beam; and a zone melting recrystallization in which a bar-shaped heater is moved to scan with a belt-like melt zone. These methods respectively have advantages and disadvantages, involving problems in process controllability, productivity, product uniformity, and product quality, and are not industrialized yet. For example, the CVD method requires sacrificial oxidation, giving low crystallinity in the solid-phase growth. The beam annealing method involves problems in processing time of focused beam scanning and in controllability of beam superposition and focusing. of the above methods, the zone melting recrystallization is the most advanced method, and is employed in relatively large scale integrated circuits. This method, however, still causes crystal defects in subgrain boundaries, and is not successful in the production of a minority carrier device.

The above known process 2 in which the Si substrate is not utilized as the seed for epitaxial growth includes the four methods below:

1. An oxidation film is formed on a monocrystalline Si substrate which has V-shaped grooves on the surface formed by anisotropical etching; a polycrystalline Si layer is deposited in a thickness approximate to that of the Si substrate on the oxidation film; and the back face of the Si substrate is ground to form a monocrystalline Si region isolated dielectrically by surrounding with the V-shaped grooves. This method involves problems in controllability and productivity in deposition of polycrystalline Si in a thickness of as large as several hundred microns, and in removal of the monocrystalline Si substrate by grinding at the back face to leave an isolated active Si layer only.

2. An SiO₂ layer is formed by ion implantation into a monocrystalline Si substrate (SIMOX: Separation by ion implanted oxygen). This is the most highly advanced method in view of the matching with the Si process. This method, however, requires implantation of oxygen ions in an amount of as much as 10¹⁸ ions/cm², which takes a long time, resulting in low productivity and high wafer cost. Further, the product has many remaining crystal defects; and does not have satisfactory properties for the industrial production of a minority carrier device.

3. An SOI structure is formed by oxidation of porous Si for dielectric isolation. In this method, an N-type Si layer is formed in an island-like pattern on a P-type monocrystalline Si substrate surface by proton ion implantation (Imai, et al.: J. Crystal Growth, Vol. 63, p. 547 (1983)) or by epitaxial growth and patterning, and subsequently only the P-type Si substrate is made porous by anodic oxidation in an HF solution to surround the island-patterned N-type Si, and the N-type Si island is dielectrically isolated by accelerated oxidation. In this method, the isolated Si regions are fixed prior to the device process, which may limit the freedom of device design disadvantageously.

4. Different from the above conventional SOI formation, a method has recently come to be noticed in which a monocrystalline Si substrate is bonded to another thermally oxidized monocrystalline Si substrate by heat treatment or use of an adhesive to form an SOI structure. This method requires uniform thinness of the active layer for the device: namely, formation of a film of a micron thick or thinner from a monocrystalline substrate of several hundred microns thick. This thin film may be formed by either of the two methods below.

1. Thin film formation by grinding; and

2. Thin film formation by selective etching.

The grinding method does not readily give a uniform thin film. In particular, formation of a film of submicron thickness results in thickness variation of tens of percent. This irregularity is a serious problem. With a larger diameter of the wafer, the uniformity of the thickness is much more difficult to attain.

The etching method is regarded to be effective for uniform thin film formation. This method, however, involves the problems of insufficient selectivity of about 10² at the highest, inferior surface properties after etching, and low crystallinity of the SOI layer because of the employed ion implantation, epitaxial or heteroepitaxial growth on a high-concentration B-doped Si layer. (C. Harendt, et al.: J. Elect. Mater., Vol. 20, p. 267 (1991); H. Baumgart, et al.: Extended Abstract of ECS 1st International Symposium of Wafer Bonding, pp. 733 (1991); and C. E. Hunt: Extended Abstract of ECS 1 st International Symposium of Wafer Bonding, pp. 696(1991))

The semiconductor substrate which is prepared by lamination requires two wafers essentially, and a major part of one of the wafers is discarded by grinding or etching, thereby wasting the resource. Therefore, the SOI prepared by lamination involves many problems in controllability, uniformity, production cost, and so forth in conventional processes.

A thin Si layer deposited on a light-transmissive substrate typified by a glass plate becomes amorphous or polycrystalline owing to disorder of crystallinity of the substrate, not giving high performance of the device. Simple deposition of Si does not give desired quality of single crystal layer owing to the amorphous crystal structure of the substrate.

The light-transmissive substrate is essential for construction of a light-receiving element such as a contact sensor, and projection type of liquid crystal image-displaying apparatus. Additionally, a driving element of high performance is necessary for higher density, higher resolution, and higher precision of the sensor and of the image elements of the display. Consequently, the element provided on a light transmissive substrate is also required to have a monocrystalline layer of high crystallinity.

Amorphous Si or polycrystalline Si will not give a driving element having the required sufficient performance because of the many defects in the crystal structure.

As mentioned above, a compound semiconductor device requires essentially a compound semiconductor substrate. The compound semiconductor substrate, however, is expensive, and is not readily formed in a larger size.

Epitaxial growth of a compound semiconductor such as GaAs on an Si substrate gives a grown film of poor crystallinity owing to the difference in the lattice constants and the thermal expansion coefficients, thereby the resulting grown film being unsuitable for use for a device.

Epitaxial growth of a compound semiconductor on porous Si is intended for mitigation of mismatch of the lattices. However, the substrate does not have sufficient stability and reliability owing to the low thermal stability and long-term deterioration of the porous Si.

In view of the above-mentioned problems, Takao Yonehara, one of the inventors of the present invention, disclosed formerly a novel process for preparing a semiconductor member in European Patent Publication No. 0469630A2. This process comprises the steps of forming a member having a nonporous monocrystalline semiconductor region on a porous monocrystalline semiconductor region; bonding the surface of a member of which the surface is constituted of an insulating substance onto the surface of the nonporous monocrystalline semiconductor region; and then removing the porous monocrystalline semiconductor region by etching. This process is satisfactory for solving the above-mentioned problems. Further improvement of the disclosed process for higher productivity and lower production cost will contribute greatly to the industries concerned.

Formation of a single-crystal Si semiconductor layer on an insulator is widely known as a silicon on insulator SOI. This technique has been extensively researched since a device utilizing the SOI technique has a number of advantages which cannot be achieved by a bulk Si substrate forming the normal Si integrated circuit. Specifically, for example, the following advantages can be achieved by employing the SOI technique:

1. Dielectric isolation is easy and high integration is possible;

2. Radiation resistance is excellent;

3. Floating capacitance is reduced and high speed is possible;

4. Well process can be prevented;

5. Latch-up can be prevented; and

6. Fully depleted (FD) field effect transistor is achieved through film thickness reduction.

These are described in detail, for example, in the literature of Special Issue: “Single-crystal silicon on non-single-crystal insulators”; edited by G. W. Cullen, Journal of Crystal Growth, volume 63, no. 3, pp. 429-590 (1983).

Further, over the past few years, the SOI has been largely reported as a substrate which realizes the acceleration of a MOSFET and low power consumption (IEEE SOI conference 1994). Since an element has an insulating layer at its lower part when employing the SOI structure, an element separation process can be simplified as compared with forming an element on a bulk silicon wafer so that preparing a device can take less time. Specifically, in addition to achieving the higher performance, reduction of the wafer cost and the process cost is expected as compared with a MOSFET or IC on bulk silicon.

Particularly, the fully depleted (FD) MOSFET is expected to achieve higher speed and lower power consumption through improvement in driving force. In general, a threshold voltage (Vth) of a MOSFET is determined by the impurity concentration at a channel portion. On the other hand, in case of the FD MOSFET using the SOI, a depletion layer is also subjected to an influence of a film thickness of the SOI. Thus, for producing the large scale integrated circuits at high yield, uniformity of the SOI thicknesses has been strongly demanded.

On the other hand, a device on a compound semiconductor has high performance, such as high speed and luminescence, which cannot be achieved by Si. Presently, such a device is normally formed in an epitaxial layer grown on a compound semiconductor substrate, such as a GaAs substrate.

However, there is a problem that the compound semiconductor substrate is expensive while low in mechanical strength, so that a large area wafer is difficult to produce.

Under these circumstances, an attempt has been made to achieve the heteroepitaxial growth of a compound semiconductor on a Si wafer which is inexpensive and high in mechanical strength so that a large area wafer can be produced.

Referring back to the SOI, research on the formation of the SOI substrates has been active since the 1970s. In the beginning, the research was performed in connection with the SOS (sapphire on silicon) method, which achieves the heteroepitaxial growth of single-crystal silicon on a sapphire substrate being an insulator, the FIPOS (fully isolated by porous oxidized silicon) method, which forms the SOI structure by dielectric isolation based on oxidation of porous Si, and the oxygen ion implantation method.

In the FIPOS method, an n-type Si layer is formed on a surface of a p-type Si single-crystal substrate in an island shape through the proton ion implantation (Imai and collaborator, J. Crystal Growth, vol. 63, 547 (1983)) or through the epitaxial growth and the patterning, then only the p-type Si substrate is rendered porous so as to surround the Si island from the surface by means of the anodizing method in a HF solution, and thereafter the n-type Si island is dielectric-isolated through accelerating oxidation. In this method, there is a problem that the isolated Si region is determined in advance of the prepared device so that the degree of freedom of device designing is limited.

The oxygen ion implantation method is a method called SIMOX first reported by K. Izumi. After implanting about 10¹⁷ to 10¹⁸/cm² of oxygen ions into a Si wafer, the ion-implanted Si wafer is annealed at the high temperature of about 1,320° C. in the atmosphere of argon/oxygen. As a result, oxygen ions implanted with respect to a depth corresponding to a projection range (Rp) of ion implantation are bonded with silicon so as to form a silicon oxide layer. On this occasion, a silicon layer which has been rendered amorphous at an upper portion of the silicon oxide layer due to the oxygen ion implantation is also recrystallized so as to be a single-crystal silicon layer. Conventionally, there have been a lot of defects included in the silicon layer on the surface, that is, about 10⁵/cm². On the other hand, by setting an implantation amount of oxygen to about 4×10¹⁷/cm², defects are successfully reduced to about 10²/cm². However, since the ranges of implantation energy and implantation amount for maintaining the quality of the silicon oxide layer, the crystalline property of the surface silicon layer and the like are so narrow that thicknesses of the surface silicon layer and the buried silicon oxide (BOX: buried oxide) layer were limited to particular values. For achieving a desired thickness of the surface silicon layer, it was necessary to perform sacrificial oxidation and epitaxial growth. In this case, there is a problem that, since the degradation caused through these processes is superimposed on the distribution of thicknesses, the thickness uniformity deteriorates.

It has been reported that a formation failure region of silicon oxide called a pipe exists in the BOX layer. As one cause of this, the forcing matter upon implantation, such as dust, is considered. In the portion where the pipe exists, the deterioration of the device characteristic results from leaks between an active layer and a support substrate.

Further, since the amount of ion implantation in the SIMOX is large as compared with the ion implantation in the ordinary semiconductor process, implantation time is lengthy even after developing the apparatus to be used exclusively for that process. The ion implantation is performed by raster-scanning an ion beam of a given current amount or expanding the beam so that an increment of the implantation time is predicted following an increment in the area of the wafer. Further, in the high temperature heat treatment of the large-area wafer, it has been pointed out that a problem of occurrence of slip due to the temperature distribution in the wafer becomes more severe. In SIMOX, the heat treatment is essential at high temperature, that is, 1,320° C., which is not normally used in silicon semiconductor processes, so that there has been concern that this problem, including the development of the apparatus, becomes more significant.

On the other hand, apart from the foregoing conventional SOI forming method, attention has been recently given to the method which forms the SOI structure by sticking a Si single-crystal substrate to a thermal-oxidized Si single-crystal substrate through heat treatment or using adhesives. In this method, it is necessary to form an active layer for the device into a uniform film. Specifically, it is necessary to form a Si single-crystal substrate of a thickness of as much as hundreds of microns into a film of several microns or less. There are three kinds of methods for thickness reduction as follows:

1. Thickness reduction through polishing;

2. Thickness reduction through local plasma etching;

3. Thickness reduction through selective etching.

In polishing, uniform thickness reduction is difficult. Particularly, in the case of thickness reduction to submicrons, the irregularity amounts to as much as tens of percents so that uniformity is a big problem. If the size of the wafer is further enlarged, the difficulty is increased correspondingly.

In the second method, after reducing the thickness to about 1 to 3 μm through polishing, the thickness distribution is measured at many points. Thereafter, by scanning the plasma using the SF6 of a diameter of several millimeters based on the thickness distribution, etching is performed while correcting the thickness distribution, to reduce the thickness to a given value. In this method, it has been reported that the thickness distribution can be within the range of about ±10 nm. However, if foreign matter (particles) exists on the substrate upon plasma etching, the foreign matter works as an etching mask so that projections are formed on the substrate.

Since the surface is rough immediately after the etching, touch polishing is necessary after completion of the plasma etching. The polishing amount is controlled based on time management, and hence, the control of final film thickness and the deterioration of film thickness distribution due to polishing have been noted. Further, in polishing, abrasives such as colloidal silica directly rub the surface working as an active layer so that there has been concern about formation of a fracture layer due to polishing and introduction of processing distortion. Further, if the wafer is substantially increased in area, since the plasma etching time is increased in proportion to increment of the wafer area, there is concern about extreme reduction of the throughput.

In the third method, a film structure capable of selective etching is formed in advance in a substrate to be formed into a film. For example a p+-Si thin layer containing boron in the concentration no less than 10¹⁹/cm³ and a p⁻-Si thin layer are formed on a p⁻ substrate using the method of, for example, the epitaxial growth to form a first substrate. The first substrate is bonded with a second substrate via an insulating layer such as an oxide film, and then the underside of the first substrate is ground or polished in advance so as to reduce its thickness. Thereafter, the p⁺ layer is exposed through the selective etching of the p⁻ layer and further the p⁻ layer is exposed through the selective etching of the p⁺ layer, so as to achieve the SOI structure. This method is detailed in the report of Maszara.

Although the selective etching is said to be effective for uniform thickness reduction, it has the following problems:

The ratio of etching selectively is 10² at most, which is not sufficient.

Since surface property after etching is bad, touch polishing is required after etching. However, as a result, the film thickness is reduced and the thickness uniformity tends to deteriorate. Particularly, although the amount of polishing is managed based on time, since dispersion of the polish speed is large, the control of the amount of polishing is difficult. Thus, it becomes a problem particularly in forming an extremely thin SOI layer of, for example, 100 nm.

The crystalline property is bad because of using the ion implantation, the epitaxial growth or the heteroepitaxial growth on the high-concentration B doped Si layer.

The surface property of a surface to be bonded which is inferior to the normal silicon wafer (C. Harendt, et al., J. Elect. Mater. Vol. 20, 267 (1991), H. Baumgart, et al., Extended Abstract of ECS 1st International Symposium of Wafer Bonding, pp. 733 (1991), C. E. Hunt, Extended Abstract of ECS 1st International Symposium of Wafer Bonding, pp. 696 (1991)). Further, the selectivity of selective etching largely depends upon a difference in concentration of impurities such as boron and sharpness of the profile in the depth direction. Accordingly, if the high-temperature bonding annealing for increasing the bonding strength or the high temperature epitaxial growth for improving the crystalline property is performed, the depth direction distribution of the impurity concentration expands so that the selectivity of etching deteriorates. That is, it is difficult to improve both the ratio of etching selectively and the crystalline property or the bonding strength.

Recently, in view of the foregoing problems, Yonehara and collaborators have reported the bonded SOI which is excellent in thickness uniformity and crystalline property and capable of batch processing. Brief explanation about this will be given using FIGS. 33A to 33E. In this method, a porous layer 162 formed on an Si substrate 161 is used as a material for selective etching (FIG. 33A). After epitaxially growing a nonporous single-crystal Si layer 163 on the porous layer 162 (FIG. 33B), the three-layer composite is bonded with a support substrate 164 via the oxidized Si layer 163 (FIG. 33C). The Si substrate 161 is reduced in thickness through grinding or the like from the underside so as to expose the porous Si 162 all over the substrate. (FIG. 33D). The exposed porous Si 162 is removed through etching using a selective etching liquid, such as KOH or HF+H₂O₂ (FIG. 33E). At this time, since the ratio of etching selectively porous Si relative to bulk Si (nonporous single-crystal silicon) can be set fully high, that is, 100,000 times, the non-porous single-crystal silicon layer grown on the porous layer in advance can be left on the support substrate without being hardly reduced in thickness, so as to form the SO substrate. Accordingly, the thickness uniformity of the SOI is substantially determined during the epitaxial growth. Since a CVD apparatus used in the normal semiconductor process can be used for the epitaxial growth, according to the report of Sato and collaborator, the thickness uniformity is realized, for example, within 100 nm±2%. Further, the crystalline property of the epitaxial silicon layer is also excellent and has been reported to be 3.5×10²/cm².

In the conventional method, since the selectivity of etching depends on the difference in impurity concentration and the depth direction profile, the temperature of the heat treatment (bonding, epitaxial growth, oxidation or the like) which expands the concentration distribution is largely limited to approximately no higher than 800° C. On the other hand, in the etching of this method, since the difference in structure between porous and bulk determines the etching speed, the limitation of the heat treatment temperature is small. It has been reported that the heat treatment at about 1,180° C. is possible. For example, it is known that the heat treatment after bonding enhances the bonding strength between the wafers and reduces the number and size of voids generated at the bonded interface. Further, in the etching based on such a structural difference, the particles, even if adhered on porous silicon, do not affect the thickness uniformity.

On the other hand, in general, on a light transmittable substrate, typically glass, the deposited thin Si layer only becomes amorphous or polycrystalline at best, reflecting disorder in crystal structure of the substrate, so that the high-performance device cannot be produced. This is due to the crystal structure of the substrate being amorphous, and thus an excellent single-crystal layer cannot be achieved even by merely depositing the Si layer.

However, the semiconductor substrate obtained through bonding normally requires two wafers one of which is removed, wastefully for the most part, through polishing, etching or the like, so that the finite resources of the earth are wasted.

Accordingly, in the conventional method, the bonded SOI has various problems of controllability, uniformity and economics.

Formation of a single-crystal Si semiconductor layer on an insulator is widely known as Si On Insulator (SOI) technology and much research has been focused thereon, because devices obtained utilizing the SOI technology have many advantages that cannot be achieved by the normal bulk Si substrates for fabrication of Si integrated circuits. Namely, use of SOI technology can enjoy the following advantages, for example:

1. Dielectric isolation is easy and high integration is possible.

2. Radiation resistance is high.

3. Stray capacitance is reduced and the operation speed can be enhanced.

4. The well process can be omitted.

5. Latch-up can be prevented.

6. Fully depleted field effect transistors can be fabricated by thin-film structure.

These advantages are described in further detail, for example, in the reference [Special Issue: “Single-crystal silicon on non-single-crystal insulators”; edited by G. W. Cullen, Journal of Crystal Growth, volume 63, no 3, pp 429-590 (1983)].

In recent years, many reports have been presented on the SOI as a substrate focused on increase of speed and decrease of consumption power of MOSFET (IEEE SOI conference 1994). Since the SOI structure has an insulating layer below the device, use thereof can simplify the device isolation process as compared with cases for forming the devices on a bulk Si wafer, which results in shortening the device process steps. Namely, in addition to the increase in performance, the total costs including the wafer cost and the process cost are expected to be lower than those of MOSFETs and ICs on bulk Si.

Among others, the fully depleted MOSFETs are expected to increase the speed and decrease the consumption power due to an improvement in driving force. The threshold voltage (Vth) of MOSFET is determined in general by an impurity concentration of the channel portion, and, in the case of the fully depleted (FD) MOSFETs using the SOI, the thickness of a depletion layer is also influenced by the film thickness of the SOI. Accordingly, evenness of the film thickness of SOI is highly desirable for fabricating large-scale integrated circuits with good yields.

On the other hand, the devices on a compound semiconductor have high performance that cannot be attained by Si, for example, high-speed operation, radiation of light, and so on. Presently, most of these devices are fabricated in a layer epitaxially grown on a compound semiconductor substrate of GaAs or the like. The compound semiconductor substrates, however, have problems such as high expense, low mechanical strength, difficulty in fabrication of a large-area wafer, etc.

Because of these problems, attempts have been made to hetero-epitaxially grow a compound semiconductor on the Si wafer, which is cheap, has high mechanical strength, and permits fabrication of a large-area wafer.

Returning to the SOI structure, research on formation of SOI substrates has been active since the 1970s. In the early stage, much research was focused on a method for hetero-epitaxially growing single-crystal Si on a sapphire substrate as an insulator (SOS: Silicon on Sapphire), a method for forming the SOI structure by dielectric isolation based on oxidation of porous Si (FIPOS: Full Isolation by Porous Oxidized Silicon), and an oxygen ion implantation method.

The FIPOS method is a method for forming an n-type Si layer in an island pattern on a surface of a p-type Si single-crystal substrate by proton implantation (Imai et al., J. Crystal Growth, vol 63, 547 (1983)) or by epitaxial growth and patterning, making only the p-type Si substrate porous from the surface, so as to surround Si islands by anodization in HF solution, and then dielectric-isolating the n-type Si islands by enhanced oxidation. This method has a problem in that degrees of freedom on device designing are limited, because the Si regions isolated are determined prior to the device processes.

The oxygen ion implantation method is called SIMOX, which was first reported by K. Izumi. Oxygen ions are first implanted in about 10¹⁷ to 10¹⁸/cm² into a Si wafer, and thereafter the wafer is annealed at a high temperature of approximately 1320° C. in an argon-oxygen atmosphere. As a result, the oxygen ions implanted around the depth corresponding to the projected range (Rp) of ion implantation are bound with Si to form an oxidized Si layer. At that point, a Si layer, amorphized by the oxygen ion implantation above the oxidized Si layer, is also recrystallized to form a single-crystal Si layer. Crystalline defects in the surface Si layer were as many as 10⁵/cm² before, but they were successfully decreased to below 10²/cm² by adjusting the amount of implantation of oxygen to approximately 4×10¹⁷/cm². However, the film thicknesses of the surface Si layer and the buried, oxidized Si layer (BOX; Buried Oxide) were limited to specific values due to narrow ranges of implantation energy and implantation dose capable of maintaining the film quality of the oxidized Si layer, crystallinity of the surface Si layer, and so on. Sacrificial oxidation or epitaxial growth was necessary for obtaining the surface Si layer in a desired film thickness. In that case, there is a problem that evenness of film thickness is degraded, because degradation due to these processes is added on the distribution of film thickness.

It is also reported that malformed regions of oxidized Si called pipes exist in the BOX. One of the causes thereof is conceivably contaminations such as dust upon implantation. In the portions including the pipes, degradation of device characteristics occurs due to leakage between the active layer and the support substrate.

Since the implantation dose in the ion implantation of SIMOX is larger than in the ion implantation used for the normal semiconductor processes as described previously, the implantation time is still long even after dedicated equipment has been developed. Since the ion implantation is carried out by raster scan of an ion beam of a predetermined electric current amount or by expanding the beam, an increase in the implantation time is anticipated with an increase in the area of wafer. In high-temperature annealing of a large-area wafer, it is pointed out that the problem of generation of slip or the like due to the temperature distribution within the wafer becomes more severe. Annealing at high temperatures, such as 1320° C., which are not used normally in the Si semiconductor processes, is indispensable for the SIMOX, and there is thus such a concern that the above problem becomes more significant, including development of equipment.

Aside from the conventional SOI forming methods described above, attention has recently focused on another method for bonding a Si single-crystal substrate to another Si single-crystal substrate thermally oxidized, by annealing or with an adhesive, thereby forming the SOI structure. This method requires evenly thinning the active layer for the device. In other words, it is necessary to thin the Si single-crystal substrate even several hundred μm thick down to the order of μm or less. The following three types of methods are available for this thinning:

(1) thinning by polishing

(2) thinning by localized plasma etching

(3) thinning by selective etching.

It is difficult to achieve uniform thinning by the polishing method of (1). In particular, several ten % of dispersion appears in thinning on the sub-em order, and evening of this dispersion is a big problem. The degree of difficulty increases with further increases in the diameter of a given wafer.

The above method of (2) is used to thin the layer roughly by the method of polishing of (1) to about 1 to 3 μm and to measure a distribution of film thicknesses at multiple points over the entire surface. After that, based on this distribution of film thicknesses, the layer is etched to correct the distribution of film thicknesses by scanning it with a plasma using SF₆ or the like in the diameter of several mm, whereby the layer is thinned down to a desired film thickness. It is reported that this method can achieve the film thickness distribution of about ±10 nm. However, if there are contaminants (particles) on the substrate upon plasma etching, the contaminants will serve as an etching mask, thereby forming projections on the substrate.

Since the surface is rough immediately after etching, touch polishing is necessary after completion of the plasma etching. Control of the amount of polishing is carried out by time management, and thus control of degradation of the final film thickness and of the film thickness distribution by polishing is possible. Further, because in polishing, an abrasive such as colloidal silica directly rubs the surface to become the active layer, concerns exist about formation of a crush layer and introduction of work strain by polishing. As the wafers further increase in area, the time for plasma etching also increases proportionally, which also raises another concern about an extreme drop of throughput.

The above method of (3) is a method for preliminarily forming a selectively etchable film structure in a substrate to be thinned. For example, a thin layer of p⁺-Si containing boron in a concentration of 10¹⁹ or more/cm³ and a thin layer of p-type Si are stacked on a p-type substrate by the method of epitaxial growth or the like, thereby obtaining a first substrate. This is bonded to a second substrate through an insulating layer of oxide film or the like and thereafter the back face of the first substrate is preliminarily thinned by grinding and polishing. After that, the p⁺-layer is exposed by selective etching of the p-type substrate and the p-type thin layer is exposed by selective etching of the p⁺-layer, thus completing the SOI structure. This method is described in detail in the report of Maszara (J. Electrochem. Soc. 138, 341 (1991)).

Although the selective etching is said to be effective for uniform thinning, it has the following problems:

The etch selectivity is not sufficient, at most 10².

It requires touch polishing after etching, because the surface flatness after etching is poor. This, however, results in a decrease in the film thickness and a tendency to degrade the uniformity of film thickness. Polish amounts are managed by polishing time, but polishing rates vary greatly, which makes controlling the amount of polish difficult. Accordingly, a problem arises particularly in forming a very thin SOI layer, for example, 100 nm thick.

Crystallinity of the SOI layer is poor due to use of ion implantation and epitaxial growth or hetero-epitaxial growth on the high-concentration-B-doped Si layer. The surface flatness of the bonded surfaces are inferior to normal Si wafers.

Thus, the method of (3) has the above problems (C. Harendt, et al., J. Elect. Mater. Vol. 20, 267 (1991), H. Baumgart, et al., Extended Abstract of ECS 1st International Symposium of Wafer Bonding, pp-733 (1991); C. E. Hunt, Extended Abstract of ECS 1st International Symposium of Wafer Bonding, pp-696 (1991)). Also, the selectivity of selective etching is greatly dependent on concentration differences of impurities of boron or the like and steepness of its depthwise profile. Therefore, if high-temperature bonding annealing is conducted in order to enhance the bonding strength or if high-temperature epitaxial growth is conducted in order to improve crystallinity, the depthwise distribution of impurity concentration will expand to degrade the etch selectivity. This illustrates the difficulty realizing both an improvement in etch selectivity and an improvement in bonding strength.

Recently, Yonehara et al., solving such problems, reported the bonding of SOI excellent in uniformity of film thickness and in crystallinity and capable of being batch-processed (T. Yonehara, K. Sakaguchi and N. Sato, Appl. Phys. Lett. 64, 2108 (1994)). This method uses aporous layer 242 on an Si substrate 241, as a material of selective etching. A non-porous single-crystal Si layer 243 is epitaxially grown on the porous layer and thereafter it is bonded to a second substrate 244 through an oxidized Si layer 245 (FIG. 34). The first substrate is thinned from its back surface by a method of grinding or the like, to expose the porous Si 242 across the entire surface of substrate (FIG. 35). The porous Si 242 thus exposed is removed by etching with a selective etchant such as KOH or HF+H₂O₂ (FIG. 36). At this time, the etch selectivity of porous Si to bulk Si (non-porous single-crystal Si) is sufficiently high, about 100,000. Hence, the non-porous single-crystal Si layer preliminarily grown on the porous layer can be left on the second substrate with little reduction of film thickness thereof, thus forming the SOI substrate. Therefore, the uniformity of film thickness of SOI is determined almost upon epitaxial growth. Since the epitaxial growth allows use of the CVD system used in the normal semiconductor processes, it realized the uniformity thereof, for example 100 nm±within 2%, according to the report of Sato et al. (SSDM 95). Also, the crystallinity of the epitaxial Si layer was reported to be as good as 3.5×10²/cm².

Since in the conventional methods the etch selectivity depended on the differences of impurity concentration and the depthwise profile, temperatures of thermal treatments (bonding, epitaxial growth, oxidation, etc.) to expand the concentration distribution were greatly restricted to below approximately 800° C. On the other hand, in the etching of this method, the etch rate is determined by the difference of structure between porous and bulk, and thus there is little restriction on the temperature of the thermal treatments. It is reported that thermal treatment at about 1180° C. is possible. For example, annealing after bonding is known to enhance the bonding strength between wafers and to decrease the number and size of vacancies (voids) occurring in the bonding interface. In such etching based on the structural difference, particles deposited on porous Si at the etching process, if present, do not affect the uniformity of film thickness.

However, the semiconductor substrate using bonding always requires two wafers, most of one of which is wastefully removed and discarded by polishing, etching, etc., which would result in wasting the earth's limited resources.

Accordingly, SOI by bonding, according to the existing methods, has a lot of problems regarding controllability, uniformity, and cost efficiency.

### SUMMARY OF THE INVENTION

The present invention intends to improve further the process disclosed in the above European Patent for producing a semiconductor member.

The present invention further intends to provide a process for producing economically a semiconductor substrate having a monocrystalline layer or a compound semiconductor monocrystalline layer having excellent crystallinity, large-area and a uniform flat surface on a surface of a monocrystalline substrate, in which the substrate is removed to leave the active semiconductor layer to obtain a monocrystalline layer or a compound semiconductor monocrystalline layer formed on the surface and having few defects.

The present invention still further intends to provide a process for producing a semiconductor substrate on a transparent substrate (light-transmissive substrate) for obtaining a monocrystalline Si semiconductor layer or a monocrystalline compound semiconductor layer having crystallinity as high as that of a monocrystalline wafer with high productivity, high uniformity, high controllability, and low production cost.

The present invention still further intends to provide a process for producing a semiconductor substrate useful in place of expensive SOS or SIMOX in the production of a large scale integrated circuit of SOI structure.

A first embodiment of the process for producing a semiconductor substrate of the present invention comprises the steps of: forming a non-porous monocrystalline semiconductor layer on a porous layer of the first substrate having the porous layer; bonding the nonporous monocrystalline layer onto a second substrate; separating the bonded substrates at the porous layer; removing the porous layer on the second substrate; and removing the porous layer constituting the first substrate.

A second embodiment of the process for producing a semiconductor substrate of the present invention comprises the steps of: forming a nonporous monocrystalline semiconductor layer on a porous layer of a first substrate having the porous layer; bonding the nonporous monocrystalline layer onto a second substrate with interposition of an insulative layer; separating the bonded substrates at the porous layer; removing the porous layer on the second substrate; and removing the porous layer constituting the first substrate.

In the present invention, the lamination-bonded substrates are separated at the porous layer, and the porous layer is removed from the second substrate having a nonporous monocrystalline semiconductor layer. Thereby, a semiconductor substrate is prepared which has nonporous monocrystalline semiconductor layer of high quality. Furthermore, the first substrate can be repeatedly used for producing the semiconductor substrate in the next production cycle by removing the remaining porous layer on the first substrate after the separation of the two substrates. Thereby, the semiconductor substrate can be produced with higher productivity and lower cost.

The present invention enables preparation of a monocrystalline layer of Si or the like, or a monocrystalline compound semiconductor layer having excellent crystallinity similar to monocrystalline wafers on a substrate including a light-transmissive substrate with advantages in productivity, uniformity, controllability, and production cost.

The present invention further enables production of a semiconductor substrate which can be a substitute for expensive SOS and SIMOX in the production of large scale integrated circuits of an SOI structure.

According to the present invention, the combined substrates are separated at the porous layer or layers into two or more substrates, and the one or more separated substrates may be used as a semiconductor substrate after removal of the remaining porous layer, and the other substrate may be used repeatedly in the next production cycle of a semiconductor substrate.

Further, according to the present invention, two semiconductor substrates can be produced simultaneously by forming porous layers and nonporous monocrystalline layers on the both faces of a substrate, bonding thereto two other substrates, and separating the substrates at the porous layer.

The present invention has an object to provide a semiconductor substrate and a forming method thereof which can solve the foregoing various problems by superposing a finer porous structure in a porous layer.

As a result of assiduous efforts made by the present inventors, the following invention has been achieved.

Specifically, a semiconductor substrate of the present invention is characterized by having a porous Si layer at a surface layer of a Si substrate, and a porous Si layer with large porosity existing in a region of the above-mentioned porous Si layer, which region is at a specific depth from the surface of the above-mentioned porous Si layer. In the semiconductor substrate, a non-porous Si portion may exist on the surface of the porous Si layer and an electrode may be formed on respective surfaces of the Si substrate and the nonporous Si layer, so that the semiconductor substrate constitutes a luminescent element.

According to a semiconductor substrate of the present invention, for example, a structure can be easily achieved, wherein a porous layer having a fine structure to work as a luminescent material is sandwiched in a porous layer having a high mechanical strength, such as porous silicon formed on a p⁺-Si substrate. Although the porous layer having such a fine structure differs from bulk Si in lattice constant, by sandwiching it in the large porous Si layer having an intermediate lattice constant, stresses can be relaxed and introduction of cracks or defects can be suppressed. Specifically, since the luminescent layer which can stable in structure can be formed, it not only serves to form peripheral circuit or wiring, but it is also possible to provide a material which is excellent in long-term stability.

Further, according to a semiconductor substrate of the present invention, an extremely thin porous layer corresponding to a projection range of ion implantation can be formed. Since the pore size of such a porous layer can be set small, that is, no greater than several tens of nanometers, even the small foreign matter contained in gas and exceeding several tens of nanometers in diameter can be removed. Further, a thickness of such a porous layer can be set small, that is, no greater than 20 μm, the conductance of the gas can be ensured. Specifically, when using it as a filter for particles in the gas, it is possible to produce a filter which can remove the particles greater than several tens of nanometers in diameter and whose pressure loss is small. Further, if high purity Si which is used in the semiconductor process is used as a substrate, there is no worry about contamination from the filter itself.

The present invention includes a method of producing a semiconductor substrate.

Specifically, a method of producing a semiconductor substrate of the present invention comprises a porous-forming step for forming a Si porous substrate and forming a porous Si layer on at least a surface of the Si substrate, and a high-porosity layer forming step for forming a porous Si layer with large porosity in the region at the specific depth from the porous layer in the porous Si layer. The high-porosity layer forming step can be carried out as an ion implanting step for implanting ions into the porous Si layer with a given projection range. It is preferable that the ions comprise at least one kind of noble gas, hydrogen and nitrogen. It is preferable that a non-porous layer forming step is provided for forming a non-porous layer on a surface of the porous Si layer before the ion implanting step. It is preferable that a bonding step is provided for bonding a support substrate on a surface of the non-porous layer after the high-porosity layer forming step and that a separating step is provided for separating the Si substrate into two at the large porosity porous Si layer after the bonding step. It is preferable that the separating step is performed by heat-treating the Si substrate, by pressurizing the Si substrate in a direction perpendicular to a surface thereof by drawing the Si substrate in a direction perpendicular to a surface thereof or by applying a shearing force to the Si substrate.

It is preferable that the non-porous layer is made of single-crystal Si, single-crystal Si having an oxidized Si layer on a surface to be bonded or a single-crystal compound semiconductor. It is preferable that the support substrate is a Si substrate, a Si substrate having an oxidized Si layer on a surface to be bonded or a light transmittable substrate. It is preferable that the bonding step is performed by anode bonding, pressurization, heat treatment or a combination thereof. It is preferable that a porous Si removing step is provided, after the separating step, for removing the porous Si layer exposed on a surface of the support substrate and exposing the non-porous layer. It is preferable that the porous Si removing step is performed by an electroless wet etching using at least one of hydrofluoric acid, a mixed liquid obtained by adding at least one of alcohol and aqueous hydrogen peroxide to hydrofluoric acid, buffered hydrofluoric acid, and a mixed liquid obtained by adding a least one of alcohol and hydrogen peroxide water to buffered hydrofluoric acid. It is preferable that a flattening step is provided for flattening a surface of the non-porous layer after the porous Si removing step. It is preferable that the flattening step is performed by heat treatment in an atmosphere including hydrogen.

The porous-forming step may form porous Si layers on both sides of the Si substrate, and the bonding step may bond two support substrates to the porous Si layers formed on both sides of the Si substrate. A second non-porous layer forming step can be provided, after the separating step, for again forming a non-porous layer on the surface of the porous Si layer exposed on the surface of the Si substrate, and that a second ion implanting step is provided, after the porous layer forming step, for implanting ions into the porous Si layer with a given projection range and forming a porous Si layer with large porosity in the porous Si layer. It is preferable that the porous-forming step is performed by anodization. It is preferable that the anodization is performed in a HF solution.

The high-porosity layer forming step can be carried out by also altering the current density, during the porous-forming step.

After removing any remaining porous layer, the Si substrate separated by the foregoing method may be reused as a Si substrate by performing the surface flattening process if the surface flatness is insufficient. The surface flattening process may be polishing, etching or the like normally used in semiconductor processing. On the other hand, heat treatment in an atmosphere including hydrogen may also be used. By selecting the conditions, this heat treatment can achieve flatness to an extent where the atomic step is locally presented.

According to the method of producing the semiconductor substrate of the present invention, upon removal of the Si substrate, the Si substrate can be separated at one time in a large area via the porous layer. Thus, the process can be shortened. Further, since the separating position is limited to within the porous layer with large porosity due to the ion implantation, thicknesses of the porous layer remaining on the support substrate side can be uniform so that the porous layer can be removed with excellent selectivity.

According to the producing method of the semiconductor substrate of the present invention, the Si substrate can be separated in advance in one step over a large area via the porous layer. Thus, the grinding, polishing or etching process which was essential in the prior art for removing the Si substrate to expose the porous silicon layer can be omitted to shorten the process. Further, since the separating position is limited to within the porous layer with large porosity by implanting ions of at least one kind of noble gas, hydrogen and nitrogen into the porous layer so as to have the projection range, thicknesses of the porous layer remaining on the support substrate side can be uniform so that the porous layer can be removed with excellent selectivity. It is unlikely that the thickness of the remaining porous layer is thin locally, so that the non-porous layer appears on the surface earlier and is etched accordingly. In that case, the method of forming the porous layer having a high porosity is not restricted to ion implantation, but formation can also be realized by altering the electric current at anodization. Specifically, not only the grinding or etching process which was essential in the prior art for exposing porous silicon can be omitted, but also the removed Si substrate can be reused as a Si substrate by removing the remaining porous layer. If the surface flatness after removing the porous silicon is insufficient, the surface flattening process is performed. Since the position where the bonded two substrates are separated is regulated by the projection range, the dispersion of the separating positions within porous silicon does not occur as in the prior art. Thus, upon removal of porous silicon, the single-crystal silicon layer is prevented from being exposed and etched to deteriorate the uniformity of thickness. Further, the Si substrate can be reused in the desired number of times until its structural strength makes it impossible. Further, since the separating position is restricted to around the depth corresponding to the projection range of the ion implantation, the thickness of the porous layer can be set smaller as compared with the prior art. Further, it is capable of making the layer having a high porosity a layer having a specific depth constant from the surface of the porous layer to separate it, so that the crystallizability of the porous layer is not deteriorated.

Alternatively, without removing the remaining porous layer, the separated Si substrate can be reused again as a Si substrate of the present invention by forming a non-porous single-crystal Si layer. Also in this case, the Si substrate can be reused in the desired number of times until its structural strength makes it impossible.

In the conventional method of producing the bonded substrates, the Si substrate is gradually removed from one side thereof through grinding or etching. Thus, it is impossible to effectively use both sides of the Si substrate for bonding to the support substrate. On the other hand, according to the present invention, the Si substrate is held in the initial state other than its surface layers so that, by using both sides of the Si substrate as the main surfaces and bonding the support substrates to the sides of the Si substrate, respectively, two bonded substrates can be simultaneously produced from one Si substrate. Thus, the process can be shortened and the productivity can be improved. As appreciated, also in this case, the separated Si substrate can be recycled as a Si substrate after removing the remaining porous Si.

Specifically, the present invention uses a single-crystal Si substrate which is economical, flat and uniform over a large area and has excellent crystalline properties, and removes from one side thereof to a Si or compound semiconductor active layer formed on the surface which thus remains, so as to provide a single-crystal Si layer or a compound semiconductor single-crystal layer with fewer defects on an insulating material.

The present invention provides a method of producing a semiconductor substrate which is capable of achieving a Si or compound semiconductor single-crystal layer with a crystalline property as good as a single-crystal wafer on a transparent substrate (light transmittable substrate), with high productivity, high uniformity, excellent controllability and reduced cost.

Further, the present invention provides a method of producing a semiconductor substrate which is replaceable for an expensive SOS or SIMOX upon producing a large scale integrated circuit of an SOI structure.

According to the present invention, the single-crystal compound semiconductor layer with excellent crystalline property can be formed on porous Si, and further, this semiconductor layer can be transferred onto the large-area insulating substrate which is cost efficient. Thus, the foregoing problem of the difference in lattice constant and thermal expansion coefficient can be sufficiently suppressed so as to form the compound semiconductor layer with excellent crystallinity on the insulating substrate.

Further, since porous Si has a low mechanical strength and an extensive surface area, removing the porous Si layer of the present invention can also be performed by selective polishing using the single-crystal layer as a polishing stopper.

According to the method of producing the semiconductor substrate, since the porous layer of fine structure can be formed after formation of the single-crystal silicon layer on the porous layer, the epitaxial growth conditions of the single-crystal layer can be free of influence of the structural changes of the porous layer. Specifically, since the fine-structure porous layer, working as a luminescent layer, which tends to change due to thermal treatment, can be formed after completion of thermal treatment for the film formation, its characteristics can be stable.

According to the method of producing the semiconductor substrate, upon removing the Si substrate, the Si substrate can be separated in one step over a large area via the porous layer and, the process can be shortened. Further, since the separating position is limited to within the porous layer by means of the ion implantation, thicknesses of the porous layer remaining on the support substrate side can be uniform so that the porous layer can be removed with high selectivity. Thus, even when etching is unstable due to the size of apparatus or the change of the environment, the non-porous thin film, such as the single-crystal Si layer or the compound semiconductor single-crystal layer, which is economical, flat and uniform over the large area and has the extremely excellent crystalline property, can be transferred onto the support substrate with high yield. Specifically, the SOI structure with the single-crystal Si layer formed on the insulating layer can be obtained with high uniformity of film thickness and high yield. Further, since the separating position is regulated by the project range of the ion implantation so as to be within the porous layer, the thicknesses of the porous layer remaining on the support substrate side can be uniform so that the porous layer can be removed with high selectivity. Further, the removed Si substrate can be reused as an Si substrate by removing the remaining porous layer. If the surface flatness after removing porous silicon is insufficient, the surface flattening process is performed.

The present invention provides a producing method of a semiconductor substrate which is capable of achieving a Si or compound semiconductor single-crystal layer with a crystalline property as good as a single-crystal wafer on a transparent substrate (light transmittable substrate), with high productivity, high uniformity, excellent controllability and reduced cost.

According to the method of producing the semiconductor substrate of the present invention, since the selective etching with a good ratio of etching selectively can be performed, by performing the bonding with the support substrate, a SOI substrate or the compound semiconductor single crystal on the support substrate, which is flat and uniform over the large area and has an extremely excellent crystalline property, can be achieved.

Further, according to the method of producing the semiconductor substrate, the single-crystal compound semiconductor layer with high crystalline property can be formed on porous Si, and further, this semiconductor layer can be transferred onto a large-area insulating substrate which is economical. Thus, the foregoing problems of the differences in lattice constants and thermal expansion coefficients can be sufficiently suppressed to form the compound semiconductor layer with excellent crystalline properties on the insulating substrate.

Further, even if non-formation regions of the implanted layer are formed due to presence of foreign matter on the surface upon ion implantation, since the mechanical strength of the porous layer itself is smaller than bulk Si, the separation occurs in the porous layer. Thus, the two bonded substrates can be separated without causing damages such as cracks in the non-porous single-crystal silicon layer.

Further, since the gettering effect is available at the ion-implanted region, even if metal impurities exist, the two bonded substrates are separated after achieving the gettering of the impurities into the ion-implanted region, and then the ion-implanted region is removed so that it is also effective against impurity contamination.

Further, since the separating region is limited to the ion-implanted region within the porous layer, the depths of the separating region do not disperse within the porous layer. Accordingly, even if the ratio of selectively etching porous silicon is insufficient, a time for removing porous silicon can be rendered substantially constant so that the thickness uniformity of the single-crystal silicon layer transferred onto the support substrate is not spoiled.

The inventor has made strenuous efforts to achieve the above object and obtain the following invention. Namely, a first fabrication process for a semiconductor substrate according to the present invention is a fabrication process comprising: a step of bonding a principal surface of a first substrate to a principal surface of a second substrate, the first substrate being an Si substrate in which at least one layer of non-porous thin film is formed through a porous Si layer; a step of exposing the porous Si layer in a side surface of a bonding substrate comprised of the first substrate and the second substrate; a step of dividing the bonding substrate in the porous Si layer by oxidizing the bonding substrate; and a step of removing a porous Si and oxidized porous Si layer on the second substrate separated by the division of the bonding substrate in the porous Si layer.

Further, a second fabrication process for a semiconductor substrate according to the present invention is a fabrication process comprising: a step of e bonding a principal surface of a first substrate to a principal surface of a second substrate, the first substrate being a Si substrate in which at least one layer of non-porous thin film is formed through a porous Si layer and in which the porous Si layer is exposed in a side surface thereof; a step of dividing the bonding substrate in the porous Si layer by oxidizing a bonding substrate comprised of the first substrate and the second substrate; and a step of removing a porous Si and oxidized porous Si layer on the second substrate separated by the division of the bonding substrate in the porous Si layer.

Also, a third fabrication process for a semiconductor substrate according to the present invention is one according to the above first or second fabrication, wherein after removing the porous Si and oxidized porous Si layer on the first substrate separated by the division of the bonding substrate in the porous Si layer, the first substrate is again used as a raw material for the first substrate before bonding.

In addition, a fourth fabrication process for a semiconductor substrate according to the present invention is one according to the above first or second fabrication process, wherein after removing the porous Si and oxidized porous Si layer on the first substrate separated by the division of the bonding substrate in the porous Si layer, the first substrate is again used as a raw material for the second substrate before bonding.

Moreover, a fifth fabrication process for a semiconductor substrate according to the present invention is one according to any of the above first to fourth fabrication processes, wherein at least one layer of non-porous thin film is formed through a porous Si layer on each of two principal surfaces of the first substrate and the second substrate is bonded to each of the two principal surfaces.

The present invention utilizes enhanced oxidation of porous Si to oxidize the porous Si layer from the periphery of the wafer, whereby volume expansion of porous Si becomes greater from the center to the periphery. This seems as if porous Si is uniformly wedged from the periphery, so that the internal pressure is exerted on only the porous layer, and it splits the wafer in the porous Si layer therethrough across the entire surface of the wafer. This provides a fabrication process for a semiconductor substrate solving the various problems discussed above.

Namely, in the case of the bonding substrate having a multi-layered structure, if the method of splitting at porous Si by external pressure is applied and if the substrate has an interface with low strength or a partially weak region, the substrate will be split at the weak portion. In contrast, the present invention permits the internal pressure to be exerted only on the porous Si layer by utilizing oxidation, one step of the normal Si—IC processes, excellent in uniformity, and by combining high-speed oxidizability of porous Si, volume expansion of porous Si, and fragility of porous Si, whereby the wafer can be split with good controllability in and through the porous Si layer.

Further, use of the process according to the present invention enables reuse of the first Si substrate after removal of the porous substrate portion. This first Si substrate can be reused any number of times before it becomes unusable with respect to its mechanical strength.

The present invention permits separation through the porous layer over a large area in removing the first Si substrate. The first Si substrate thus removed can be reused again as a first Si substrate or as a next second substrate after removing the residual porous layer or after flattening the surface if the surface is too rough. The surface flattening process may be polishing, etching, or any other method used in the normal semiconductor processes, but may be annealing in an atmosphere containing hydrogen. By selecting suitable conditions for this annealing, the surface can be flattened so as to reveal atomic steps locally. In the case of repetitive use as a first Si substrate, this first Si substrate can be reused any number of times before it becomes unusable with respect to its mechanical strength.

Since the present invention permits division of a large area en bloc through the porous layer, it can obviate the need for the grinding, polishing, and etching steps conventionally essential for removing the first substrate to expose the porous Si layer, thereby decreasing the steps. In addition, the position of division can be defined at a limited depth in the porous Si layer by preliminarily performing ion implantation of at least one element chosen from rare gases, hydrogen, and nitrogen so as to have the projected range in the porous layer, which evens the thickness of the porous layer remaining on the second substrate side. Then the porous layer can be removed uniformly even with an etchant having low to moderate etch selectivity. Further, the conventional fabrication of a bonding substrate employed a method for successively removing the first Si layer from one surface by grinding and etching, therefore making it impossible to bond the two surfaces of the first Si layer with respective support substrates, thereby effectively utilizing both surfaces. In contrast, according to the present invention, the first Si substrate, except for the surface layer thereof, is maintained as it was, and two substrates can be fabricated simultaneously by bonding, dividing and thinning, with the aid of a first Si substrate by using both surfaces of the first Si substrate as principal surfaces and bonding support substrates to the respective surfaces, thereby raising productivity. Of course, the first Si substrate after division can be reused.

In addition, the present invention permits a large area to be divided en bloc through the porous layer in removing the first Si substrate. This method decreases processing steps, which is economically desirable, and can transfer a non-porous thin film such as a Si single-crystal layer or a compound semiconductor single-crystal layer, which is uniformly flat across a large area and which has excellent crystallinity, to the second substrate at a good yield. Namely, the SOI structure with the Si single-crystal layer formed on the insulating layer can be attained with good uniformity of film thickness and at a good yield.

In other words, the present invention provides the Si single-crystal layer or the compound semiconductor single-crystal layer with a remarkably reduced number of imperfections on the insulator by using a Si single-crystal substrate in an economically desirable amount, which exhibits uniform flatness across a large area and excellent crystallinity, by removing the portion from its one surface to the active layer and leaving the Si or compound semiconductor active layer formed on the surface.

The present invention provides a fabrication process for a semiconductor substrate superior with respect to productivity, uniformity, controllability, and cost in obtaining the Si or compound semiconductor single-crystal layer with excellent crystallinity equivalent to that of a single-crystal wafer, on a transparent substrate (light transmissive substrate).

The fabrication process for a semiconductor substrate according to the present invention involves performing selective etching with outstandingly excellent etch selectivity, thereby enabling one to obtain a Si single crystal or compound semiconductor single crystal which is uniformly flat across a large area and which has excellent crystallinity.

Further, removal of the porous Si layer of the present invention can also be done by selective polishing, using the single-crystal layer as a polishing stopper because porous Si has low mechanical strength and enormous surface area.

Also, the present invention can provide a fabrication process for a semiconductor substrate that can replace the expensive SOS or SIMOX for fabricating large-scale integrated circuits of the SOI structure.

The present invention can form a single-crystal compound semiconductor layer with good crystallinity on porous Si, can transfer the semiconductor layer onto an economically desirable and large-area insulating substrate, and can form the compound semiconductor layer with good crystallinity on the insulating substrate while restraining the differences in lattice constant and coefficient of thermal expansion, which were problems in the prior art.

In the present invention, a layer of a material having a smaller coefficient of thermal expansion than that of Si is formed at least on one side of the outer surfaces of the bonding substrate before splitting by oxidation (or possibly before bonding), whereby at temperatures during oxidation, Si becomes more likely to expand and thus stress acts in the wafer peeling directions in the peripheral region of the bonding wafer, facilitating occurrence of the wedge effect by oxidation.

Also, in the case where regions without an implant layer are formed due to the existence of contaminations on the surface upon ion implantation, because the mechanical strength of the porous layer itself is smaller than that of bulk Si, peeling occurs in the porous layer, so that the two substrates bonded can be divided without extending damages such as cracks to the non-porous single-crystal Si layer.

Since the ion implant region has the gettering effect, metal impurities, if present, can be subject to gettering by the ion implant region and thereafter the ion implant region with the impurities can be removed by separating the two substrates bonded. It is thus effective with respect to impurity contamination.

The present invention may combine anodization with ion implantation to make the porosity of the side surface small and the porosity of the central part large, thereby making the volume expansion of the side surface greater and the strength of the central part low so as to facilitate peeling.

### BRIEF DESCRIPTION OF THE DRAWINGS

FIGS. 1A to 1E are schematic drawings for explaining an example of the process of the present invention.

FIGS. 2A to 2E are schematic drawings for explaining another example of the process of the present invention.

FIGS. 3A to 3E are schematic drawings for explaining still another example of the process of the present invention.

FIGS. 4A to 4E are schematic drawings for explaining a further example of the process of the present invention.

FIGS. 5A to 5E are schematic drawings for explaining a still further example of the process of the present invention.

FIGS. 6A to 6E are schematic diagrams for explaining a conventional semiconductor substrate producing process;

FIGS. 7A and 7B are schematic diagrams for explaining a semiconductor substrate producing process according to a preferred embodiment 6 of the present invention;

FIGS. 8A to 8C are schematic diagrams for explaining a semiconductor substrate producing process according to a preferred embodiment 7 of the present invention;

FIGS. 9A to 9C are schematic diagrams for explaining a semiconductor substrate producing process according to a preferred embodiment 8 of the present invention;

FIGS. 10A to 10D are sectional views showing a process of an EL element;

FIGS. 11A to 1 IF are schematic diagrams for explaining a semiconductor substrate producing process according to a preferred embodiment 9 of the present invention;

FIGS. 12A to 12F are schematic diagrams for explaining a semiconductor substrate producing process according to a preferred embodiment 10 of the present invention;

FIGS. 13A to 13E are schematic diagrams for explaining a semiconductor substrate producing process according to a preferred embodiment 11 of the present invention;

FIGS. 14A and 14B are schematic diagrams for explaining anodization;

FIGS. 15A to 15G are schematic diagrams for explaining a semiconductor substrate producing process according to a preferred embodiment 12 of the present invention;

FIGS. 16A to 16G are schematic diagrams for explaining a semiconductor substrate producing process according to a preferred embodiment 13 of the present invention;

FIG. 17 is a schematic cross-sectional view for explaining a step of another example;

FIG. 18 is a schematic cross-sectional view for explaining a step of another example;

FIG. 19 is a schematic cross-sectional view for explaining a step of another example;

FIG. 20 is a schematic cross-sectional view for explaining the principle of the present invention;

FIG. 21 is a schematic cross-sectional view for explaining the principle of the present invention;

FIG. 22 is a schematic cross-sectional view for explaining the principle of the present invention;

FIG. 23 is a schematic cross-sectional view for explaining a step of the present invention;

FIG. 24 is a schematic cross-sectional view for explaining a step of the present invention;

FIG. 25 is a schematic cross-sectional view for explaining a step of the present invention;

FIG. 26 is a schematic cross-sectional view for explaining a step of the present invention;

FIG. 27 is a schematic cross-sectional view for explaining a step of the present invention;

FIG. 28 is a schematic cross-sectional view for explaining a step of the present invention;

FIG. 29 is a schematic cross-sectional view for explaining a step of the present invention;

FIG. 30 is a schematic cross-sectional view for explaining a step of the present invention;

FIG. 31 is a schematic cross-sectional view for explaining a step of the present invention;

FIG. 32 is a schematic cross-sectional view for explaining a step of the present invention;

FIGS. 33A to 33E are schematic diagrams for explaining a semiconductor substrate producing process which has been proposed before;

FIG. 34 is a schematic cross-sectional view for explaining a step of the conventional example;

FIG. 35 is a schematic cross-sectional view for explaining a step of the conventional example; and

FIG. 36 is a schematic cross-sectional view for explaining a step of the conventional example.

### DETAILED DESCRIPTION OF THE PREFERRED EMBODIMENTS

The process for producing a semiconductor substrate of the present invention is described by employing a silicon substrate as an example.

The mechanical strength of porous silicon is much lower than that of bulk silicon depending on the porosity thereof. For instance, porous silicon having a porosity of 50% is considered to have half the mechanical strength of bulk silicon. Therefore, on application of a tensile force, a compressive force, or a shearing force to a laminated wafer, the porous layer will be broken first. The larger the porosity of the porous layer, the less force is needed for the breakdown of the layer.

A silicon substrate can be made porous by anodization in an HF solution. The resulting porous Si layer has a density ranging from 1.1 to 0.6 g/cm³ depending on the HF solution concentration of from 50 to 20% in comparison with the density of 2.33 g/cm³ of monocrystalline Si. The porous layer is formed only on a P-type Si substrate, but is not formed on an N-type Si layer for the reasons described later. The porous Si layer has pores of about 600 Å in average diameter according to transmissive electron microscopy.

The porous Si was found by Uhlir, et al. in the year 1956 during the study of electropolishing of semiconductors (A. Uhlir: Bell Syst. Tech. J., vol. 35, p. 333 (1956)).

Unagami, et al. found that positive holes are required for anodization of Si in an HF solution, and the reactions proceed as shown in their report on dissolution of Si in anodization (T. Unagami, et al.: J. Electrochem. Soc., vol. 127, p. 476 (1980)) as below:

Si+2HF+(2−n)e⁺→SiF₂+2H⁺+ne⁻

SiF₂+2HF→SiF₄+H₂

SiF₄+2HF→H₂SiF₆

or

Si+4HF+(2−λ)e⁻→SiF₄+4H⁺+λe⁻

SiF₄+2HF→H₂SiF₆

where e⁺ and e⁻ represent respectively a positive hole and an electron; n and λ represent respectively the number of positive holes required for dissolving one Si atom. Unagami reported that porous Si is formed under the condition of n>2, or λ>4.

According to the above consideration, P-type Si which has positive holes can be made porous, whereas N-type Si cannot be made porous. This selectivity for porosity was evidenced by Nagano, et-al., and Imai (Nagano, Nakajima, Yasuno, Oonaka, and Kajihara: Denshi Tsushin Gakkai Gijutsu Kenkyu Hokoku (Technical Research Report of Electronic communication society) vol. 79, SSD79-9549 (1979); and K. Imai: Solid-State Electronics, vol. 24, p. 159 (1981)).

On the other hand, a report is found that high concentration N-type Si can be made porous (R. P. Holmstrom and J. Y. Chi: Appl. Phys. Lett., Vol. 42, p. 386 (1983)). Therefore, selection of the substrate is important for producing porous Si regardless of P-type or N-type.

The porous Si layer has pores of about 600 Å in average diameter by observation by transmission electron microscopy, and the density is less than half that of monocrystalline Si. Nevertheless, the single crystallinity is maintained, and thereon a monocrystalline Si can be made to grow epitaxially in layer. However, in the epitaxal growth at a temperature of 1000° C. or higher, the internal pores will come to be rearranged, which impairs the accelerated etching characteristics. Therefore, low temperature growth processes are preferred for epitaxial growth of the Si layer, such as molecular beam epitaxial growth, plasma CVD, reduced pressure CVD, photo-assisted CVD, bias sputtering, and liquid-phase epitaxial growth.

The porous layer has a large volume of voids therein, having a half or lower density of the material, and having a surface area remarkably large for the volume. Accordingly, the chemical etching is greatly accelerated in comparison with that of the normal monocrystalline layer.

Embodiment 1

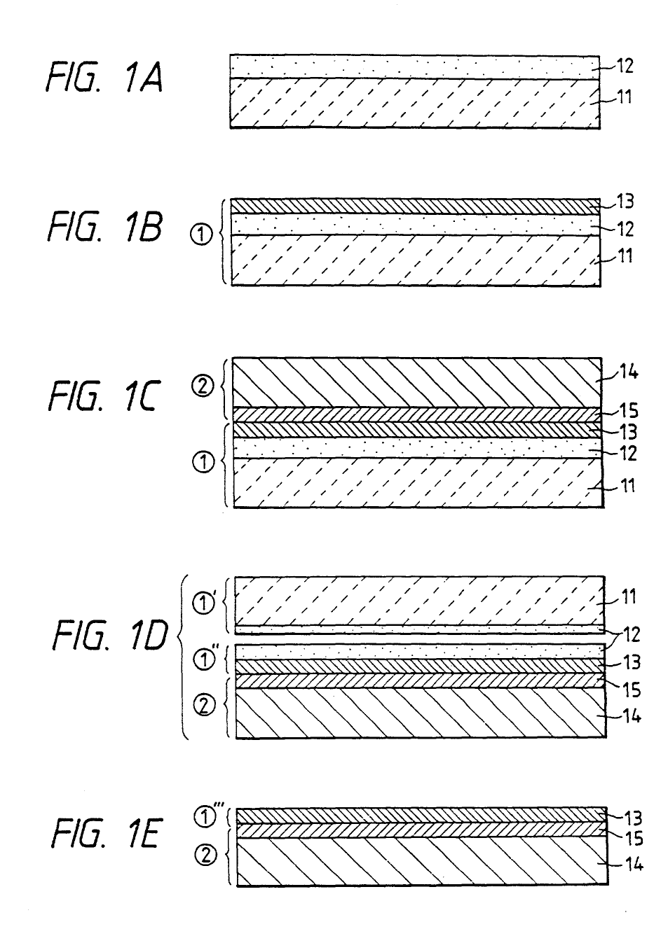

A first monocrystalline Si substrate 11 is made porous at the surface to form a porous layer 12 as shown in FIG. 1A. Then, nonporous monocrystalline Si layer 13 is formed on the porous Si layer 12 as shown in FIG. 1B.

Another Si supporting substrate 14 is brought into contact with the nonporous monocrystalline Si layer 13 with interposition of an insulative layer 15 at room temperature as shown in FIG. 1C, and then the contacted matter was subjected to anode coupling, compression, heat treatment, or combination thereof to bond tightly the Si supporting substrate 14 and the monocrystalline layer 13 with interposition of the insulative layer 15. The insulative layer 15 may be formed preliminarily on either one of the monocrystalline Si layer 13 or the Si supporting substrate 14, or the three sheets may be bonded with an insulative thin film interposed.

Subsequently, the substrates are separated at the porous Si layer 12 as shown in FIG. 1D. On the Si supporting substrate 14, the layers have the structure of porous Si 12/monocrystalline Si layer 13/insulative layer 15/Si supporting substrate 14.

The porous Si 12 is removed selectively by nonelectrolytic wet chemical etching by use of at least one of a usual Si etching solution, hydrofluoric acid or a mixture of hydrofluoric acid with alcohol and/or hydrogen peroxide as the porous Si-selective etching solution, and buffered hydrofluoric acid or a mixture of hydrofluoric acid with alcohol and/or hydrogen peroxide to leave the thin-layered monocrystalline Si layer 13 on the insulative substrate 15 and 14. As described above in detail, the porous Si can be etched selectively by a usual Si etching solution owing to the extremely large surface area of the porous surface area.

Otherwise, the porous Si 12 is selectively removed by grinding by utilizing the monocrystalline Si layer 13 as the grinding stopper.

FIG. 1E illustrates a semiconductor substrate of the present invention. The monocrystalline Si layer 13 is formed flat and uniformly in a thin layer on the insulative substrate 15 and 14 over the entire large area of the wafer. The resulting semiconductor substrate is useful for production of insulation-isolated electronic elements.

The first monocrystalline Si substrate 11 may be repeatedly used for the same use after removal of the remaining Si and surface flattening treatment if the surface has become roughened unacceptably in the next production cycle.

The method of separation of the two substrates at the porous Si layer in the present invention includes crushing of the porous layer by compression on both faces of the bonded substrates; pulling of the respective substrates in opposite directions; insertion of a jig or the like into the porous layer; application of force in opposite directions parallel to the bonded face of the substrates; application of supersonic vibration to the porous layer; and so forth.

The porosity of the porous Si layer suitable for the separation ranges generally from 10 to 80%, preferably from 20 to 60%.

Embodiment 2

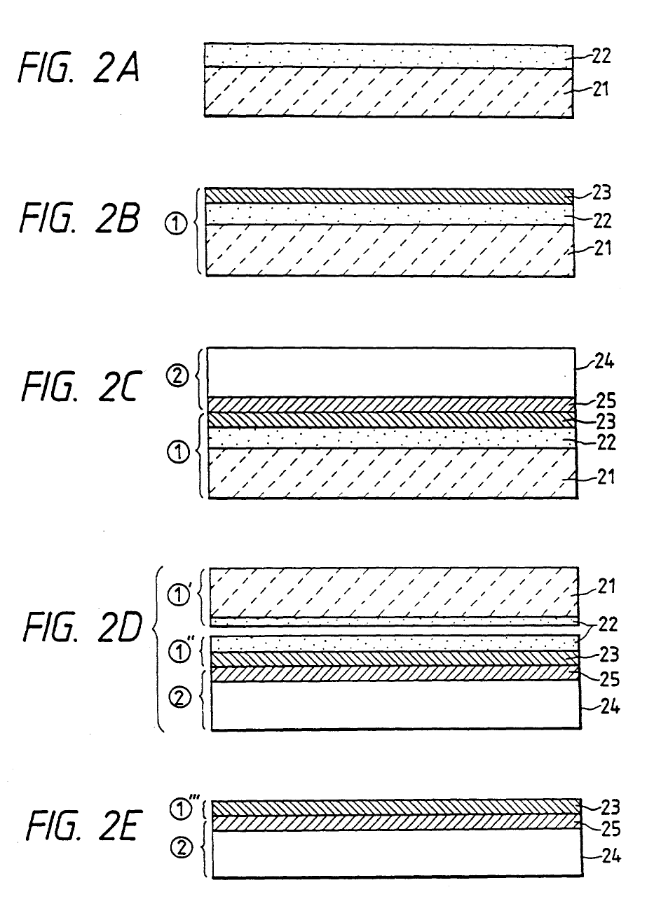

A first monocrystalline Si substrate 21 is made porous at the surface to form a porous layer 22 as shown in FIG. 2A. Then a nonporous monocrystalline Si layer 23 is formed on the porous Si layer 22 as shown in FIG. 2B.

A light-transmissive supporting substrate 24 is brought into contact with the monocrystalline Si layer 23 with interposition of an insulative layer 25 at room temperature as shown in FIG. 2C, and then the contacted matter was subjected to anode coupling, compression, heat treatment, or combination of the treatment to bond tightly the light-transmissive supporting substrate 24 and the monocrystalline layer 23 with interposition of the insulative layer 25. The insulative layer 25 may be formed preliminarily on either one of the monocrystalline Si layer or the light-transmissive supporting substrate 24, or the three sheets may be bonded with interposition of an insulative thin film.

Subsequently, the substrates are separated at the porous Si layer 22 as shown in FIG. 2D. On the light-transmissive supporting substrate, the layers have the structure of porous Si 22/monocrystalline Si layer 23/insulative layer 25/light-transmissive supporting substrate 24.

The porous Si 22 is removed selectively by non-electrolytic wet chemical etching by use of at least one of a usual Si etching solution, hydrofluoric acid or a mixture of hydrofluoric acid with alcohol and/or hydrogen peroxide as the porous Si-selective etching solution, and buffered hydrofluoric acid or a mixture of hydrofluoric acid with alcohol and/or hydrogen peroxide to leave a thin-layered monocrystalline Si layer 23 on the insulative substrate 25 and 24. As described above in detail, the porous Si can be etched selectively by a usual Si etching solution because of the extremely large surface area of the porous surface area.

Otherwise, the porous Si 23 is selectively removed by grinding by utilizing the monocrystalline Si layer 22 as the grinding stopper.

FIG. 2E illustrates a semiconductor substrate of the present invention. The monocrystalline Si layer 23 is formed flat and uniformly in a thin layer on the insulative substrate 25 and 24 over the entire large area of the wafer. The obtained semiconductor substrate is useful for production of insulation-isolated electronic elements.

The presence of the interposed insulative layer 25 is not essential.

The first monocrystalline Si substrate 21 may be repeatedly used for the same use after removal of the remaining Si and surface flattening treatment if the surface has become roughened unacceptably in the next production cycle.

Embodiment 3

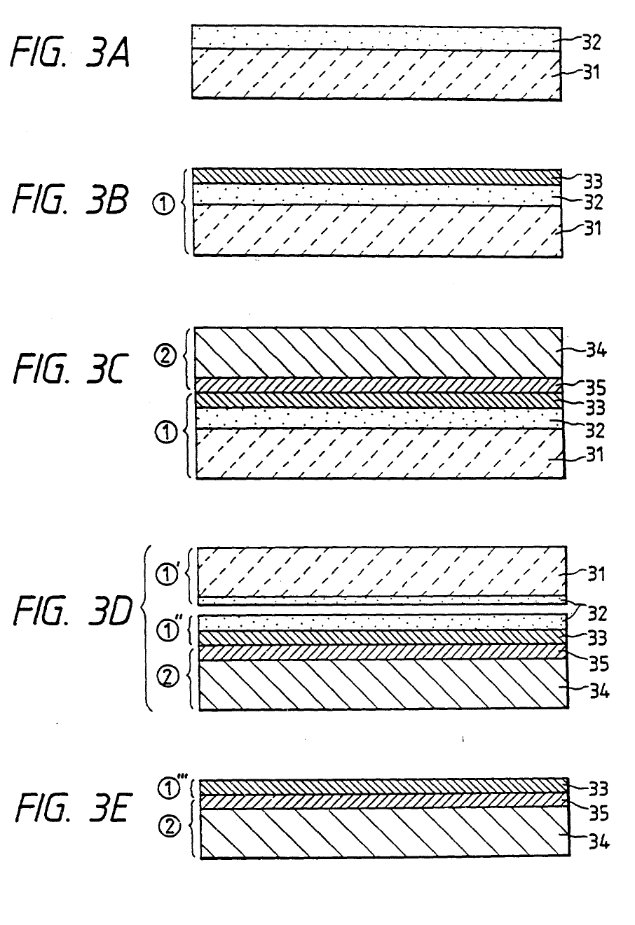

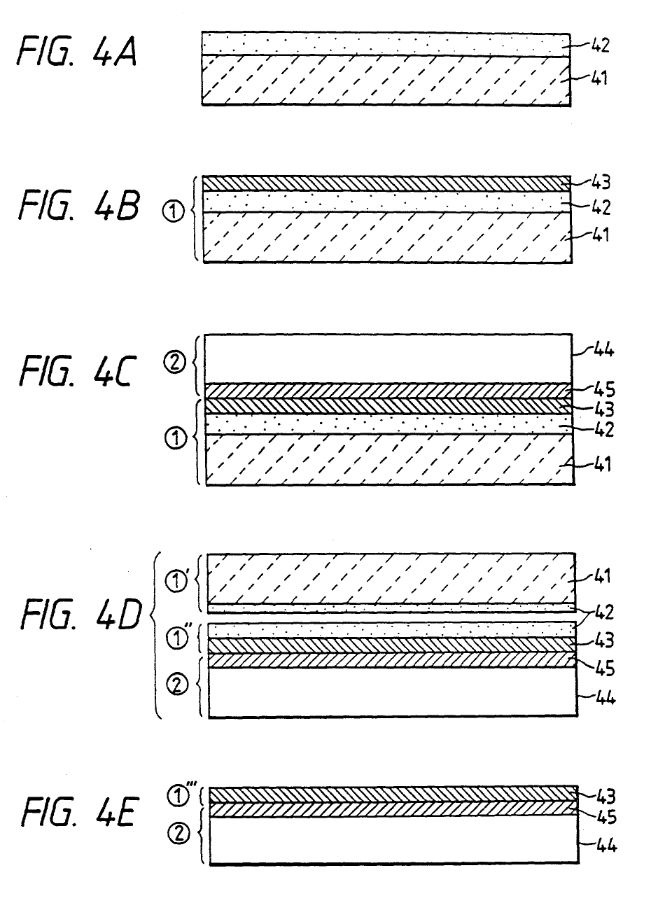

A first monocrystalline Si substrate 31 is made porous at the surface to form a porous layer 32 as shown in FIG. 3A. Then a nonporous monocrystalline compound semiconductor layer 33 is formed on the porous Si layer 32 as shown in FIG. 3B.

Another Si supporting substrate 34 is brought into close contact with the monocrystalline compound semiconductor layer 33 with interposition of an insulative layer 35 at room temperature as shown in FIG. 3C, and then the contacted matter was subjected to anode coupling, compression, or heat treatment, or combination of the treatments to bond tightly the Si supporting substrate 34 and the monocrystalline layer 33 with interposition of the insulative layer 35. The insulative layer 35 may be formed preliminarily on either one of the monocrystalline compound semiconductor layer or the Si supporting substrate 34, or the three sheets may be bonded with interposition of an insulative thin film.

Subsequently, the substrates are separated at the porous Si layer 32 as shown in FIG. 3D. On the Si supporting substrate, the layers have the structure of porous Si 3 2/monocrystalline compound semiconductor layer 33/insulative layer 35/Si supporting substrate 34.

The porous Si 32 is removed selectively by chemical etching by use of an etching solution which is capable of etching Si at a higher etching rate than the compound semiconductor to leave the thin-layered monocrystalline compound semiconductor layer 33 on the insulative substrate 35 and 34.

Otherwise, the porous Si 32 is selectively removed by grinding by utilizing the monocrystalline compound semiconductor layer 33 as the grinding stopper.

FIG. 3E illustrates a semiconductor substrate of the present invention. The monocrystalline compound semiconductor layer 33 is formed flat and uniformly in a thin layer on the insulative substrate 35 and 34 over the entire large area of the wafer. The resulting semiconductor substrate is useful as a compound semiconductor substrate and for production of insulation-isolated electronic elements.

When the substrate is used as a compound semiconductor substrate, the insulative layer 35 is not essential.

The first monocrystalline Si substrate 31 may be repeatedly used for the same use after removal of the remaining Si and surface flattening treatment if the surface has become roughened unacceptably in the next production cycle.

Embodiment 4

A first monocrystalline Si substrate 41 is made porous at the surface to form a porous layer 42 as shown in FIG. 4A. Then a nonporous monocrystalline compound semiconductor layer 43 is formed on the porous Si layer 42 as shown in FIG. 4B.

A light-transmissive supporting substrate 44 is brought into close contact with the monocrystalline compound semiconductor layer 43 with interposition of an insulative layer 45 at room temperature as shown in FIG. 4C, and then the contacted matter was subjected to anode coupling, compression, heat treatment, or combination of the treatments to bond tightly the light-transmissive supporting substrate 44 with the monocrystalline layer 43 with interposition of the insulative layer 45. The insulative layer 45 may be formed preliminarily on either one of the monocrystalline compound semiconductor layer or the light-transmissive supporting substrate 44, or the three sheets may be bonded with interposition of an insulative thin film.

Subsequently, the substrates are separated at the porous Si layer 42 as shown in FIG. 4D. On the light-transmissive supporting substrate, the layers have the structure of porous Si 42/monocrystalline compound semiconductor layer 43/insulative layer 45/light-transmissive supporting substrate 44.

The porous Si 42 is removed selectively by chemical etching by use of an etching solution which is capable of etching Si at a higher etching rate than the compound semiconductor to leave a thin-layered monocrystalline compound semiconductor layer 43 on the insulative substrate 45 and 44.

Otherwise, the porous Si 42 is selectively removed by grinding by utilizing the monocrystalline compound semiconductor layer 43 as the grinding stopper.

FIG. 4E illustrates a semiconductor substrate of the present invention. The monocrystalline compound semiconductor layer 43 is formed flat and uniformly in a thin layer on the insulative substrate 45 and 44 over the entire large area of the wafer. The resulting semiconductor substrate is useful for production of insulation-isolated electronic elements.

The insulative layer 45 is not essential in this embodiment.

The first monocrystalline Si substrate 41 may be repeatedly used for the same use after removal of the remaining Si and surface flattening treatment if the surface has become roughened unacceptably in the next production cycle.

Embodiment 5

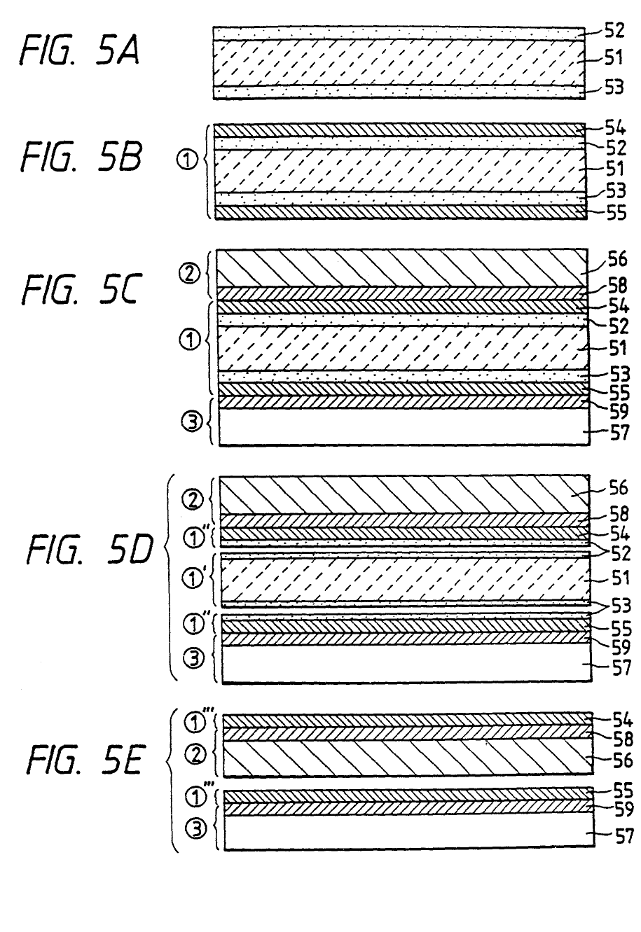

A first monocrystalline Si substrate 51 is made porous at the both faces to form porous layers 52, 53 as shown in FIG. 5A. Then, nonporous monocrystalline compound semiconductor layers 54, 55 are formed on the porous Si layers 52, 53 as shown in FIG. 5B.

Two supporting substrates 56, 57 are brought into close contact with the monocrystalline semiconductor layers 54, 55 with interposition of insulative layers 58, 59 respectively at room temperature as shown in FIG. 5C, and then the contacted matter is subjected to anode coupling, compression, heat treatment, or combination of the treatments to bond tightly the supporting substrates 56, 57 and the monocrystalline layers 54, 55 with interposition of the insulative layers 58, 59. In the bonding, the respective insulative layers 58, 59 may be formed preliminarily on either one of the monocrystalline semiconductor layer 54, 55 or the supporting substrate 56, or the five sheets may be bonded with interposition of insulative thin films.

Subsequently, the substrates are separated into three at the both porous Si layers 52, 53 as shown in FIG. 5D. The two supporting substrates come to have a structure of porous Si/monocrystalline semiconductor layer/insulative layer/supporting substrate (52/54/58/56, and 53/55/59/57).

The porous Si layers 52, 53 are removed selectively by chemical etching to leave thin-layered monocrystalline semiconductor layers 54, 55 on the supporting substrates 58/56 and 59/57.

Otherwise, the porous Si 52, 53 is selectively removed by grinding by utilizing the monocrystalline semiconductor layers 54, 55 as the grinding stopper.

FIG. 5E illustrates semiconductor substrates prepared according to the present invention. The monocrystalline compound semiconductor layers are formed flat and uniformly in a thin layer on the supporting substrates over the entire large area of the two wafers at a time with a large area. The resulting semiconductor substrate is useful for production of insulation-isolated electronic elements.

The insulative intervening layers 58, 59 are not essential.

The supporting substrates 56, 57 need not be the same.

The first monocrystalline Si substrate 51 may be repeatedly used for the same use after removal of the remaining Si and surface flattening treatment if the surface has become roughened unacceptably in the next production cycle.

### EXAMPLE 1

A first monocrystalline (100) Si substrate of P-type having a diameter of 6 inches, a thickness of 625 μm, and a specific resistance of 0.01 Ω.cm was anodized in an HF solution under the anodization conditions as below:

| Current density: | 5 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for one hour. Thereby the inner wall of the pores of the porous Si was covered with a thermal oxidation film. On the porous Si, monocrystalline Si was allowed to grow epitaxially in a thickness of 1 μm by CVD (chemical vapor deposition) under the growth conditions below:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

The face of the epitaxially grown Si layer was thermally oxidized to form an SiO₂ layer of 100 nm thick.

On the face of this Si substrate, a separately prepared second Si substrate having an SiO₂ layer of 500 nm thick was superposed with the SiO₂ layer inside, and the superposed matter was heat-treated at 900° C. for 2 hours to bond the substrates tightly.

A pulling force was applied to the resulting bonded wafer in the direction perpendicular to the wafer face in such a manner that a plate was bonded respectively to each of the both faces of the wafer with an adhesive and the plates were pulled to opposite directions with a jig. Consequently, the porous Si layer was broken to cause separation of the wafer into two sheets with the porous Si layers exposed.

The porous Si layer on the second substrate was etched selectively in a mixture of 49% hydrofluoric acid and 30% hydrogen peroxide (1:5) with agitation. The porous Si was etched and removed completely with the monocrystalline Si remaining unetched as an etching stopper. The etching rate of the nonporous monocrystalline Si was extremely low, the selection ratio of the etching rate of the porous Si being 10⁵ or higher. Therefore, the decrease in thickness of the nonporous layer by etching was practicably negligible (several tens of Å).

Consequently, a monocrystalline Si layer was formed in a thickness of 1 μm on an Si oxide film. The monocrystalline Si layer did not change at all by the selective etching of the porous Si layer.

The cross-section of the Si layer was observed by transmission electron microscopy, and it was confirmed that no additional crystal defect was formed in the Si layer and the excellent crystallinity was retained.

Thus an SOI substrate was obtained which has a semiconductor layer of high quality.

The other Si substrate having been separated at the porous Si layer portion was etched in the same manner as above to remove the remaining porous layer, and its surface was polished. The obtained Si substrate was used repeatedly for the same use in the next production cycle. Thereby a plurality of SOI substrates having a semiconductor layer of high quality were obtained.

### EXAMPLE 2

A first monocrystalline (100) Si substrate of P-type having a diameter of 4 inches, a thickness of 525 μm, and a specific resistance of 0.01 Ω.cm was anodized in an HF solution under the anodization conditions as below:

| Current density: | 7 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for 2 hours. Thereby the inner wall of the pores of the porous Si was covered with a thermal oxidation film. On the porous Si, monocrystalline Si was allowed to grow epitaxially in a thickness of 0.5 μm by MBE (molecular beam epitaxy) under the growth conditions below:

| | |
|---|---|
| Temperature: | 700° C. |
| Pressure: | 1 × 10⁻⁹ Torr |
| Growth rate: | 0.1 μm/sec |
| Temperature: | 950° C. |
| Growth rate: | 0.3 μm/min |

The face of the epitaxially grown Si layer was thermally oxidized to form an SiO₂ layer of 100 nm thick.

On the face of the SiO₂ layer, was superposed a separately prepared fused quartz substrate, and the superposed matter was heat-treated at 400° C. for 2 hours to bond the substrates.

A sufficient compression force was applied uniformly to the resulting bonded wafer in the direction perpendicular to the wafer face such that plates were bonded to each of the both faces of the wafer with an adhesive and the compression force was applied with the same jig as in Example 1.

Consequently, the porous Si layer was broken to cause separation of the wafer into two sheets with the porous Si layers exposed.

The porous Si layers were etched selectively in a mixture of buffered hydrofluoric acid and 30% hydrogen peroxide (1:5) with agitation. Thereby the porous Si was etched and removed completely with the monocrystalline Si remaining unetched as an etch-stop material. The etching rate of the nonporous monocrystalline Si was extremely low, the selection ratio of the etching rate of the porous Si being, 10⁵ or higher. Therefore, the decrease in thickness of the nonporous layer by etching was practicably negligible (several tens of Å).

Consequently, a monocrystalline Si layer was formed in a thickness of 0.5 μm on a fused quartz substrate. The monocrystalline Si layer did not change at all by the selective etching of the porous Si layer.

The cross-section of the Si layer was observed by transmission electron microscopy, and it was confirmed that no additional crystal defect was formed in the Si layer and the excellent crystallinity was retained.

A plurality of SOI substrates having a semiconductor layer of high quality were prepared by repeating the above process in the same manner as in Example 1.

### EXAMPLE 3

A first monocrystalline (100) Si substrate of P-type or N-type having a diameter of 6 inches, a thickness of 625 μm, and a specific resistance of 0.01 Ω.cm was anodized in an HF solution under the anodization conditions as below:

| Current density: | 7 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for one hour. Thereby the inner wall of the pores of the porous Si was covered with a thermal oxidation film. On the porous Si, monocrystalline GaAs was allowed to grow epitaxially in a thickness of 1 μm by MOCVD (metal organic chemical vapor deposition) under the growth conditions below:

| | |
|---|---|
| Source gas: | TMG/AsH₃/H₂ |
| Gas pressure: | 80 Torr |
| Temperature: | 700° C. |

On the face of the formed GaAs layer, was superposed a separately prepared second Si substrate, and the superposed matter was heat-treated at 900° C. for one hour to bond the substrates tightly.

A sufficient compression force was applied to the resulting bonded wafer in the same manner as in Example 2. Thereby, the porous Si layer was broken to allow the wafer to separate into two sheets with the porous Si layers exposed.

Then, the oxide film on the inner wall of the porous Si layer was removed by hydrofluoric acid, and the porous Si was etched with a mixture of ethylene diamine, pyrocathecol, and water (17 ml:3 g:8 ml) at 110° C. Thereby the porous Si was etched selectively and removed completely with the monocrystalline GaAs remaining unetched as an etch-stopping material. The etching rate of the nonporous monocrystalline GaAs was extremely low and practicably negligible.

Consequently, a monocrystalline GaAs layer was formed in a thickness of 1 μm on a Si substrate. The monocrystalline GaAs layer did not change at all by the selective etching of the porous Si layer.

The cross-section of the GaAs layer was observed by transmission electron microscopy, and it was confirmed that no additional crystal defect was formed in the GaAs layer and the excellent crystallinity was retained.

A plurality of semiconductor substrates having a GaAs layer of high quality were prepared by repeating the above process in the same manner as in Example 2.

GaAs on an insulative film was also prepared by employing an Si substrate having an oxide film as the supporting substrate.

### EXAMPLE 4

A first monocrystalline (100) Si substrate of P-type or N-type having a diameter of 5 inches, a thickness of 625 μm, and a specific resistance of 0.01 Ω.cm was anodized in an HF solution under the anodization conditions as below:

| Current density: | 10 mA · cm⁻² |
|---|---|
| Anodization solution: | HF:H₂O:C₂H₅OH = 1:1:1 |
| Time: | 24 minutes |
| Thickness of porous Si: | 20 μm |
| Porosity: | 17% |

This substrate was oxidized at 400° C. in an oxygen atmosphere for 2 hours. Thereby the inner wall of the pores of the porous Si was covered with a thermal oxidation film. On the porous Si, monocrystalline AlGaAs was allowed to grow epitaxially in a thickness of 0.5 μm by MBE (molecular beam epitaxy).

On the face of the formed AlGaAs layer, was superposed a face of a separately prepared low-melting glass substrate. The superposed matter was heat-treated at 500° C. for 2 hours to bond the substrates tightly.

A sufficient compression force was applied to the resulting bonded wafer in the same manner as in Example 2. Thereby, the porous Si layer was broken to allow the wafer to separate into two sheets with the porous Si layers exposed.

The porous Si was etched with hydrofluoric acid solution. Thereby the porous Si was etched selectively and removed off completely with the monocrystalline AlGaAs remaining unetched as an etch-stopping material. The etching rate of the nonporous monocrystalline AlGaAs was extremely low and practicably negligible.

Consequently, a monocrystalline AlGaAs layer was formed in a thickness of 0.5 μm on a glass substrate. The monocrystalline AlGaAs layer did not change at all by the selective etching of the porous Si layer.

The cross-section of the AlGaAs layer was observed by transmission electron microscopy, and it was confirmed that no additional crystal defect was formed in the AlGaAs layer and the excellent crystallinity was retained.

A plurality of semiconductor substrates having a GaAs layer of high quality were prepared by repeating the above process in the same manner as in Example 2.

### EXAMPLE 5

A first monocrystalline (100) Si substrate of P-type or N-type having been polished on the both faces and having a diameter of 6 inches, a thickness of 625 μm, and a specific resistance of 0.01 Ω.cm was anodized on the both faces in an HF solution under the anodization conditions below:

| Current density: | 5 mA · cm⁻² |
|---|---|
| Anodization solution: | HF:H₂O:C₂H₅OH = 1:1:1 |
| Time: | 12 × 2 minutes |
| Thickness of porous Si: | 10 μm each |
| Porosity: | 15% |

This substrate was oxidized at 400° C. in an oxygen atmosphere for one hour. Thereby the inner wall of the pores of the porous Si was covered with a thermal oxidation film. On the porous Si formed on the both faces of the substrate, monocrystalline Si was allowed to grow epitaxially in a thickness of 1 μm respectively by CVD (chemical vapor deposition) under the growth conditions below:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

The faces of the formed epitaxial Si layers were thermally oxidized to form SiO₂ layers in a thickness of 100 nm.

On each of the faces of the SiO₂ layers, a separately prepared Si substrate having a 500-nm thick SiO₂ layer was superposed respectively with the SiO₂ layers inside, and the superposed matter was heat-treated at 600° C. for 2 hours to bond the substrates tightly.

A sufficient pulling force was applied to the resulting bonded wafer in the direction perpendicular to the bonded wafer face in the same manner as in Example 1. Thereby, the two porous Si layers were broken to allow the wafer to separate into three sheets with the porous Si layers exposed.

The porous Si layers were etched selectively with a mixture of 49% hydrofluoric acid with 30% hydrogen peroxide (1:5) with agitation. Thereby the porous Si was etched selectively and removed completely with the monocrystalline Si remaining unetched as an etch-stopping material. The etching rate of the nonporous monocrystalline Si was extremely low, the selection ratio of the etching rate of the porous Si being 10⁵ or higher. Therefore, the decrease in thickness of the nonporous layer by etching was practically negligible (several tens of Å).

Consequently, a monocrystalline Si layer was formed in a thickness of 1 μm respectively on the two Si oxide films simultaneously. The monocrystalline Si layers did not change at all by the selective etching of the porous Si layer.

The cross-section of the Si layer was observed by transmission electron microscopy, and it was confirmed that no additional crystal defect was formed in the Si layer and the excellent crystallinity was retained.

A plurality of semiconductor substrates having a semiconductor layer of high quality were prepared by repeating the above process in the same manner as in Example 1.

### EXAMPLE 6

A first monocrystalline (100) Si substrate of P-type or N-type having a diameter of 5 inches, a thickness of 625 μm, and a specific resistance of 0.01 Ω.cm was anodized in an HF solution under the anodization conditions below:

| Current density: | 7 mA · cm⁻² |
|---|---|
| Anodization solution: | HF:H₂O:C₂H₅OH = 1:1:1 |
| Time: | 4 minutes |
| Thickness of porous Si: | 3 μm |
| Porosity: | 15% |

The anodization was conducted further under the conditions below:

| Current density: | 30 mA · cm⁻² |
|---|---|
| Anodization solution: | HF:H₂O:C₂H₅OH = 1:3:2 |
| Time: | 3 minutes |
| Thickness of porous Si: | 10 μm |
| Porosity: | 45% |

This substrate was oxidized at 400° C. in an oxygen atmosphere for one hour. Thereby the inner wall of the pores of the porous Si was covered with a thermal oxidation film. On the porous Si formed on the substrate, monocrystalline Si was allowed to grow epitaxially in a thickness of 0.3 μm by CVD under the conditions below:

| | |
|---|---|
| Source gas: | SiH₄ |
| Carrier gas: | H₂ |
| Temperature: | 850° C. |
| Pressure: | 1 × 10⁻² Torr |
| Growth rate: | 3.3 nm/sec |

The surface of the formed epitaxial Si layer was thermally oxidized to form SiO₂ layer in a thickness of 100 nm.

On the face of the SiO₂ layer, a separately prepared second Si substrate having a 500-nm thick SiO₂ layer was superposed with the SiO₂ layer inside, and the superposed matter was heat-treated at 700° C. for 2 hours to bond the substrates tightly.

A sufficient pulling force was applied to the resulting bonded wafer in the direction perpendicular to the bonded wafer face in the same manner as in Example 1. Thereby, the porous Si layer was broken to allow the wafer to separate into two sheets with the porous Si layers exposed.

The porous Si on the second Si substrate was etched selectively with an etching solution of HF/HNO₂/CH₃COOH type. Thereby the porous Si was etched selectively and removed completely. The etching rate of the nonporous monocrystalline Si was extremely low, so that the thickness decrease of the nonporous layer by etching was practicably negligible.

Consequently, a monocrystalline Si layer was formed in a thickness of 1 μm on the Si oxide film. The monocrystalline Si layers did not change at all by the selective etching of the porous Si layer.

The cross-section of the Si layer was observed by transmission electron microscopy, and it was confirmed that no additional crystal defect was formed in the Si layer and the excellent crystallinity was retained. A plurality of semiconductor substrates having a semiconductor layer of high quality were prepared by repeating the above process in the same manner as in Example 1.

### EXAMPLE 7

A first monocrystalline (100) Si substrate of P-type or N-type having a diameter of 6 inches, a thickness of 625 μm, and a specific resistance of 0.01 Ω.cm was anodized in an HF solution under the anodization conditions below:

| Current density: | 5 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for one hour. Thereby the inner wall of the pores of the porous Si was covered with a thermal oxidation film. On the porous Si formed on the substrate, monocrystalline Si was allowed to grow epitaxially in a thickness of 1 μm by CVD under the growth conditions below:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

The surface of the formed epitaxial Si layer was thermally oxidized to form SiO₂ layer in a thickness of 100 nm.

On the face of the SiO₂ layer, a separately prepared second Si substrate having a 500-nm thick SiO₂ layer was superposed with the SiO₂ layer inside, and the superposed matter was heat-treated at 900° C. for 2 hours to bond the substrates tightly.

A sufficient pulling force was applied to the resulting bonded wafer in the direction perpendicular to the bonded wafer face in the same manner as in Example 1. Thereby, the porous Si layer was broken to allow the wafer to separate into two sheets with the porous Si layers exposed.

The porous Si layer on the second substrate was ground selectively by utilizing the monocrystalline layer as the stopper. Thereby the porous Si was removed selectively.

Consequently, a monocrystalline Si layer was formed in a thickness of 1 μm on the Si oxide film. The monocrystalline Si layers did not change at all by the selective grinding of the porous Si layer.

The cross-section of the Si layer was observed by transmission electron microscopy, and it was confirmed that no additional crystal defect was formed in the Si layer and the excellent crystallinity was retained.

A plurality of semiconductor substrates having a semiconductor layer of high quality were prepared by repeating the above process in the same manner as in Example 1.

### EXAMPLE 8

A first monocrystalline (100) Si substrate of P-type or N-type having a diameter of 6 inches, a thickness of 625 μm and a specific resistance of 0.01 Ω.cm was anodized in an HF solution under the anodization conditions below:

| Current density: | 5 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for one hour. Thereby the inner wall of the pores of the porous Si was covered with a thermal oxidation film. On the porous Si formed on the substrate, monocrystalline Si was allowed to grow epitaxially in a thickness of 1 μm by CVD under the conditions below:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

The surface of the formed epitaxial Si layer was thermally oxidized to form SiO₂ layer in a thickness of 100 nm.

On the face of the SiO₂ layer, a separately prepared second Si substrate having a 500-nm thick SiO₂ layer was superposed with the SiO₂ layer inside, and the superposed matter was heat-treated at 900° C. for 2 hours to bond the substrates tightly.

A supersonic energy was applied to the resulting bonded wafer in a vessel provided with a supersonic oscillator. Thereby, the porous Si layer was broken to allow the wafer to separate into two sheets with the porous Si layers exposed.

The porous Si layer on the second Si substrate was etched selectively with a mixture of 49% hydrofluoric acid with 30% hydrogen peroxide (1:5) with agitation. Thereby the porous Si was etched selectively and removed completely with the monocrystalline Si remaining unetched as an etch-stopping material. The etching rate of the nonporous monocrystalline Si was extremely low, the selection ratio of the etching rate of the porous Si being 10⁵ or higher. Therefore, the decrease in thickness of the nonporous layer by etching was practically negligible (several tens of Å).

Consequently, a monocrystalline Si layer was formed in a thickness of 1 μm on the Si oxide film. The monocrystalline Si layers did not change at all by the selective etching of the porous Si layer.

The cross-section of the Si layer was observed by transmission electron microscopy, and it was confirmed that no additional crystal defect was formed in the Si layer and the excellent crystallinity was retained.

The first monocrystalline Si substrate was used repeatedly for the same use after removal of the porous Si remaining thereon.

### EXAMPLE 9

A first monocryatalline (100) Si substrate of P-type or N-type having a diameter of 4 inches, a thickness of 525 μm, and a specific resistance of 0.01 Ω.m was anodized in an HF solution under the anodization conditions as below:

| Current density: | 7 mA · cm⁻² |
|---|---|
| Anodization solution: | HF:H₂O:C₂H₅OH = 1:1:1 |
| Time: | 12 minutes |
| Thickness of porous Si: | 10 μm |
| Porosity: | 15% |

This substrate was oxidized at 400° C. in an oxygen atmosphere for 2 hours. Thereby the inner wall of the pores of the porous Si was covered with a thermal oxidation film. On the porous Si, monocrystalline Si was allowed to grow epitaxially in a thickness of 0.5 μm by MBE (molecular beam epitaxy) under the growth conditions below:

| | |
|---|---|
| Temperature: | 700° C. |
| Pressure: | 1 × 10⁻⁹ Torr |
| Growth rate: | 0.1 nm/sec |
| Temperature: | 950° C. |
| Growth rate: | 0.3 μm/min |

The surface of the epitaxially grown Si layer was thermally oxidized to form an SiO₂ layer of 100 nm thick.

On the face of the SiO₂ layer, was superposed a separately prepared fused quartz substrate, and the superposed matter was heat-treated at 400° C. for 2 hours to bond the substrates.

The end of the porous layer was bared to the edge face of the wafer, and the porous Si is slightly etched. Thereto, a sharp blade like a shaver blade was inserted. Thereby, the porous layer was broken, and the wafer was separated into two sheets with the porous Si layers exposed.

The porous Si layer on the fused quartz substrate was etched selectively in a mixture of buffered hydrofluoric acid and 30% hydrogen peroxide (1:5) with agitation. Thereby the porous Si was etched and removed completely with the monocrystalline Si remaining unetched as an etch-stopping material. The etching rate of the nonporous monocrystalline Si was extremely low, the selection ratio of the etching rate of the porous Si being, 10⁵ or higher. Therefore, the decrease in thickness of the nonporous layer by etching was practically negligible (several tens of Å).

Consequently, a monocrystalline Si layer was formed in a thickness of 0.5 μm on a fused quartz substrate. The monocrystalline Si layer did not change at all by the selective etching of the porous Si layer.

The cross-section of the Si layer was observed by transmission electron microscopy, and it was confirmed that no additional crystal defect was formed in the Si layer and the excellent crystallinity was retained.

The same results were obtained without forming the oxide film of the surface of the epitaxial Si surface. The first monocrystalline Si substrate was used repeatedly for the same use after removal of the remaining porous Si and mirror-polishing of the surface.

### EXAMPLE 10

A first monocrystalline (100) Si substrate of P-type or N-type having a polished face on each side and having a diameter of 6 inches, a thickness of 625 μm and a specific resistance of 0.01 Ω.cm was anodized on both sides in an HF solution under the anodization conditions below:

| Current density: | 5 mA · cm⁻² |
|---|---|
| Anodization solution: | HF:H₂O:C₂H₅OH = 1:1:1 |
| Time: | 12 × 2 minutes |
| Thickness of porous Si: | 10 μm each |
| Porosity: | 15% |

This substrate was oxidized at 400° C. in an oxygen atmosphere for one hour. Thereby the inner wall of the pores of the porous Si was covered with a thermal oxidation film. On the porous Si formed on both faces of the substrate, monocrystalline Si was allowed to grow epitaxially in a thickness of 1 μm by CVD (chemical vapor deposition) under the conditions below:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

The surfaces of the formed epitaxial Si layers were thermally oxidized to form SiO₂ layers in a thickness of 100 nm.

On each of the faces of the SiO₂ layers, a separately prepared second Si substrate having a 500-nm thick SiO₂ layer was superposed with the SiO₂ layer inside, and the superposed matter was heat-treated at 600° C. for 2 hours to bond the substrates tightly.

The porous layers were bared at the edge face of the wafer, and a liquid such as water was allowed to penetrate into the porous Si. The entire bonded wafer was heated or cooled, whereby the porous Si layers were broken owing to expansion or other causes to allow the wafer to separate into three sheets with the porous Si layers exposed.

The porous Si layers were etched selectively with a mixture of 49% hydrofluoric acid with 30% hydrogen peroxide (1:5) with agitation. Thereby the porous Si was etched selectively and removed completely with the monocrystalline Si remaining unetched as an etch-stopping material. The etching rates of the nonporous monocrystalline Si was extremely low, the selection ratio of the etching rate of the porous Si being 10⁵ or higher. Therefore, the decrease in thickness of the nonporous layer by etching was practically negligible (several tens of Å).

Consequently, a monocrystalline Si layer was formed in a thickness of 1 μm respectively on the two Si oxide films simultaneously. The monocrystalline Si layers did not change at all by the selective etching of the porous Si layer.

The cross-section of the Si layer was observed by transmission electron microscopy, and it was confirmed that no additional crystal defect was formed in the Si layer and the excellent crystallinity was retained.

The same results were obtained without formation of the oxide film on the surface of the epitaxial Si layer.

The first monocrystalline Si substrate was used repeatedly for the same use after removal of the remaining porous Si and flattening of the surface by hydrogen treatment.

### EXAMPLE 11

A first monocrystalline (100) Si substrate of P-type or N-type having a diameter of 5 inches, a thickness of 625 μm, and a specific resistance of 0.01 Ω.cm was anodized in an HF solution under the anodization conditions below:

| Current density: | 7 mA · cm⁻² |
|---|---|
| Anodization solution: | HF:H₂O:C₂H₅OH = 1:1:1 |
| Time: | 4 minutes |
| Thickness of porous Si: | 3 μm |
| Porosity: | 15% |

The anodization was conducted further under the conditions below:

| Current density: | 30 mA · cm⁻² |
|---|---|
| Anodization solution: | HF:H₂O:C₂H₅OH = 1:3:2 |
| Time: | 3 minutes |
| Thickness of porous Si: | 10 μm |
| Porosity: | 45% |

This substrate was oxidized at 400° C. in an oxygen atmosphere for one hour. Thereby the inner wall of the pores of the porous Si was covered with a thermal oxidation film. On the porous Si formed on the substrate, monocrystalline Si was allowed to grow epitaxially in a thickness of 0.3 μm by CVD under the conditions below:

| | |
|---|---|
| Source gas: | SiH₄ |
| Carrier gas: | H₂ |
| Temperature: | 850° C. |
| Pressure: | 1 × 10⁻² Torr |
| Growth rate: | 3.3 nm/sec |

The surface of the formed epitaxial Si layer was thermally oxidized to form a SiO₂ layer in a thickness of 100 nm.

The porous Si layer was etched selectively with an HF/HNO₃/CH₃COOH type etching solution. Thereby the porous Si was etched selectively and removed completely. The etching rate of the nonporous monocrystalline Si was extremely low, so that the decrease in thickness of the nonporous layer by etching was practicably negligible.

Consequently, a monocrystalline Si layer was formed in a thickness of 1 μm on the Si oxide layer. The monocrystalline Si layer did not change at all by the selective etching of the porous Si layer.

The cross-section of the Si layer was observed by transmission electron microscopy, and it was confirmed that no additional crystal defect was formed in the Si layer and the excellent crystallinity was retained.

The same results were obtained without forming the oxide film on the surface of the epitaxial Si layer surface.

The first monocrystalline Si substrate was used repeatedly for the same use after removal of the remaining porous Si.

### EXAMPLE 12

A first monocrystalline (100) Si substrate of P-type or N-type having a diameter of 5 inches, a thickness of 625 μm, and a specific resistance of 0.01 Ω.cm was anodized in an HF solution under the anodization conditions below:

| Current density: | 7 mA · cm⁻² |
|---|---|
| Anodization solution: | HF:H₂O:C₂H₅OH = 1:1:1 |
| Time: | 4 minutes |
| Thickness of porous Si: | 3 μm |
| Porosity: | 15% |

The anodization was conducted further under the conditions below:

| Current density: | 30 mA · cm⁻² |
|---|---|
| Anodization solution: | HF:H₂O:C₂H₅OH = 1:3:2 |
| Time: | 3 minutes |
| Thickness of porous Si: | 10 μm |
| Porosity: | 45% |

This substrate was oxidized at 400° C. in an oxygen atmosphere for one hour. Thereby the inner wall of the pores of the porous Si was covered with a thermal oxidation film. On the porous Si formed on the substrate, monocrystalline Si was allowed to grow epitaxially in a thickness of 0.3 μm by CVD under the conditions below:

| | |
|---|---|
| Source gas: | SiH₄ |
| Carrier gas: | H₂ |
| Temperature: | 850° C. |
| Pressure: | 1 × 10⁻² Torr |
| Growth rate: | 3.3 nm/sec |

The surface of the formed epitaxial Si layer was thermally oxidized to form a SiO₂ layer in a thickness of 100 nm.

On the face of the SiO₂ layer, a separately prepared second Si substrate having a 500-nm thick SiO₂ layer was superposed with the SiO₂ layer inside, and the superposed matter was heat-treated at 700° C. for 2 hours to bond the substrates tightly.

The porous layers were bared at the edge face of the wafer, and the porous Si was etched from the edge face with a selective etching solution, whereby the wafer came to be separated into two sheets.

Further, the porous Si layer on the second Si substrate was etched selectively with an HF/HNO₃/CH₃COOH type etching solution. Thereby the porous Si was etched selectively and removed completely. The etching rate of the nonporous monocrystalline Si was extremely low, so that the thickness decrease of the nonporous layer by etching was practicably negligible.

Consequently, a monocrystalline Si layer was formed in a thickness of 1 μm on the Si oxide film. The monocrystalline Si layers did not change at all by the selective etching of the porous Si layer.

The cross-section of the Si layer was observed by transmission electron microscopy, and it was confirmed that no additional crystal defect was formed in the Si layer and the excellent crystallinity was retained.

The same results were obtained without forming the oxide film on the surface of the epitaxial Si layer surface.

The first monocrystalline Si substrate was used repeatedly for the same use after removal of the remaining porous Si.

A method is proposed in Japanese Patent Application No. 7-045441 for recycling the first substrate which is wasted in such a bonding method.

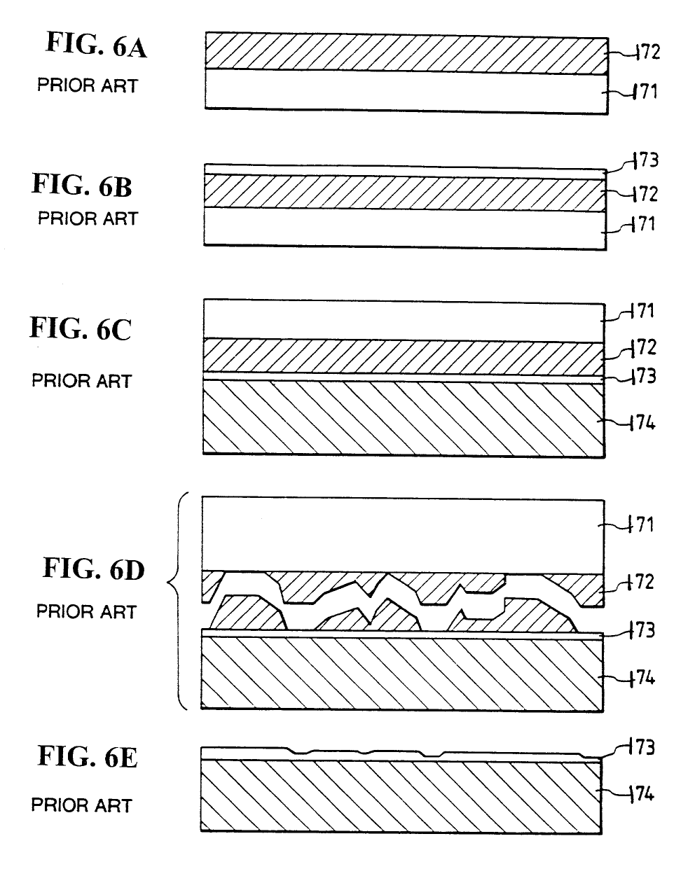

In this method, the following method is adopted, in the foregoing bonding and etch-back method using the porous Si, instead of the step for reducing in thickness the first substrate through grinding, etching or the like from the underside so as to expose the porous Si. This will be explained using FIGS. 6A to 6E.

After forming a porous surface layer 172 of an Si substrate 171 (FIG. 6A), a single-crystal Si layer 173 is formed thereon (FIG. 6B). Then, the single-crystal Si layer 173 along with the Si substrate 171 is bonded to a main surface of another Si substrate 174, working as a support substrate, via an insulating layer therebetween (FIG. 6C). Thereafter, the bonded wafers are separated at the porous layer 172 and the porous Si layer 172 exposed on the surface at the side of the Si substrate 174 is selectively removed so that the SOI substrate is formed. Separation of the bonded wafers is performed, for example, a method selected from the following methods that the tensile force or pressure is sufficiently applied to the bonded wafers perpendicularly relative to an in-plane and uniformly over in-plane; that the wave energy such as the ultrasonic wave is applied; that the porous layer is exposed at the wafer end surfaces, the porous Si is etched to some extent, and what is like a razor blade is inserted thereinto; that the porous layer is exposed at the wafer end surfaces and a liquid such as water is impregnated into the porous Si, and the whole bonded wafers are heated or cooled so as to expand the liquid. Alternatively, separation is performed by applying the force to the Si substrate 171 in parallel to the support substrate 174.

Each of these methods is based on the fact that, although the mechanical strength of the porous Si layer 172 differs depending on the porosity, it is considered to be much weaker than the bulk Si. For example, if the porosity is 50%, the mechanical strength can be considered to be half the bulk. Specifically, when a compressive, tensile or shear force is applied to the bonded wafers, the porous Si layer is first ruptured. As the porosity is increased, the porous layer can be ruptured with a weaker force.

However, if the porosity of porous silicon is increased, it is possible that distortion is introduced due to the ratio of bulk silicon relative to the lattice constant being increased so as to increase warpage of the wafer. As a result, the following problems may be raised, that is, the number of void bonding failure regions, called voids is increased upon bonding, the crystal defect density is increased and, in the worst case, cracks are introduced into the epitaxial layer, and slip lines are introduced on the periphery of the wafer due to the influence of thermal distortion upon the epitaxial growth.

When applying the force in the vertical or horizontal direction relative to the surface of the wafer, since the semiconductor substrate is not a fully rigid body but an elastic body, the wafer may be subjected to elastic deformation depending on a supporting fashion of the wafer so that the force escapes and thus is not applied to the porous layer effectively. Similarly, when inserting what is like a razor blade from the wafer end surface, unless the razor blade is fully thin and fully high in rigidity, the yield may be lowered.

Further, if the bonding strength at the bonded interface is weaker as compared with the strength of the porous Si layer or if weak portions exist locally, the two wafers may be separated at the bonded interface so that the initial object cannot be achieved.

Further, since, in any of the methods, the position where separation occurs in the porous layer is not fixed, if the ratio in etching speed between the porous Si and the bulk Si is not sufficient, the epitaxial silicon layer is first etched more or less at a portion where the porous layer remains thin rather than at a portion where the porous layer remains thick. Thus, the thickness uniformity of the SOI layer may deteriorate. Particularly, when the final thickness of the SOI layer is reduced to about 100 nm, the thickness uniformity is deteriorated so that a problem may result when forming the element, such as the fully depleted MOSFET, whose threshold voltage is sensitive to the film thickness.

Japanese Patent Application No. 5-211128 (corresponding to U.S. Pat. No. 5,374,564) discloses a method for producing the SOI. In this method, hydrogen ions are directly implanted into a single-crystal Si substrate, and then the single-crystal Si substrate and a support substrate are bonded together. Finally, the single-crystal Si substrate is separated at a layer where hydrogen ions are implanted, so as to form the SOI. In this method, since hydrogen ions are directly implanted into the single-crystal Si substrate which is then separated at the ion-implanted layer, the flatness of the SOI layer is not good. Further, the thickness of the SOI layer is determined by the projection range, so that the degree of freedom of the thickness is low. Further, it is necessary to select an implanting condition satisfying both the layer thickness and the separation, which creates a difficulty in control. Further, in case of aiming at obtaining a thin layer, the thickness of which cannot be determined by the ion implantation, it is necessary to carry out a reducing process in thickness such as grinding and etching, which process is nonselective, so that there is a fear of deteriorating uniformity of the thickness.

In view of the foregoing, a method has been demanded for producing, with high reproducibility, a high quality SOI substrate and whose SOI layer is extremely flat, while simultaneously saving resources and reducing costs through recycling of the wafer.

On the other hand, in general, on a light transmittable substrate, typically glass, the deposited thin Si layer only becomes amorphous or polycrystalline at best, reflecting disorderliness in crystal structure of the substrate, so that a high-performance device cannot be produced. This is due to the crystal structure of the substrate being amorphous, and thus an excellent single-crystal layer cannot be achieved by merely depositing the Si layer.

The light transmittable substrate is important for constituting a contact sensor as being a light-receiving element or a projection-type liquid-crystal image display device. To achieve further densification, higher resolution and increased fineness of picture elements of the sensor or the display device, a high-performance drive element is required. As a result, it is necessary to produce the element on the light transmittable substrate using the single-crystal layer having an excellent crystalline property.

Further, when using the single-crystal layer, reduction in size and acceleration of a chip can be achieved by incorporating a peripheral circuit for driving the picture elements and an image processing circuit into the same substrate having the picture elements.

Specifically, in case of amorphous Si or polycrystalline Si, it is difficult, due to its defective crystal structure, to produce the drive element having the performance which is required or will be required in the future.

On the other hand, to produce the compound semiconductor device, the substrate of the compound semiconductor is essential. However, the compound semiconductor substrate is expensive and further is very difficult to increase in area.

An attempt has been made to achieve the epitaxial growth of the compound semiconductor such as GaAs on the Si substrate. However, due to differences in lattice constant or thermal expansion coefficient, the grown film is poor in crystalline property and thus is very difficult to apply to the device.

Further, an attempt has been made to achieve the epitaxial growth of the compound semiconductor on porous Si to reduce misfit of the lattice. However, due to low thermostability and age deterioration of porous Si, its stability and reliability are poor as the substrate during or after production of the device. However, there is a problem that the compound semiconductor substrate is expensive and low in mechanical strength so that the large-area wafer is difficult to produce.

In view of the foregoing, an attempt has been made to achieve the heteroepitaxial growth of a compound semiconductor on a Si wafer which is inexpensive and high in mechanical strength so that a large-area wafer can be produced.

Recently, attention has been given to porous silicon as a luminescent material for photoluminescence, electroluminescence or the like, and many research reports have been made. In general, the structure of porous silicon largely differs depending on the type (p, n) and the concentration of impurities contained in the silicon. When the p-type impurities are doped, the structure of porous silicon is roughly divided into two kinds depending on whether the impurity concentration is no less than 10¹⁸/cm³ or no more than 10¹⁷/cm³. In the former case, the pore walls are relatively thick, that is, from several nanometers to several tens of nanometers, the pore density is about 10¹¹/cm² and the porosity is relatively low. However, it is difficult for this porous silicon to luminesce. On the other hand, in the latter case, as compared with the former case, porous silicon whose pore wall is no more than several nanometers in thickness, whose pore density is greater by one figure order of magnitude and whose porosity exceeds 50%, can be easily formed. Most luminous phenomena, such as photoluminescence, are mainly based on the formation of porous silicon using the latter as a starting material. However, the mechanical strength is low due to the large porosity. Further, since a lattice constant deviation relative to bulk Si is as much as 10⁻³ (about 10⁴ in the former case), there has been a problem that, when epitaxial-growing the single-crystal silicon layer on such porous silicon, defects are largely introduced into the epitaxial Si layer and cracks are further introduced thereinto. On the other hand, for utilizing the fine porous structure, which is suitable for a luminescent material, as a luminescent element, it has been desired that the epitaxial Si layer be formed on porous silicon for providing a contact or the MOSFET or the like as a peripheral circuit to be formed on the epitaxial silicon layer.

The present invention simultaneously solves the foregoing various problems by superposing a finer porous structure in the foregoing porous layer.

It has been reported that, by performing ion implantation of helium or hydrogen into bulk silicon and applying heat thereto, micro-cavities having diameters in the range from several nanometers to several tons of nanometers are formed at the implanted region in the density of as much as 10¹⁶ to 10¹⁷/cm³ (for example, A. Van Veen, C.C. Griffioen, and J. H. Evans, Mat. Res. Soc. Symp. Proc. 107 (1988, Material Res. Soc. Pittsburgh, Pa.) p. 449). Recently, utilizing these micro-cavity groups as gettering sites of metal impurities has been investigated.

V. Raineri and S. U. Campisano implanted helium ions into bulk silicon and applied a heat treatment thereto to form the cavity groups, then exposed the sides of the cavity groups by forming grooves in the substrate and applied an oxidation treatment thereto. As a result, the cavity groups were selectively oxidized to form a buried silicon oxide layer. That is, they reported that the SOI structure could be formed (V. Raineri and S. U. Campisano, Appl. Phys. Lett. 66 (1995) p. 3654). However, in their method, thicknesses of the surface silicon layer and the buried silicon oxide layer were limited to achieve both formation of the cavity groups and relaxation of stresses introduced due to volume expansion upon oxidation and further the formation of the grooves were necessary for selective oxidation so that the SOI structure could not be formed all over the substrate. Such formation of the cavity groups has been reported as a phenomenon following the implantation of light elements into metal along with an expansion or separation phenomenon of the cavity groups as a part of the research about a first reactor wall of the nuclear fusion reactor.

Porous Si was found in the course of the research of electropolishing of the semiconductor in 1956 by Uhlir and collaborator (A. Uhlir, Bell Syst. Tech. J., vol. 35, 333 (1956)). Porous silicon can be formed by anodizing the Si substrate in the HF solution. Unagami and collaborator researched the dissolution reaction of Si in the anodization and reported that positive holes were necessary for the anodizing reaction of Si in the HF solution and the reaction was as follows (T. Unagami, J. Electrochem. Soc., vol. 127, 476 (1980)):

Si+2HF+(2−n)e⁺→SiF₂+2H⁺+ne⁻

SiF₂+2HF→SiF₄+H₂

SiF₄+2HF→H₂SiF₆

or

Si+4HF+(4−λ)e⁺→SiF₄+4H⁺+λe⁻

SiF₄+2HF→H₂SiF₆

wherein e⁺ and e⁻ represent a hole and an electron, respectively, and n and λ represent the numbers of holes necessary for dissolution of one Si element, respectively. It was reported that porous Si was formed when n>2 or λ>4 was satisfied.

As appreciated from the foregoing, p-type Si having the holes is rendered porous while n-type Si is not rendered porous. The selectivity while getting porous has been proved by Nagano and collaborators and Imai (Nagano, Nakajima, Yasuno, Oonaka, Kajiwara, Engineering Research Report of Institute of Electronics and Communication Engineers of Japan, vol. 79, SSD799549 (1979)), (K. Imai, Solid-State Electronics, vol. 24, 159 (1981)).

However, there have also been reports that high-concentration n-type Si can be rendered porous (R. P. Holmstrom and J. Y. Chi, Appl. Phys. Lett., vol. 42, 386 (1983)) so that it is important to choose the substrate which can be rendered porous, irrespective of p- or n-type.

Porous silicon can be formed by anodizing the Si substrate in the HF solution. The porous layer has a structure like sponge including holes of about 10⁻¹ to 10 nm in diameter arranged at intervals of about 10⁻¹ to 10 nm. The density thereof can be changed in the range of 1.1 to 0.6 g/cm³ by changing the HF solution concentration in the range of 50 to 20% and by changing the current density, as compared with the density 2.33 g/cm³ of the single-crystal Si. That is, the porosity can be changed. Although the density of porous Si is no more than half as compared with the single-crystal Si as described above, the monocrystalline property is maintained so that the single-crystal Si layer can be epitaxially grown at the upper part of the porous layer. However, at a temperature not less than 1,000° C., rearrangement of the internal holes occurs to spoil the accelerating etching characteristic. In view of this, it has been said that the low temperature growth, such as molecular beam epitaxial growth, plasma CVD, vacuum CVD, optical CVD, bias sputtering or liquid deposition, is suitable for the epitaxial growth of the Si layer. On the other hand, if a protective film is formed in advance on the pore walls of the porous layer by means of the method of low temperature oxidation or the like, high temperature growth is also possible.

Further, the porous layer is reduced in density to no more than half due to the formation of a lot of the internal cavities therein. As a result, since the surface area is greatly increased as compared with the volume, the chemical etching speed thereof is extremely increased as compared with the etching speed of the normal single-crystal layer.

Although the mechanical strength of porous Si differs depending on porosity, it is considered to be smaller than that of bulk Si. For example, if porosity is 50%, the mechanical strength can be considered to be half the bulk. Specifically, when a compressive, tensile or shear force is applied to the bonded wafers, the porous Si layer is ruptured first. As the porosity is increased, the porous layer can be ruptured with a weaker force.

The present invention simultaneously solves the foregoing various problems by superposing a finer porous structure in the foregoing porous layer.

It has been found that, when ion implantation of at least one kind of noble gas, hydrogen and nitrogen is performed into the porous layer with a projection range ensured, the porosity of the implanted region is increased. When observing in detail the implanted layer using an electron microscope, a lot of micro-cavities were formed in the pore walls of the porous layer formed in advance. Specifically, the fine porous structure was formed. Upon irradiation of ultraviolet light, the luminous phenomenon at the wavelength around 700 nm was confirmed.

If choosing further implantation conditions, porous silicon can be separated at a depth corresponding to the projection range of the ion implantation.

The separation can be improved in uniformity or achieved with less implantation amount by forming in advance a thin film on the pore walls of porous silicon using the method of particularly low temperature oxidation. The separation can be facilitated by applying the heat treatment after the ion implantation.

By ion-implanting at least one kind of noble gas, hydrogen and nitrogen into the porous layer with a projection range ensured after formation of at least one layer of non-porous film, such as a non-porous single-crystal silicon layer, on porous silicon or without such formation, the porosity of the implanted layer is increased. If such a Si substrate is bonded to the support substrate and then the bonded substrates are subjected to the mechanical force or the heat treatment, or even without such processes, the two bonded substrates can be separated into two at a portion of the porous silicon layer where ions are implanted.

By supporting both sides of the ion-implanted layer with a fully thick elastic or rigid body, the separation can be achieved uniformly over a large area. Further, it is possible to facilitate the separation of the substrates by applying heat treatment, force or ultrasonic waves to the substrates.

Even if non-formation regions of the implanted layer are formed due to presence of the foreign matter on the surface upon the ion implantation, since the mechanical strength of the porous layer itself is smaller than bulk Si, separation occurs in the porous layer. Thus, the two bonded substrates can be separated without causing cracks or lines in the non-porous single-crystal Si layer. In other words, the phenomenon of the separation can be selected by selecting timing for the manifestation from the time of implantation and the time of heat treatment; and a condition of implantation such as an amount of implanted beam and energy thereof. Further, the layer having a large porosity may be formed at a region of a constant depth from the surface of the porous layer by controlling the condition at anodization.

Further, by selectively removing the porous Si layer remaining on the surface of the separated substrate using the method of etching, polishing or the like, the single-crystal Si layer is exposed on the support substrate. on the other hand, after removing the remaining porous Si, the Si substrate can be again formed with porous silicon, then formed with a single-crystal Si layer and subjected to the ion implantation of at least one kind of noble gas, hydrogen and nitrogen into the porous layer with the projection range ensured, and then bonded to a support substrate. That is, the Si substrate can be recycled. Further, if the Si substrate, with the porous silicon layer remaining, is subjected to heat treatment in the reducing atmosphere including hydrogen or the like, the porous silicon surface is rendered flat and smooth so that the single-crystal silicon layer can be formed successively. By bonding the single-crystal silicon layer to the support substrate, the Si substrate can also be recycled.

According to this method, since the portion to be separated is limited to the ion-implanted region in the porous layer, the depth of the separated region is not dispersed in the porous layer. Thus, even if the ratio for selectively etching porous silicon is insufficient, porous silicon can be removed for substantially a constant time so that the uniformity of the thickness of the single-crystal silicon layer provided on the support substrate is not spoiled.

In the conventional method of producing the bonded substrates, the Si substrate is gradually removed from one side thereof through grinding or etching. Thus, it is impossible to effectively use both sides of the Si substrate for bonding to the support substrate. On the other hand, according to the present invention, the Si substrate is held in the initial state other than its surface layers so that, by using both sides of the Si substrate as the main surfaces and bonding the support substrates to the sides of the Si substrate, respectively, two bonded substrates can be simultaneously produced from one Si substrate. As appreciated, also in this case, the Si substrate can be recycled as an Si substrate after removing the remaining porous Si.

The support substrate may be, for example, a light transmittable substrate, such as a Si substrate, a Si substrate with a silicon oxide film formed thereon, a silica glass substrate or a glass substrate, or a metal substrate, but not particularly limited thereto.

The thin film formed on the porous Si layer on the Si substrate may be, for example, a non-porous single-crystal Si film, a compound semiconductor film such as GaAs or InP, a metal film or a carbon film, but not particularly limited thereto. Further, the thin film is not necessarily formed all over the porous Si layer, but may be partially etched by the patterning process.

[Embodiment 6]

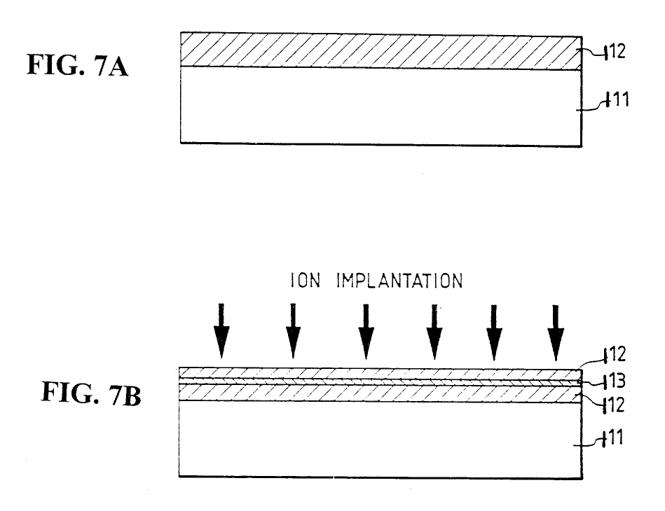

As shown in FIG. 7A, a Si single-crystal substrate 111 is first prepared and then rendered porous at its surface layer. Numeral 112 denotes the resulting porous layer. As shown in FIG. 7B, at least one kind of noble gas, hydrogen and nitrogen is ion-implanted into the porous layer 112. Then, a porous layer 113 having large porosity is formed in the porous layer 112. The charge condition of the implanted ions is not particularly limited. The acceleration energy is set such that the projection range corresponds to a depth at which the ion implantation is desired. Depending on the implantation amount, the size and the density of the micro-cavities to be formed are changed, but approximately no less than 1×10¹³/cm² and more preferably 1×10¹⁴/cm². When setting the projection range to be deeper, the channeling ion implantation may be employed. After the implantation, heat treatment is performed if necessary. In the case of the heat treatment atmosphere being an oxidizing atmosphere, the pore walls are oxidized so that attention should be given to prevent the Si region from being all changed into silicon oxide due to overoxidation.

When the light of a mercury lamp, a xenon lamp or the like is applied to the thus produced sample as the light of shorter wavelength, the sample emits the red light around 780 nm. That is, the photoluminescence is confirmed. Or an EL (Electroluminescence) element can be formed.

In FIG. 7B, the semiconductor substrate of the present invention is shown. The layer 113 is the porous Si layer with the large porosity obtained as the result of the foregoing ion implantation. The fine porous structure showing the luminous phenomenon is formed uniformly in a large area all over the wafer. Further, the metallic luster is held on the surface, that is, not showing the stained manner as in the prior art, so that metallic wiring can be easily arranged.

Embodiment 7

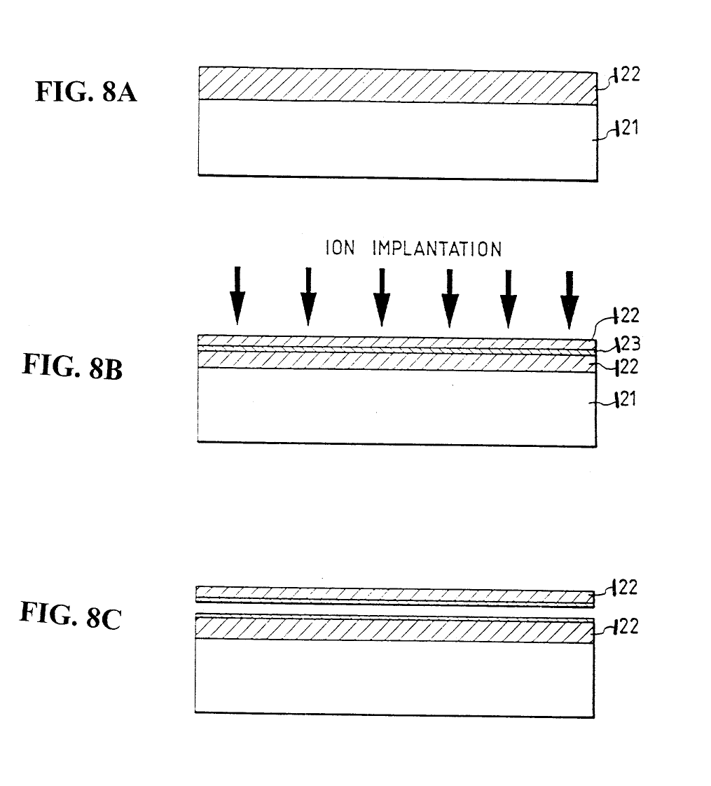

As shown in FIG. 8A, a Si single-crystal substrate 121 is first prepared and then rendered porous at its surface layer. Numeral 122 denotes the resulting porous layer. As shown in FIG. 8B, at least one kind of noble gas, hydrogen and nitrogen is ion-planted into the porous layer 122. Then, a porous layer (ion-implanted layer) 123 having large porosity is formed in the porous layer 122. The charge condition of the implanted ions is not particularly limited. The acceleration energy is set such that the projection range corresponds to a depth at which the ion implantation is desired. Depending on the implantation amount, the size and the density of the micro-cavities to be formed are changed, but approximately no less than 1×10¹⁴/cm² and more preferably 1×10¹⁵/cm². When setting the projection range to be deeper, the channeling ion implantation may be employed. After the implantation, the heat treatment is performed or at least one of compressive, tensile and shear stresses is applied to the wafer in a direction perpendicular to the surface as necessary, so as to divide the semiconductor substrate into two at the ion-implanted layer as a border. In the case of the heat treatment atmosphere being an oxidizing atmosphere, the pore walls are oxidized so that attention should be given to preventing the Si region from being all changed into silicon oxide due to over-oxidation.

In FIG. 8C, the extremely thin porous substrate obtained by the present invention is shown. Since the division of the substrate starts spontaneously upon the heat treatment or the like as a trigger due to the internal stress introduced upon the implantation, the extremely thin porous structure can be formed uniformly all over the substrate. The pores of the porous structure are formed from one main surface of the substrate toward the other main surface. Accordingly, when the gas is implanted under pressure from the one main surface, it is ejected out from the other main surface. In this case, since the pore size of the porous structure is in the range from several nanometers to several tens of nanometers, a particle greater than this cannot pass therethrough. On the other hand, although pressure loss is caused depending on the pore size, the pore density and a thickness of the extremely thin porous substrate, the strength of the substrate and the pressure loss can be both within the practical range if the thickness of the porous layer is approximately no more than 20 μm.

Embodiment 8

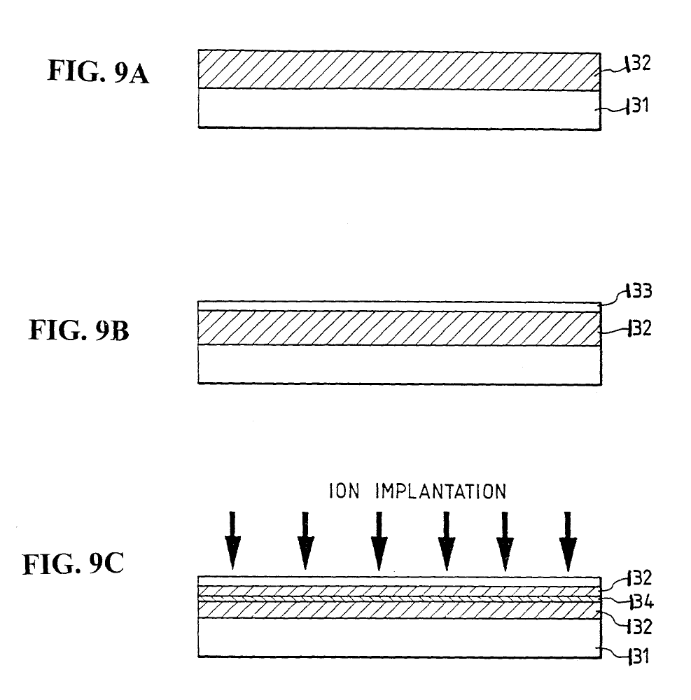

As shown in FIG. 9A, a Si single-crystal substrate 131 is first prepared and then rendered porous at its surface layer. Numeral 132 denotes the resulting porous layer. Subsequently, as shown in FIG. 9B, at least one layer 133 is formed on the porous layer. The film to be formed is arbitrarily selected from among a single-crystal Si film, a polycrystalline Si film, an amorphous Si film, a metal film, a compound semiconductor film, a superconductive film and the like.

As shown in FIG. 9C, at least one kind of noble gas, hydrogen and nitrogen is ion-implanted into the porous layer 132. Then, a porous layer 134 having large porosity is formed in the porous layer 132. The charge condition of the implanted ions is not particularly limited. The acceleration energy is set such that the projection range corresponds to a depth at which the ion implantation is desired. Depending on the implantation amount, the size and the density of the micro-cavities to be formed are changed, but approximately no less than 1×10¹⁴/cm² and more preferably 1×10¹⁵/cm². When setting the projection range to be deeper, the channeling ion implantation may be employed. After the implantation, heat treatment is performed as necessary. In the case of the heat treatment atmosphere being the oxidizing atmosphere, the pore walls are oxidized so that attention should be given to preventing the Si region from being all changed into silicon oxide due to overoxidation.

When the light of a mercury lamp, a xenon lamp or the like is applied to the thus produced sample as the light of shorter wavelength, the sample emits the red light around 780 nm. That is, the photoluminescence is confirmed. Or an EL element can be formed.

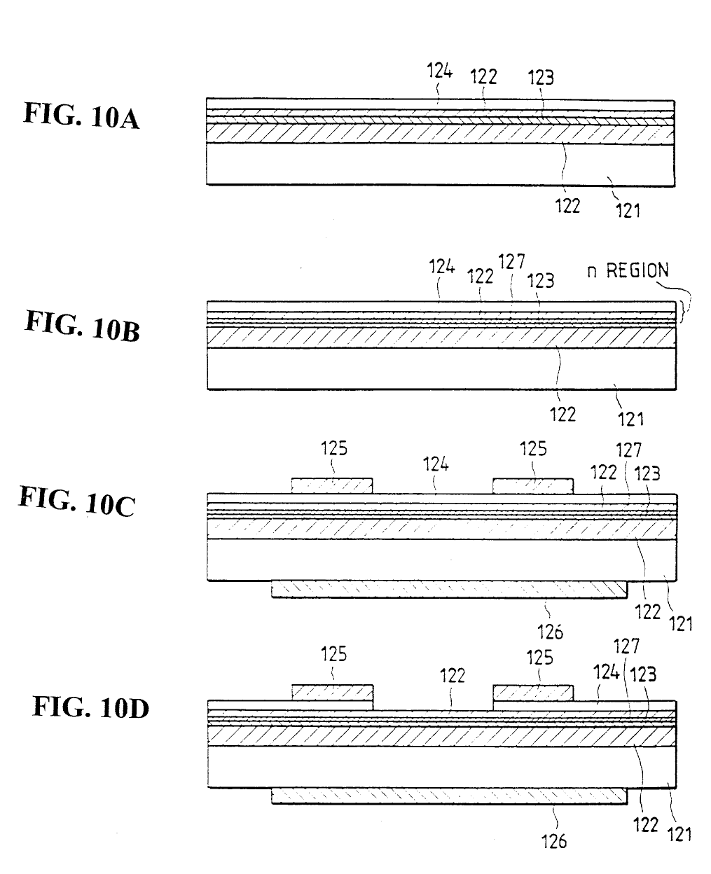

The EL element shown in FIGS. 10A-10B is realized by forming a construction where a voltage is applied to a porous layer having a large porosity formed in the porous layer by means of ion implantation and so forth. For example, when turning p+substrate 121 porous, the EL element is realized by implanting phospho-ion and so forth in porous layer 122 including porous layer 123 having a large porosity from the surface in a manner of making the ion reach a region of a constant depth from the surface, or by diffusing the ion by means of heat diffusion etc., to form a p-n junction in porous layer 123 having a large porosity or in the neighborhood thereof. A portion 127 is an n-region of the porous layer having a large porosity, which region is obtained as a result of the above-mentioned process.

Electrodes 125 and 126 are secured with the substrate and the surface of the porous portion. The electrodes may be formed in the side of the surface of the porous portion by a process comprised of forming epitaxial Si layer 124 on the porous portion prior to the formation of the electrode and then forming the electrode thereon (see FIG. 10C). Further, as shown in FIG. 10D, the epitaxial Si layer may be removed partly as the occasion demands so as to facilitate the penetration of the light of the EL.

In FIG. 3B, the semiconductor substrate of the present invention is shown. The fine porous structure showing the luminous phenomenon is formed uniformly in a large area all over the wafer. Further, the metallic luster is held on the surface, that is, not showing the cracks or the like as in the prior art, so that metallic wiring can be easily arranged.

Embodiment 9

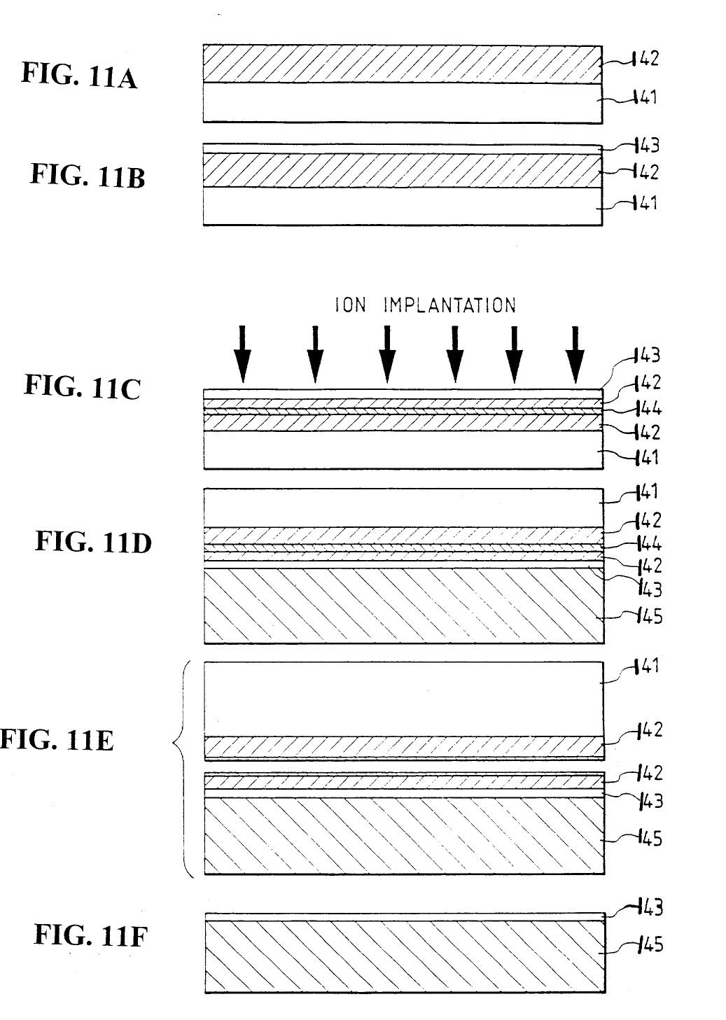

As shown in FIG. 11A, a Si single-crystal substrate 141 is first prepared and then rendered porous at its surface layer. Numeral 142 denotes the resulting porous layer. Subsequently, as shown in FIG. 11B, at least one non-porous thin film 143 is formed on the porous layer. The film to be formed is arbitrarily selected from among a single-crystal Si film, a polycrystalline Si film, an amorphous Si film, a metal film, a compound semiconductor film, a superconductive film and the like. Or an element structure such as a MOSFET may be formed.

As shown in FIG. 11C, at least one kind of noble gas, hydrogen and nitrogen is ion-implanted into the porous layer 142 so as to form an implanted layer 144. When observing the implanted layer by a transmission electron microscope, formation of numberless micro-cavities can be seen. The charge condition of the implanted ions is not particularly limited. The acceleration energy is set such that the projection range corresponds to a depth at which the ion implantation is desired. Depending on the implantation amount, the size and the density of the micro-cavities to be formed are changed, but approximately no less than 1×10¹⁴/cm² and more preferably 1×10¹⁵/cm². When setting the projection range to be deeper, the channeling ion implantation may be employed. After the implantation, the heat treatment is performed as necessary. In case of the heat treatment atmosphere being the oxidizing atmosphere, the pore walls are oxidized so that attention should be given to preventing the Si region from being all changed into silicon oxide due to overoxidation.

As shown in FIG. 11D, after abutting a support substrate 145 and the surface of the first substrate with each other at room temperature, they are bonded to each other through anodic bonding, pressurization, heat treatment or a combination thereof. As a result, both substrates are firmly coupled with each other.

When single-crystal Si is deposited, it is preferable to perform the bonding after oxidized Si is formed on the surface of single-crystal Si through thermal oxidation or the like. On the other hand, the support substrate can be selected from among a Si substrate, a Si substrate with a silicon oxide film formed thereon, a light transmittable substrate such as quartz, a sapphire substrate and the like, but not limited thereto as long as the surface serving for the bonding is fully flat. The bonding may be performed in three plies with an insulating thin plate interposed therebetween.

Subsequently, the substrates are divided at the ion-implanted layer 144 in the porous Si layer 142 (FIG. 11E). The structure of the second substrate side includes the porous Si layer 142, the non-porous thin film (for example, the single-crystal Si layer) 143 and the second substrate 145.

Further, the porous Si layer 142 is selectively removed. In case of the non-porous thin film being single-crystal Si, only the porous Si layer 142 is subjected to the electroless wet chemical etching using at least one of the normal Si etching liquid, hydrofluoric acid being the porous Si selective etching liquid, a mixed liquid obtained by adding at least one of alcohol and aqueous hydrogen peroxide to hydrofluoric acid, buffered hydrofluoric acid, and a mixed liquid obtained by adding at least one of alcohol and aqueous hydrogen peroxide to buffered hydrofluoric acid, so as to render the film formed in advance on the porous layer of the first substrate remaining on the second substrate. As described above in detail, only the porous Si layer can be selectively etched using the normal Si etching liquid due to the extensive surface area of porous Si. Alternatively, the porous Si layer 142 may be removed through selective polishing using the single-crystal Si layer as a polishing stopper.

In the case where the compound semiconductor layer is formed on the porous layer, only the porous Si layer 142 is subjected to chemical etching using the etching liquid which has the greater etching speed for Si relative to the compound semiconductor, so that the thickness-reduced single-crystal compound semiconductor layer 143 remains on the insulating substrate 145. Alternatively, the porous Si layer 142 is removed through selective polishing using the single-crystal compound semiconductor layer 143 as a polishing stopper.

In FIG. 11F, the semiconductor substrate of the present invention is shown. On the insulating substrate 145, the non-porous thin film, such as the single-crystal Si thin film 143, is formed in a large area all over the wafer, flatly and uniformly reduced in thickness. The semiconductor substrate thus obtained can be suitably used in production of an insulated electronic element.

The Si single-crystal substrate 141 can be reused as a Si single-crystal substrate 141 after removing any remaining porous Si and after performing surface-flattening if the surface flatness makes the substrate unusable.

Alternatively, a non-porous thin film may be again formed without removing porous Si so as to provide the substrate as shown in FIG. 11B, which is then subjected to the processes shown in FIGS. 11C to 11F.

Embodiment 10

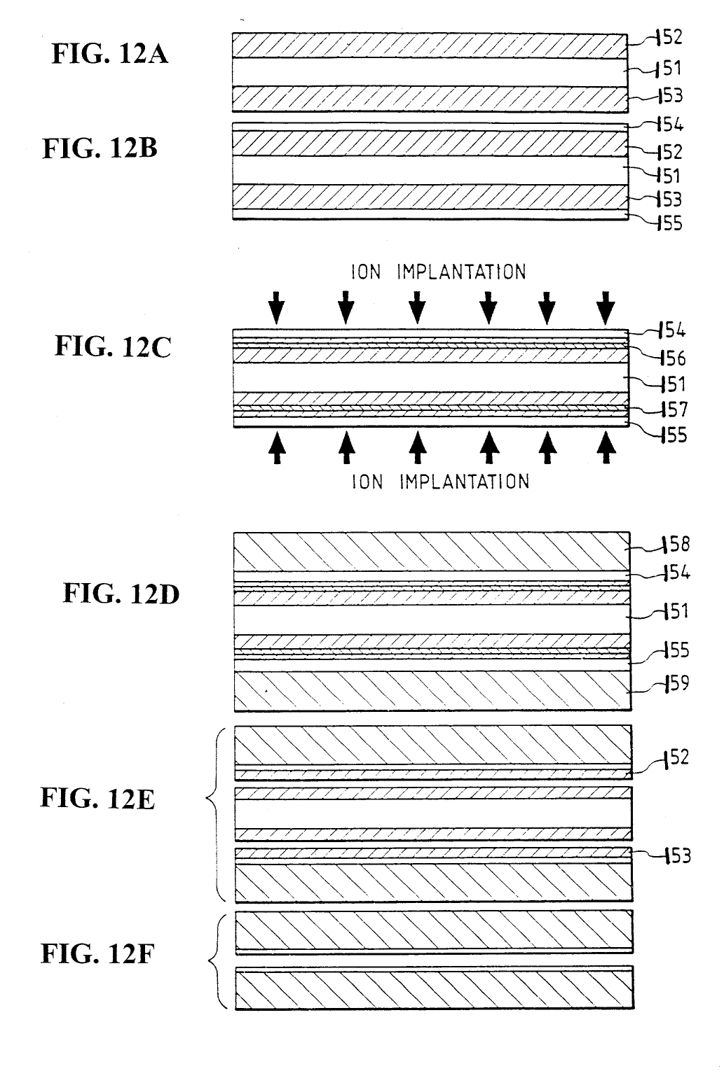

As shown in FIG. 12A, a Si single-crystal substrate 151 is first prepared and then rendered porous at both surface layers thereof. Numerals 152 and 153 denote the obtained porous layers. Subsequently, as shown in FIG. 12B, at least one non-porous thin film 154, 155 is formed on each of the porous layers. The film to be formed is arbitrarily selected from among a single-crystal Si film, a polycrystalline Si film, an amorphous Si film, a metal film, a compound semiconductor film, a superconductive film and the like. Or an element structure such as a MOSFET may be formed.

As shown in FIG. 12C, at least one kind of noble gas, hydrogen and nitrogen is ion-implanted into the porous layers 152 and 153 so as to form implanted layers 156 and 157. When observing the implanted layers by a transmission electron microscope, formation of numberless micro-cavities can be seen, and accordingly the porosity enlarges. The charge condition of the implanted ions is not particularly limited. The acceleration energy is set such that the projection range corresponds to a depth at which the ion implantation is desired. Depending on the implantation amount, the size and the density of the micro-cavities to be formed are changed, but they are approximately no less than 10¹⁴/cm² and more preferably 1×10^{15/cm}². When setting the projection range deeper, channeling ion implantation may be employed. After the implantation, heat treatment is performed as necessary. In the case of the heat treatment atmosphere being an oxidizing atmosphere, the pore walls are oxidized so that attention should be given to preventing the Si region from being all changed into silicon oxide due over oxidation.

As shown in FIG. 12D, after abutting two support substrates 158 and 159 and the surfaces of the non-porous thin films 154 and 155 of the first substrate with each other at room temperature, they are bonded to each other through anode bonding, pressurization, heat treatment or a combination thereof. As a result, the three substrates are firmly coupled with each other.

Alternatively, the bonding may be performed in five plies with insulating thin plates interposed therebetween.

When single-crystal Si is deposited, it is preferable to perform the bonding after oxidized Si is formed on the surface of single-crystal Si through thermal oxidation or the like. On the other hand, the support substrate can be selected from among a Si substrate, a Si substrate with a silicon oxide film formed thereon, a light transmittable substrate such as quartz, a sapphire substrate and the like, but not limited thereto as long as the surface serving for the bonding is completely flat.

The bonding may be performed in three plies with an insulating thin plate interposed therebetween.

Subsequently, the substrates are divided at the ion-implanted layers 156 and 157 in the porous Si layers 152 and 153 (FIG. 12E). The structure of each of the two support substrate sides includes the porous Si layer 152, 153, the non-porous thin film (for example, the single-crystal Si layer) 154, 155 and the support substrate 158, 159.

Further, the porous Si layer 152, 153 is selectively removed. In case of the non-porous thin film being single-crystal Si, only the porous Si layer 152, 153 is subjected to the electroless wet chemical etching using at least one of the normal Si etching liquid, hydrofluoric acid being the porous Si selective etching liquid, a mixed liquid obtained by adding at least one of alcohol and aqueous hydrogen peroxide to hydrofluoric acid, buffered hydrofluoric acid, and a mixed liquid obtained by adding at least one of alcohol and aqueous hydrogen peroxide to buffered hydrofluoric acid, so that the film formed in advance on the porous layer of the first substrate remains on the support substrate. As described above in detail, only the porous Si layer can be selectively etched using the normal Si etching liquid due to the extensive surface area of porous Si.

Alternatively, the porous Si layer 152, 153 may be removed through selective polishing using the single-crystal Si layer 154, 155 as a polishing stopper.

In the case where the compound semiconductor layer is formed on the porous layer, only the porous Si layer 152, 153 is subjected to chemical etching using the etching liquid which has the greater etching speed for Si relative to the compound semiconductor, so that the thickness-reduced single-crystal compound semiconductor layer 154, 155 remains on the insulating substrate. Alternatively, the porous Si layer 152, 153 is removed through selective polishing using the single-crystal compound semiconductor layer 154, 155 as a polishing stopper.

In FIG. 12F, the semiconductor substrates of the present invention are shown. On the support substrates, the non-porous thin films, such as the single-crystal Si thin films 154 and 155, are formed in large area all over the wafer, flatly and uniformly reduced in thickness, so that the two semiconductor substrates are simultaneously formed. The semiconductor substrates thus obtained can be suitably used also in view of production of the insulated electronic elements.

The first Si single-crystal substrate 151 can be reused as a first Si single-crystal substrate 151 after removing remaining porous Si and after performing surface flattening if the surface flatness makes it unusable. Alternatively, a non-porous thin film may be again formed without removing porous Si so as to provide the substrate as shown in FIG. 12B, which is then subjected to the processes shown in FIGS. 12C to 12F. The support substrates 158 and 159 are not necessarily identical with each other.

Embodiment 11

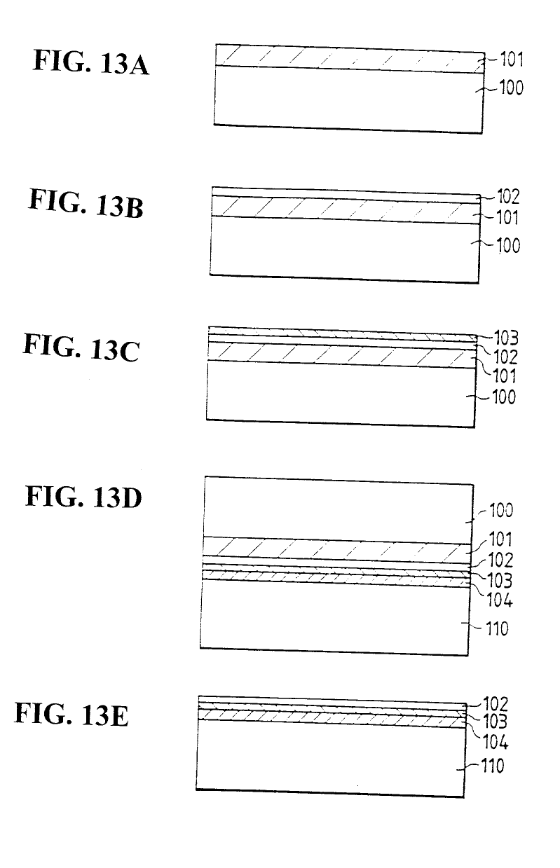

The eleventh preferred embodiment will be described with reference to FIGS. 13A to 13E.

First, a single-crystal Si substrate 100 is anodized to form a porous Si layer 101 (FIG. 13A). In this case, a thickness to be rendered porous is in the range from several micrometers to several tens of micrometers on one surface layer of the substrate. It may be arranged to anodize the whole Si substrate 100.

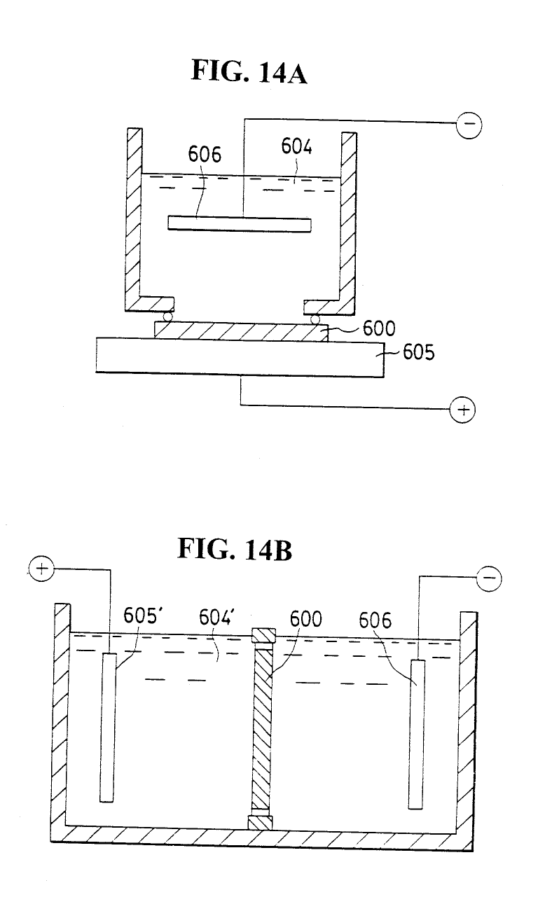

The method of forming porous silicon will be explained using FIGS. 14A and 14B. First, as the substrate, a p-type single-crystal silicon substrate 600 is prepared. An n-type may also be used. However, in this case, it is necessary that the substrate is limited to a low-resistance substrate or that the light is applied onto the surface of the substrate so as to facilitate generation of the holes. The substrate 600 is set in an apparatus as shown in FIG. 14A. Specifically, one side of the substrate is in contact with hydrofluoric acid solution 604 having therein a negative electrode 606, while the other side of the substrate is in contact with a positive metal electrode 605. On the other hand, as shown in FIG. 14B, a positive electrode 605′ may also be provided in a solution 604′. In any case, the substrate is first rendered porous from the negative electrode side abutting the hydrofluoric acid solution. As the hydrofluoric acid solution 604, concentrated hydrofluoric acid (49% HF) is used in general. As diluted by pure water (H₂O), although depending on current values, etching occurs from a certain concentration so that it is not preferable. During anodization, bubbles are generated from the surface of the substrate 600. Alcohol may be added as a surface active agent for effective removal of the bubbles. As alcohol, methanol, ethanol, propanol, isopropanol or the like is used. Instead of the surface active agent, an agitator may be used to agitate the solution so as to achieve anodization. The negative electrode 606 is made of a material, such as gold (Au) or platinum (Pt), which does not corrode relative to the hydrofluoric acid solution. A material of the positive electrode 605 may be metal which is used in general. On the other hand, since the hydrofluoric acid solution 604 reaches the positive electrode 605 when anodization is achieved relative to the whole substrate 600, it is preferable to coat the surface of the positive electrode 605 with a metal film which is resistive to the hydrofluoric acid solution. The maximum current value for anodization is several hundreds of mA/cm², while the minimum current value therefor is arbitrary, other than zero. This current value is determined in range where the good-quality epitaxial growth is achieved on the surface of porous silicon. In general, as the current value increases, the anodization speed increases and the density of the porous Si layer decreases. That is, the volume of the pores increases. This changes the condition of the epitaxial growth.

On the porous layer 101 thus formed, a non-porous single-crystal silicon layer 102 is epitaxially grown (FIG. 13B).

Subsequently, the surface of the epitaxial layer 102 is oxidized (including thermal oxidation) so as to form an SiO₂ layer 103 (FIG. 13C). This is necessary because, if the epitaxial layer is directly bonded to the support substrate in the next process, impurities tend to segregate at the bonded interface and dangling bonds of atoms at the interface increase, which will cause the thin film device to be unstable. However, this process is not essential, but may be omitted in a device structure wherein such phenomena are not serious. The SiO₂ layer 103 works as an insulating layer of the SOI substrate and should be formed on at least one side of the substrate to be bonded. There are various ways to form the insulating layer.

Upon oxidation, a thickness of the oxidized film is set to a value which is free of contamination taken into the bonded interface from the atmosphere.

Thereafter, the foregoing ion implantation is performed to form a layer with large porosity in the porous Si layer 101.

The substrate 100 having the foregoing epitaxial surface with the oxidized surface and a support substrate 110 having an SiO₂ layer 104 on the surface are prepared. The support substrate 110 may be a silicon substrate whose surface is oxidized (including thermal oxidation), quartz glass, crystallized glass, an arbitrary substrate with SiO₂ deposited thereon, or the like. A silicon substrate without the SiO₂ layer 104 may also be used as the support substrate.

The foregoing two substrates are bonded together after cleaning them (FIG. 13D). The cleaning is performed pursuant to the process of cleaning (for example, before oxidation) the normal semiconductor substrate. By pressurizing the whole substrate after the bonding, the bonding strength can be enhanced.

Subsequently, the bonded substrates are subjected to heat treatment. Although the higher temperature is preferable for the heat treatment, if it is too high, the porous layer 101 tends to cause structural change or the impurities contained in the substrate tend to be diffused into the epitaxial layer. Thus, it is necessary to select temperature and time which does not cause these problems. Specifically, about 600 to 1,100° C. is preferable. On the other hand, there are substrates that cannot be subjected to thermal treatment at the high temperature. For example, in case of the support substrate 110 being made of quartz glass, it can be subjected to the thermal treatment only at the temperature no greater than 200° C. due to differences in the thermal expansion coefficients between silicon and quartz. If this temperature is exceeded, the bonded substrates may be separated or ruptured due to stress. The thermal treatment is sufficient as long as it can endure the stress upon grinding or etching of the bulk silicon 100 performed in the next process. Accordingly, even at the temperature no greater than 200° C., the process can be performed by optimizing the surface processing condition for activation.

Then, by the foregoing method, the substrates are separated into two at the porous Si layer having the large porosity. The layer having the large porosity can be formed by altering current in the anodization, besides the ion implantation.

Subsequently, the silicon substrate portion 100 and the porous portion 101 are selectively removed with the epitaxial layer 102 remaining (FIG. 13E). In this fashion, the SOI substrate is obtained.

The following processes may be added to the foregoing processes:

(1) The thickness of the wall between the adjacent holes in the oxidized (preoxidation) porous silicon layer, of i.e. the pore internal walls of the porous layer is very small, that is, several nanometers to several tens of nanometers. Thus, if the high-temperature process is applied to the porous layer upon formation of the epitaxial silicon layer or upon heat treatment after bonding, the pore wall may agglomerate and enlarge so that the pore wall may clog the pore and lower the etching speed. In view of this, after formation of the porous layer, a thin oxidized film is formed on the pore wall so as to suppress the enlargement of the pore wall. On the other hand, since it is necessary to epitaxially grow the non-porous single-crystal silicon layer on the porous layer, it is necessary to oxidize only the surface of the pore inner wall such that the monocrystalline property remains inside the pore wall of the porous layer. It is preferable that the oxidized film is in the range of several angstroms to several tens of angstroms. The oxidized film of such a thickness is formed through heat treatment in an oxygen atmosphere at the temperature of 200° C. to 700° C., and more preferably 250° C. to 500° C.

(2) Hydrogen Baking Process

The present inventors have shown in the Publication No. EP553852A2 that, through heat treatment in a hydrogen atmosphere, small roughness on the silicon surface can be removed to obtain very smooth silicon surface. Also in the present invention, baking in the hydrogen atmosphere can be applied. The hydrogen baking can be performed, for example, after formation of the porous silicon layer and before formation of the epitaxial silicon layer. Apart from this, the hydrogen baking can be performed to the SOT substrate obtained after etching removal of the porous silicon layer. Through the hydrogen baking process performed before formation of the epitaxial silicon layer, a phenomenon occurs that the pore surface is closed due to migration of silicon atoms forming the porous silicon surface. When the epitaxial silicon layer is formed in the state where the pore surface is closed, the epitaxial silicon layer with fewer crystal defects can be achieved. On the other hand, through the hydrogen baking process performed after etching of the porous silicon layer, the epitaxial silicon surface which was more or less roughened by etching can be smoothed out, and boron from the clean room inevitably taken into the bonded interface upon bonding and boron thermally diffused in the epitaxial Si layer from the porous Si layer can be removed.

Embodiment 12

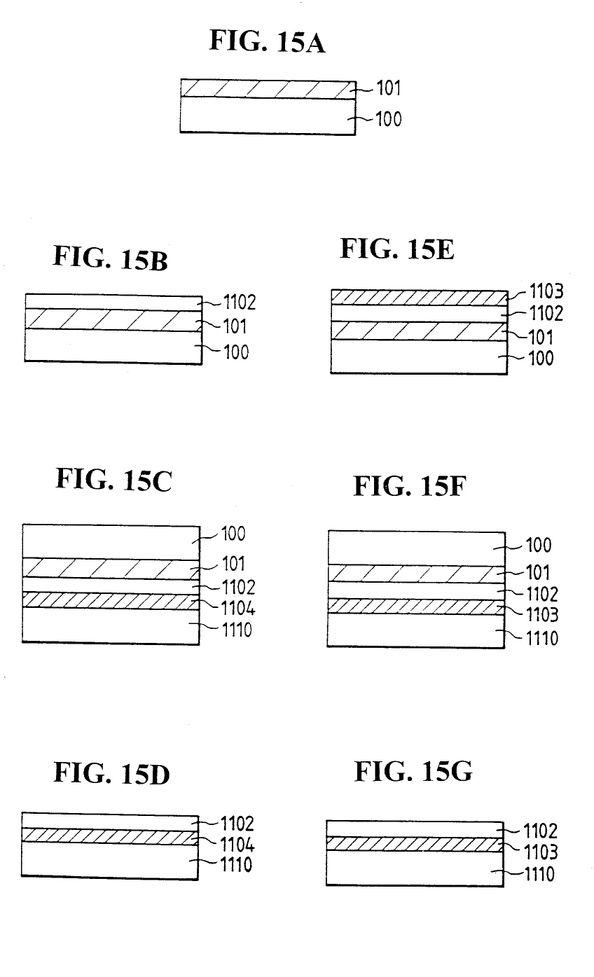

The twelfth preferred embodiment will be described with reference to FIGS. 15A to 15G. Numerals in FIGS. 15A to 15G which are the same as those in FIGS. 13A to 13E represent the same portions in FIGS. 13A to 13E. In the embodiment shown in FIGS. 13A to 13E, the surfaces of the two substrates to be bonded are the SiO₂ layer 103 and the SiO₂ layer 104. However, both of these surfaces are not necessarily the SiO₂ layers, but at least one of them may be made of SiO₂. In this preferred embodiment, the surface of an epitaxial silicon layer 1102 formed on a porous silicon layer is bonded to the surface of an oxidized film 1104 formed on a silicon substrate 1110, and the surface of an oxidized film 1103 formed by thermal oxidation of the surface of the epitaxial silicon layer 1102 is bonded to the surface of the silicon substrate 1110 which is not oxidized. In this preferred embodiment, the other processes can be performed as in the embodiment shown in FIGS. 13A to 13E.

Embodiment 13

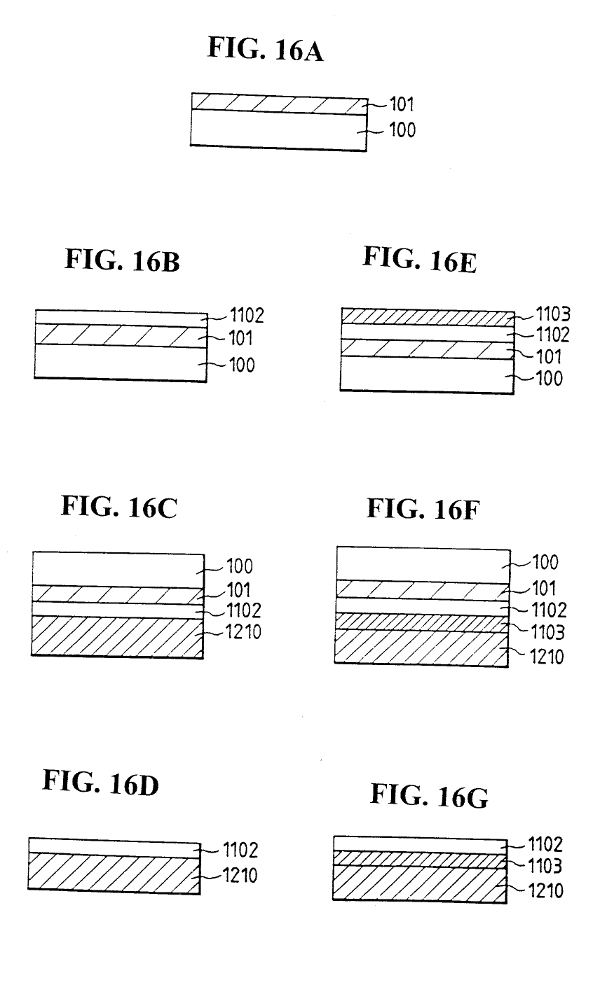

The thirteenth preferred embodiment will be described with reference to FIGS. 16A to 16G. Numerals in FIGS. 16A to 16G which are the same as those in FIGS. 13A to 13E represent the same portions in FIGS. 13A to 13E. In this preferred embodiment, a substrate bonded to a substrate formed with an epitaxial silicon film is made of a glass material 1210, such as quartz glass or blue glass. In this preferred embodiment, an epitaxial silicon layer 1102 is bonded to the glass substrate 1210, and an oxidized film 1103 formed by thermal oxidation of the surface of the epitaxial silicon layer 1102 is bonded to the glass substrate 1210. In this preferred embodiment, the other processes can be performed as in the embodiment shown in FIGS. 13A to 13E.

Hereinbelow, the present invention will be described in detail using concrete examples. However, the present invention is not limited thereto.

### EXAMPLE 13

A first p- or e-type (100) single-crystal Si substrate having 625 μm in thickness, 0.01 Ω.cm in resistivity and 6 inches in diameter was anodized in an HF solution.

The anodization condition was as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

Subsequently, He⁺ ions of 5×10¹⁶/cm² were implanted into the porous side of the substrate at an acceleration voltage of 30 keV. Then, the substrate was subjected to heat treatment at 850° C. in the vacuum for 8 hours.

When the light of a mercury lamp was applied to the substrate, luminescence of the red light with a wavelength around 750 nm was confirmed.

### EXAMPLE 14

Two first p-type (100) single-crystal Si substrates each being 625 μm thick, 0.01 Ω.cm in resistivity and 6 inches in diameter were prepared, and one of them was anodized in an HF solution.

The anodization condition was as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

He⁺ ions of 5×10¹⁶/cm² were implanted into the porous side of the anodized substrate and the surface side of the other substrate at acceleration voltage of 30 keV. Subsequently, phosphorus ions of 5×10¹⁴/cm² were implanted into the porous side of the anodized substrate and the surface side of the other substrate at an acceleration voltage of 10 keV. Then, these substrates were subjected to the heat treatment at 850° C. in the vacuum for 8 hours. Further, ITO electrodes were deposited on the surfaces.

When the voltage was applied between the Si substrates and the ITO electrodes, luminescence of a wavelength around 750 nm was confirmed at the porous substrate, while luminescence was not confirmed at the other substrate.

### EXAMPLE 15

Two first p- or e-type (100) single-crystal Si substrates each being 625 μm thick, 0.01 Ω.cm in resistivity and 6 inches in diameter were prepared, and one of them was anodized in an HF solution.

The anodization condition was as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 20 (μm) |
| Porosity: | 15 (%) |

The anodized substrate was oxidized at 400° C. in the oxygen atmosphere for 1 hour. Through the oxidation, the pore inner walls of porous Si were coated with a thermal-oxidized film. Subsequently, hydrogen ions of 5×10¹⁷/cm² were implanted all over the porous side of the porous substrate and all over the other substrate at an acceleration voltage of 0.76 MeV.

When these substrates were subjected to the heat treatment at 1,000° C. in the vacuum for 1 hour, the porous layer was separated uniformly all over the substrate with a thickness of about 1 μm corresponding to the ion-implanted region, while a lot of swells like blisters were only formed at the non-porous substrate.

### EXAMPLE 16

The first p-type (100) single-crystal Si substrate having 625 μm in thickness, 0.01 Ω.cm in resistivity and 6 inches in diameter was anodized in an HF solution.

The anodization condition was as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrate was oxidized at 400° C. in the oxygen atmosphere for 1 hour. Through the oxidation the pore inner walls of porous Si were coated with a thermally oxidized film. Using the CVD (chemical vapor deposition) method, single-crystal Si was epitaxially grown by 0.1 mm on porous Si. The growing conditions were as follows:

| | |
|---|---|
| Source Gas: | SiH₂Cl₂/H₂ |
| Gas Flow Rate: | 0.5/180 l/min |
| Gas Pressure: | 80 Torr |
| Temperature: | 900° C. |
| Growing Speed: | 0.3 μm/min |

He⁺ ions of 5×10¹⁶/cm² were implanted into the porous side of the anodized substrate and the surface side of the other substrate at acceleration voltage of 30 keV. Subsequently, phosphorus ions of 5×10¹⁴/cm² were implanted into the porous side of the anodized substrate and the surface side of the other substrate at acceleration voltage of 100 keV. Then, these substrates were subjected to heat treatment at 850° C. in the argon atmosphere for 8 hours. Further, ITO electrodes were deposited on the surfaces.

When the voltage was applied between the Si substrate and the ITO electrode, luminescence of wavelength around 750 nm was confirmed at the porous substrate.

### EXAMPLE 17

Two first p- or e-type (100) single-crystal Si substrates each being 625 μm thick, 0.01Ω.cm in resistivity and 6 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 3 (μm) |
| Porosity: | 15 (%) |

The substrates were oxidized at 400° C. in the oxygen atmosphere for 1 hour. Through the oxidation, the pore inner walls of porous Si were coated with thermally oxidized films. Using the CVD (chemical vapor deposition) method, single-crystal Si was epitaxially grown by 0.15 μm on porous Si. The growing conditions were as follows:

| | |
|---|---|
| Source Gas: | SiH₂Cl₂/H₂ |
| Gas Flow Rate: | 0.5/180 l/min |
| Gas Pressure: | 80 Torr |
| Temperature: | 950° C. |
| Growing Speed: | 0.3 μm/min |

Further, an SiO₂ layer of 100 nm was formed on the surface of each epitaxial Si layer through thermal oxidation.

Subsequently, He⁺ ions of 5×10¹⁷/cm² were implanted into the porous side of only one of the substrates at an acceleration voltage of 50 keV.

The surface of the SiO₂ layer and the surface of a separately prepared support Si substrate formed with an SiO₂ layer of 500 nm were overlapped and abutted with each other, and subjected to heat treatment at 1,000° C. for 2 hours to increase the bonding strength. Then, the two substrates were completely separated at a position corresponding to the projection range of the ion implantation. The separated surfaces were observed in detail using an optical microscope, but exposed portions of the initial bonded interface were not found. On the other hand, no change on the outward appearance was caused on the substrate which was not subjected to the helium ion implantation, and the substrates remained bonded to each other. Thus, the porous Si substrate side of the bonded substrates (not subjected to the helium ion implantation) was ground using a grinder for the normal semiconductor to expose the porous Si layer. However, due to insufficient grinding accuracy, the whole porous layer could not be exposed.

Thereafter, the porous Si layer remaining on the support substrate side was agitated in a mixed solution (1:5) of 49% hydrofluoric acid and 30% aqueous hydrogen peroxide for selective etching. Single-crystal Si remained without being etched so that porous Si was selectively etched using single-crystal Si as an etching stopper and fully removed.

The etching speed of non-porous single-crystal Si relative to the etching liquid is extremely low so that the ratio of selective etching relative to the etching speed of the porous layer reaches no less than 10⁵ and the etching amount (about several tens of angstroms) at the non-porous layer can be ignored from a practical point of view.

Specifically, the single-crystal Si layer having 0.1 μm in thickness was formed on the Si oxidized film. No change was caused on the single-crystal Si layer even by the selective etching of porous Si.

As a result of section observation by a transmission electron microscope, it was confirmed that no new crystal defects were introduced into the Si layer and the excellent crystallinity was maintained.

Similar results were obtained even without forming the oxidized film on the surface of the epitaxial Si layer.

### EXAMPLE 18

Two first p- or n-type (100) single-crystal Si substrates each being 625 μm thick, 0.01Ω.cm in resistivity and 6 inches in diameter were prepared and anodized in a HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in an oxygen atmosphere for 1 hour. Through the oxidation, the pore inner walls of porous Si were coated with thermally oxidized films. Using the CVD (chemical vapor deposition) method, single-crystal Si was epitaxially grown by 0.15 μm on porous Si. The growing conditions were as follows. The accuracy of the film thickness was +2%.

| | |
|---|---|
| Source Gas: | SiH₂Cl₂/H₂ |
| Gas Flow Rate: | 0.5/180 l/min |
| Gas Pressure: | 80 Torr |
| Temperature: | 950° C. |
| Growing Speed: | 0.3 μm/min |

Further, an SiO₂ layer of 100 nm was formed on the surface of each epitaxial Si layer through thermal oxidation.

Subsequently, hydrogen ions of 5×10¹⁶/cm² were implanted into the porous side of only one of the substrates at an acceleration voltage of 50 keV.

The surface of the SiO₂ layer and the surface of a separately prepared support Si substrate formed with an SiO₂ layer of 500 nm were overlapped and abutted with each other, and subjected to heat treatment at 1,000° C. for 2 hours to increase the bonding strength. Then, the two substrates were completely separated at a position corresponding to the projection range of the ion implantation. The separated surfaces were observed in detail using an optical microscope, but exposed portions of the initial bonded interface were not found. On the other hand, no change in the outward appearance was caused on the substrate which was not subjected to the hydrogen ion implantation, and the substrates remained bonded to each other. The porous substrate side of the bonded substrates (not subjected to the hydrogen ion implantation) was ground using a grinder for the normal semiconductor to expose the porous layer. However, due to insufficient grinding accuracy, the thickness of the remaining porous layer was 1 to 9 μm.

Thereafter, the porous Si layer remaining on the support substrate side was agitated in a mixed solution (1:2) of 49% hydrofluoric acid and 30% aqueous hydrogen peroxide for selective etching. Single-crystal Si regained without being etched so that porous Si was selectively etched using single-crystal Si as an etching stopper and fully removed.

The etching speed of non-porous single-crystal Si relative to the etching liquid is extremely low so that the ratio of selective etching relative to the etching speed of the porous layer reaches as much as no less than 10⁵ and the etching amount (about several tens of angstroms) at the non-porous layer can be ignored from a practical point of view.

Specifically, the single-crystal Si layer having 0.1 μm in thickness was formed on the Si oxidized film. Thicknesses of the formed single-crystal Si layer were measured at 100 points thereover. Uniformity of the thicknesses was 101 nm±3 nm with the hydrogen ion implantation, while it was 101 nm±7 nm without the hydrogen ion implantation so that it was confirmed that the thickness distribution was deteriorated due to influence of dispersion of thicknesses of porous silicon.

Thereafter, the heat treatment was performed at 1,100° C. in the hydrogen atmosphere for 1 hour.

When evaluating the surface roughness using an interatomic force microscope, the mean square roughness at a 50 μm square region was about 0.2 nm which was equal to the silicon wafer on the market.

As a result of section observation by a transmission electron microscope, it was confirmed that no new crystal defects were introduced into the Si layer and excellent crystallinity was maintained.

Similar results were obtained even without forming the oxidized film on the surface of the epitaxial Si layer.

At the same time, the porous Si layer remaining on the Si substrate side was also agitated in a mixed solution (1:2) of 49% hydrofluoric acid and aqueous 30% hydrogen peroxide for selective etching. Single-crystal Si remained without being etched so that porous Si was selective-etched using single-crystal Si as an etching stopper and fully removed, and the Si substrate could be again put into the porous-forming process.

### EXAMPLE 19

Two first p- or n-type (10) single-crystal Si substrates each being 625 μm thick, 0.01Ω.cm in resistivity and 5 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in the oxygen atmosphere for 1 hour. Through the oxidation, the pore inner walls of porous Si were coated with thermally oxidized films. Using the CVD (chemical vapor deposition) method, single-crystal Si was grown by 0.55 μm on porous Si. The growing conditions were as follows. The accuracy of the film thickness was ±2%.

| | |
|---|---|
| Source Gas: | SiH₂Cl₂/H₂ |
| Gas Flow Rate: | 0.5/180 l/min |
| Gas Pressure: | 80 Torr |
| Temperature: | 900° C. |
| Growing Speed: | 0.3 μm/min |

Further, an SiO₂ layer of 100 nm was formed on the surface of each epitaxial Si layer through thermal oxidation.

Subsequently, hydrogen ions of 5×10¹⁷/cm² were implanted into the porous side of only one of the substrates at an acceleration voltage of 100 keV.

The surface of the SiO₂ layer and the surface of a separately prepared support quartz substrate were exposed to oxygen plasma, respectively, then overlapped and abutted with each other, and subjected to the heat treatment at 200° C. for 2 hours to increase the bonding strength. The sufficient pressure is applied to the bonded wafers perpendicularly relative to the in-plane and uniformly over the in-plane. Then, the porous Si layer was divided into two at the ion-implanted region.

On the other hand, when the pressure was further applied to the substrate (not subjected to the hydrogen ion implantation), the porous layer was ruptured into two. However, when observing the divided porous layers, cracks were introduced into portions of the single-crystal Si layer so that the substrate could not be put into the subsequent process.

Thereafter, the porous Si layer remaining on the second substrate side was agitated in a mixed solution (1:2) of 49% hydrofluoric acid and 30% aqueous hydrogen peroxide for selective etching. Single-crystal Si remained without being etched so that porous Si was selective-etched using single-crystal Si as an etching stopper and fully removed.

The etching speed of non-porous single-crystal Si relative to the etching liquid is extremely low so that the selection ratio relative to the etching speed of the porous layer reaches no less than 10⁵ and the etching amount (about several tens of angstroms) at the non-porous layer can be ignored from a practical point of view.

Specifically, the single-crystal Si layer having 0.5 μm in thickness was formed on the Si oxidized film.

Thicknesses of the formed single-crystal Si layer were measured at 100 points thereover. Uniformity of the thicknesses was 501 nm±11 nm with the hydrogen ion implantation.

Thereafter, the heat treatment was performed at 1,100° C. in the hydrogen atmosphere for 1 hour.

When evaluating the surface roughness using an interatomic force microscope, the mean square roughness at a 50 μm square region was about 0.2 nm which was equal to the silicon wafer on the market.

As the result of section observation by a transmission electron microscope, it was confirmed that no new crystal defects were introduced into the Si layer and the excellent crystallinity property was maintained.

Similar results were obtained even without forming the oxidized film on the surface of the epitaxial Si layer.

Using the CVD (chemical vapor deposition) method, single-crystal Si was again epitaxially grown by 0.55 μm on porous Si remaining at the first substrate side. The growing conditions were as follows. The accuracy of the film thickness was ±2%.

| | |
|---|---|
| Source Gas: | SiH₂Cl₂/H₂ |
| Gas Flow Rate: | 0.5/180 l/min |
| Gas Pressure: | 80 Torr |
| Temperature: | 900° C. |
| Growing Speed: | 0.3 μm/min |

When evaluating the crystal defect density of this single-crystal Si layer through the defect revealing etching, the defect density was about 1×10³/cm² and this substrate could be again put into the processes of ion implantation and bonding.

Similar results were obtained even without forming the oxidized film on the surface of the epitaxial Si layer.

### EXAMPLE 20

Two first p- or n-type (100) single-crystal Si substrates each being 625 μm thick, 0.01Ω.cm in resistivity and 6 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in the oxygen atmosphere for 1 hour. Through the oxidation, the pore inner walls of porous Si were coated with thermal-oxidized films. Using the CVD (chemical vapor deposition) method, single-crystal Si was epitaxial-grown by 0.15 μm on porous Si. The growing conditions were as follows. The accuracy of the film thickness was ±2%.

| | |
|---|---|
| Source Gas: | SiH₂Cl₂/H₂ |
| Gas Flow Rate: | 0.5/180 l/min |
| Gas Pressure: | 80 Torr |
| Temperature: | 950° C. |
| Growing Speed: | 0.3 μm/min |

Further, an SiO₂ layer of 100 nm was formed on the surface of each epitaxial Si layer through thermal oxidation.

Subsequently, helium ions of 5×10¹⁷/cm² were implanted into the porous side of only one of the substrates at acceleration voltage of 100 keV.

The surface of the SiO₂ layer and the surface of a separately prepared support Si substrate formed with an SiO₂ layer of 500 nm were overlapped and abutted with each other, and subjected to the heat treatment at 400° C. for 2 hours. The sufficient tensile force is applied to the bonded wafers perpendicularly relative to the in-plane and uniformly over the in-plane. Then, the two substrates were completely separated at a position corresponding to the projection range of the helium ion implantation. The separated surfaces were observed in detail using an optical microscope, but exposed portions of the initial bonded interface were not found.

On the other hand, when the pressure was further applied to the substrate (not subjected to the helium ion implantation), the porous layer was ruptured into two. However, when observing the divided porous layers, cracks were introduced into portions of the single-crystal Si layer so that the substrate could not be put into the subsequent process.

Thereafter, the porous Si layer remaining on the support substrate side was agitated in a mixed solution (1:2) of 49% hydrofluoric acid and 30% aqueous hydrogen peroxide for selective etching. Single-crystal Si remained without being etched so that porous Si was selectively etched using single-crystal Si as etching stopper and fully removed.

The etching speed of non-porous single-crystal Si relative to the etching liquid is extremely low so that the selection ratio relative to the etching speed of the porous layer reaches less than 10⁵ and the etching amount (about several tens of angstroms) at the non-porous layer can be ignored from a practical point of view.

Specifically, the single-crystal Si layer having 0.1 μm in thickness was formed on the Si oxidized film. Thicknesses of the formed single-crystal Si layer were measured at 100 points thereover. Uniformity of the thicknesses was 101 nm±3 nm with the hydrogen ion implantation, while it was 101 nm±7 nm without the hydrogen ion implantation so that it was confirmed that the thickness distribution deteriorated due to influence of dispersion of thicknesses of porous silicon.

Thereafter, the heat treatment was performed at 1,100° C. in a hydrogen atmosphere for 1 hour.

When evaluating the surface roughness using an interatomic force microscope, the mean square roughness at a 50 μm square region was about 0.2 nm which was equal to the silicon wafer on the market.

As a result of section observation by a transmission electron microscope, it was confirmed that no new crystal defects were introduced into the Si layer and excellent crystallinity was maintained.

Similar results were obtained even without forming the oxidized film on the surface of the epitaxial Si layer.

At the same time, the porous Si layer remaining on the Si substrate side was also agitated in a mixed solution (1:2) of 49% hydrofluoric acid and aqueous 30% hydrogen peroxide for selective etching. Single-crystal Si remained without being etched so that porous Si was selectively etched using single-crystal Si as an etching stopper and fully removed, and the Si substrate could be again put into the porous-forming process.

### EXAMPLE 21

Two first p- or n-type (100) single-crystal Si substrates each having 625 μm in thickness, 0.01Ω.cm in resistivity and 6 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in the oxygen atmosphere for 1 hour. Through the oxidation, the pore inner walls of porous Si were coated with thermal-oxidized films. Using the MBE (molecular beam epitaxy) method, single-crystal Si was epitaxial-grown by 0.5 μm on porous Si. The growing conditions were as follows. The accuracy of the film thickness was ±2%.

| | |
|---|---|
| Temperature: | 700° C. |
| Pressure: | 1 × 10⁻⁹ Torr |
| Growing Speed: | 0.1 nm/sec |
| Temperature: | 950° C. |
| Growing Speed: | 0.3 μm/min |

Further, an SiO₂ layer of 100 nm was formed on the surface of each epitaxial Si layer through thermal oxidation.

Subsequently, helium ions of 1×10¹⁷/cm² were implanted into the porous side of only one of the substrates at an acceleration voltage of 100 keV.

The surface of the SiO₂ layer and the surface of a separately prepared support Si substrate formed with an SiO₂ layer of 500 nm were overlapped and abutted with each other, and subjected to heat treatment at 300° C. for 2 hours. The bonded two wafers were fixed by a vacuum chuck and applied with torsion and shearing forces in the horizontal direction relative to the main surface of the wafers. Then, the two substrates were completely separated at a position corresponding to the projection range of the helium ion implantation. The separated surfaces were observed in detail using an optical microscope, but exposed portions of the initial bonded interface were not found.

On the other hand, when the pressure was further applied to the substrate (not subjected to the helium ion implantation), the vacuum chuck was detached and the substrate could not be put into the subsequent process.

Thereafter, the porous Si layer remaining on the support substrate side was agitated in a mixed solution (1:2) of 49% hydrofluoric acid and 30% aqueous hydrogen peroxide for selective etching. Single-crystal Si remained without being etched so that porous Si was selectively etched using single-crystal Si as an etching stopper and fully removed.

The etching speed of non-porous single-crystal Si relative to the etching liquid is extremely low so that the selection ratio relative to the etching speed of the porous layer reaches as much as no less than 10⁵ and the etching amount (about several tens of angstroms) at the non-porous layer can be ignored from a practical point of view.

Specifically, the single-crystal Si layer 0.1 μm thick was formed on the Si oxidized film. Thicknesses of the formed single-crystal Si layer were measured at 100 points thereover. Uniformity of the thicknesses was 101 nm±3 nm with the hydrogen ion implantation, while it was 101 nm±7 nm without the hydrogen ion implantation so that it was confirmed that the thickness distribution deteriorated due to influence of dispersion of thicknesses of porous silicon.

Thereafter, heat treatment was performed at 1,100° C. in a hydrogen atmosphere for 1 hour.

When evaluating the surface roughness using an interatomic force microscope, the mean square roughness of 50 μm square region was about 0.2 nm which was equal to the silicon wafer on the market.

As the result of section observation by a transmission electron microscope, it was confirmed that no new crystal defects were introduced into the Si layer and excellent crystalline properties were maintained.

Similar results were obtained even without forming the oxidized film on the surface of the epitaxial Si layer.

At the same time, the porous Si layer remaining on the Si substrate side was also agitated in a mixed solution (1:2) of 49% hydrofluoric acid and aqueous 30% hydrogen peroxide for selective etching. Single-crystal Si remained without being etched so that porous Si was selectively etched using single-crystal Si as an etching stopper and fully removed, and the Si substrate could be again put into the porous-forming process.

### EXAMPLE 22

Two first p- or n-type (100) single-crystal Si substrates each being 625 μm thick, 0.01Ω.cm in resistivity and 5 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in the oxygen atmosphere for 1 hour. Through the oxidation, the pore inner walls of porous Si were coated with thermally oxidized films. Using the CVD (chemical vapor deposition) method, single-crystal Si was epitaxially grown by 0.55 μm on porous Si. The growing conditions was as follows. The accuracy of the film thickness was ±2%.

| | |
|---|---|
| Source Gas: | SiH₂Cl₂/H₂ |
| Gas Flow Rate: | 0.5/180 l/min |
| Gas Pressure: | 80 Torr |
| Temperature: | 900° C. |
| Growing Speed: | 0.3 μm/min |

Further, an SiO₂ layer of 100 nm was formed on the surface of each epitaxial Si layer through thermal oxidation.

Subsequently, hydrogen ions of 1×10¹⁸/cm² were implanted into the porous side of only one of the substrates at an acceleration voltage of 100 keV.

The surface of the SiO₂ layer and the surface of a separately prepared support quartz substrate were exposed to oxygen plasma, respectively, then overlapped and abutted with each other, and subjected to the heat treatment at 200° C. for 2 hours to increase the bonding strength. Then, the porous Si layer was divided into two at the ion-implanted region.

On the other hand, no change was observed at the substrate which was not subjected to the helium ion implantation.

Thereafter, the porous Si layer remaining on the support substrate side was agitated in a mixed solution (1:2) of 49% hydrofluoric acid and aqueous 30% hydrogen peroxide for selective etching. Single-crystal Si remained without being etched so that porous Si was selectively etched using single-crystal Si as an etching stopper and fully removed.

The etching speed of non-porous single-crystal Si relative to the etching liquid is extremely low so that the selection ratio relative to the etching speed of the porous layer reaches no less than 10⁵ and the etching amount (about several tens of angstroms) at the non-porous layer can be ignored from a practical point of view.

Specifically, the single-crystal Si layer 0.5 μm thick was formed on the quartz substrate. Thicknesses of the formed single-crystal Si layer were measured at 100 points thereover. Uniformity of the thicknesses was 501 nm±11 nm with the hydrogen ion implantation. Thereafter, the heat treatment was performed at 1,100° C. in the hydrogen atmosphere for 1 hour.

When evaluating the surface roughness using an interatomic force microscope, the mean square roughness at a 50 μm square region was about 0.2 nm which was equal to the silicon wafer on the market.

As a result of section observation by a transmission electron microscope, it was confirmed that no new crystal defects were introduced into the Si layer and excellent crystallinity was maintained.

Similar results were obtained even without forming the oxidized film on the surface of the epitaxial Si layer.

### EXAMPLE 23

A first p- or n-type (100) single-crystal Si substrate being 625 μm thick, 0.01Ω.cm in resistivity and 5 inches in diameter was prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrate was oxidized at 400° C. in the oxygen atmosphere for 1 hour. Through the oxidation, pore inner walls of porous Si were coated with thermally oxidized films. Using the MOCVD (metal organic chemical vapor deposition) method, single-crystal GaAs was epitaxially grown by 1 μm on porous Si. The growing conditions were as follows.

| | |
|---|---|
| Source Gas: | TMG/AsH₃/H₂ |
| Gas Pressure: | 80 Torr |
| Temperature: | 700° C. |

Subsequently, helium ions of 1×10¹⁸/cm² were implanted into the porous side of the substrate at an acceleration voltage of 100 keV.

The surface of the GaAs layer and the surface of a separately prepared support Si substrate were overlapped and abutted with each other, and subjected to the heat treatment at 200° C. for 2 hours so as to enhance the bonding strength. Then, the porous Si layer was divided into two at the ion-implanted region.

Thereafter, after removing the oxidized film on the inner walls of the porous Si layer using hydrofluoric acid, the porous Si was etched with a solution of ethylenediamine, pyrocatechol and water (ratio: 17 ml:3 g:8 ml) at 110° C. Single-crystal GaAs remained without being etched so that porous Si was selectively etched using single-crystal GaAs as an etching stopper and fully removed.

The etching speed of single-crystal GaAs relative to the etching liquid is extremely low so that the thickness reduction can be ignored from a practical point of view.

Specifically, the single-crystal GaAs layer having 1 μm in thickness was formed on the Si substrate. No change was caused on the single-crystal GaAs layer even by the selective etching of porous Si.

As a result of section observation by a transmission electron microscope, it was confirmed that no new crystal defects were introduced into the GaAs layer and excellent crystallinity was maintained.

By using the Si substrate with the oxidized film as the support substrate, GaAs on the insulating film could also be produced similarly.

### EXAMPLE 24

A first p- or n-type, (100) single-crystal Si substrate being 625 μm thick, 0.01 Ω.cm in resistivity and 5 inches in diameter was prepared and anodized in an HF solution.

The anodization conditions were as follows:

| Current Density: | 10(mA · cm⁻²) |
|---|---|
| Anodization Solution: | HF:H₂O:C₂H₅OH = 1:1:1 |
| Time: | 24 (minutes) |
| Thickness of Porous Si: | 20 (μm) |
| Porosity: | 17 (%) |

The substrate was oxidized at 400° C. in the oxygen atmosphere for 2 hours. Through the oxidation, the pore inner walls of porous Si were coated with thermally oxidized films. Using the MBE (molecular beam epitaxy) method, single-crystal AlGaAs was epitaxially grown by 0.5 μm on porous Si.

Subsequently, helium ions of 1×10¹⁸/cm² were implanted into the porous side of the substrate at an acceleration voltage of 100 keV.

The surface of the AlGaAs layer and the surface of a separately prepared support substrate of low melting point glass were overlapped and abutted with each other, and subjected to the heat treatment at 500° C. for 2 hours. Through this heat treatment, the substrates were firmly bonded with each other.

When sufficient pressure was applied to the bonded wafers perpendicularly relative to the in-plane and uniformly over the in-plane, the porous Si layer was divided into two at the ion-implanted region.

Thereafter, porous Si was etched with a hydrofluoric acid solution. Single-crystal AlGaAs remained without being etched so that porous Si was selectively etched using single-crystal AlGaAs as an etching stopper and fully removed.

The etching speed of single-crystal AlGaAs relative to the etching liquid is extremely low so that the thickness reduction can be ignored from a practical point of view.

Specifically, the single-crystal AlGaAs layer 0.5 μm thick was formed on the glass substrate. No change was caused on the single-crystal AlGaAs layer even by the selective etching of porous Si.

As a result of section observation by a transmission electron microscope, it was confirmed that no new crystal defects were introduced into the AlGaAs layer and excellent crystallinity was maintained.

### EXAMPLE 25

A first p- or n-type (100) single-crystal Si substrate with both sides polished and being 625 μm 0.01 Ω.cm in resistivity and 6 inches in diameter was prepared and anodized at both sides thereof in an HF solution. The anodization conditions were as follows:

| Current Density: | 5 (mA·cm⁻²) |
|---|---|
| Anodization Solution: | HF:H₂O:C₂H₅OH = 1:1:1 |
| Time: | 12 × 2 (minutes) |
| Thickness of Porous Si: | 10 (μm) for each side |
| Porosity: | 15 (%) |

The substrate was oxidized at 400° C. in the oxygen atmosphere for 1 hour. Through the oxidation, the pore inner walls of porous Si were coated with thermally oxidized films. Using the CVD (chemical vapor deposition) method, single-crystal Si was epitaxially grown by 1 μm on porous Si formed at each side. The growing conditions were as follows.

| | |
|---|---|
| Source Gas: | SiH₂Cl₂/H₂ |
| Gas Flow Rate: | 0.5/180 l/min |
| Gas Pressure: | 80 Torr |
| Temperature: | 950° C. |
| Growing Speed: | 0.3 μm/min |

Further, an SiO₂ layer of 100 nm was formed on the surface of each epitaxial Si layer through thermal oxidation.

Subsequently, hydrogen ions of 1×10¹⁸/cm² were implanted into the porous layers at an acceleration voltage of 100 keV.

The surfaces of the SiO₂ layers and the surfaces of separately prepared two support Si substrates each formed with an SiO₂ layer of 500 nm were overlapped and abutted with each other, and subjected to heat treatment at 600° C. for 2 hours to achieve bonding. Then, the porous Si layer was divided into two at the ion-implanted region.

Thereafter, the porous Si layer was agitated in a mixed solution (1:5) of 49% hydrofluoric acid and 30% aqueous hydrogen peroxide for selective etching. Single-crystal Si remained without being etched so that porous Si was selectively etched using single-crystal Si as an etching stopper and fully removed.

The etching speed of non-porous single-crystal Si relative to the etching liquid is extremely low so that the selection ratio relative to the etching speed of the porous layer reaches no less than 10⁵ and the etching amount (about several tens of angstroms) at the non-porous layer can be ignored from a practical point of view.

Specifically the two single-crystal Si layers each 1 μm thick were simultaneously formed on the Si oxidized films. No change was caused on the single-crystal Si layers even by the selective etching of porous Si.

As a result of section observation by a transmission electron microscope, it was confirmed that no new crystal defects were introduced into the Si layer and excellent crystallinity was maintained.

Similar results were obtained even without forming the oxidized film on the surface of the epitaxial Si layer.

### EXAMPLE 26

Two first p- or n-type (100) single-crystal Si substrates each 625 μm thick, 0.01 Ω.cm in resistivity and 5 inches in diameter were prepared and anodized in an HF solution.

The anodization conditions were as follows:

| Current Density: | 5 (mA · cm⁻²) |
|---|---|
| Anodization Solution: | HF:H₂O:C₂H₅OH = 1:1:1 |
| Time: | 12 (minutes) |
| Thickness of Porous Si: | 10 (μm) |
| Porosity: | 15 (%) |

The substrates were oxidized at 400° C. in the oxygen atmosphere for 1 hour. Through the oxidation, the pore inner walls of porous Si were coated with oxidized films. Using the CVD (chemical vapor deposition) method, single-crystal Si was grown by 0.55 μm on porous Si. The growing conditions were as follows. The accuracy of the film thickness was 12%.

| | |
|---|---|
| Source Gas: | SiH₂Cl₂/H₂ |
| Gas Flow Rate: | 0.5/180 l/min |
| Pressure: | 80 Torr |
| Temperature: | 900° C. |
| Growing Speed: | 0.3 μm/min |

Further, an SiO₂ layer of 100 nm was formed on the surface of each epitaxial Si layer through thermal oxidation.

Subsequently, hydrogen ions of 1×10¹⁸/cm² were implanted into the porous side of only one of the substrates at an acceleration voltage of 100 keV.

The surface of the SiO₂ layer and the surface of a separately prepared support quartz substrate were exposed to oxygen plasma, respectively, then overlapped and abutted with each other, and subjected to the heat treatment at 200° C. for 2 hours so as to increase the bonding strength. Subsequently, the wave energy such as the ultrasonic wave was applied to the substrates. Then, the porous Si layer was divided into two at the ion-implanted region.

On the other hand, no change was observed at the substrate which was not subjected to the hydrogen ion implantation.

Thereafter, the porous Si layer remaining on the support substrate side was agitated in a mixed solution (1:2) of 49% hydrofluoric acid and 30% aqueous hydrogen peroxide for selective etching. Single-crystal Si remained without being etched so that porous Si was selectively etched using single-crystal Si as an etching stopper and fully removed.

The etching speed of non-porous single-crystal Si relative to the etching liquid is extremely low so that the selection ratio relative to the etching speed of the porous layer reaches no less than 10⁵ and the etching amount (about several tens of angstroms) at the non-porous layer can be ignored from a practical point of view.

Specifically, the single-crystal Si layer 0.5 μm thick was formed on the quartz substrate. Thicknesses of the formed single-crystal Si layer were measured at 100 points thereover. Uniformity of the thicknesses was 501 nm±11 nm with the hydrogen ion implantation. Thereafter the heat treatment was performed at 1,100° C. in a hydrogen atmosphere for 1 hour.

When evaluating the surface roughness using an interatomic force microscope, the mean square roughness at a 50 μm square region was about 0.2 nm which was equal to the silicon wafer on the market.

As a result of section observation by a transmission electron microscope, it was confirmed that no new crystal defects were introduced into the Si layer and the excellent crystallinity was maintained.

Similar results were obtained even without forming the oxidized film on the surface of the epitaxial Si layer.

The single-crystal Si substrate was reused as a single-crystal Si substrate after removing remaining porous Si and performing surface-polishing to provide a mirror finished surface.

Recently, Sakaguchi et al. reported a method for reusing the first substrate, which was consumed in the above bonding method (Japanese Patent Application No. 07-045441 (1995)).

They employed the following method in place of the step of thinning the first substrate from the back surface by the method of grinding, etching, and the like to expose porous Si in the bonding plus etchback process using porous Si as described above.

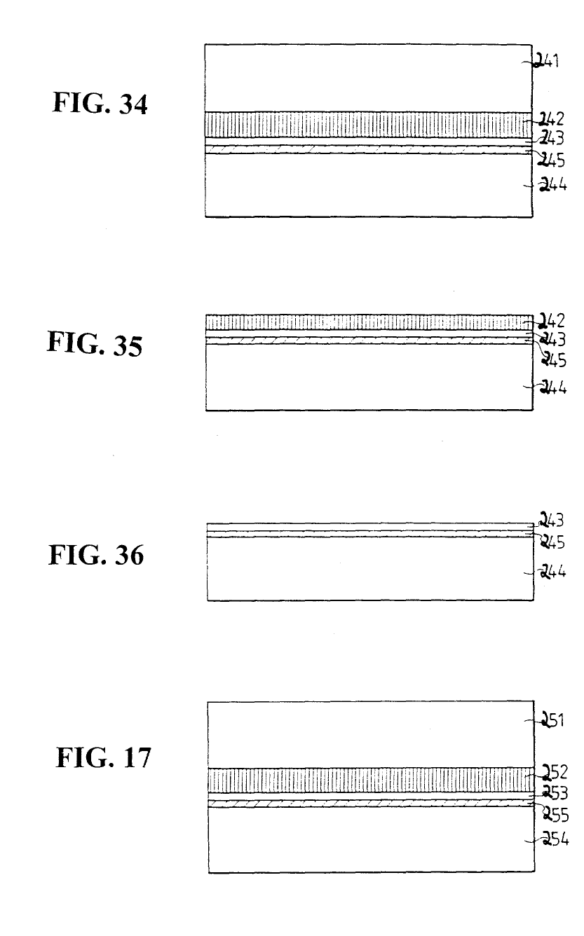

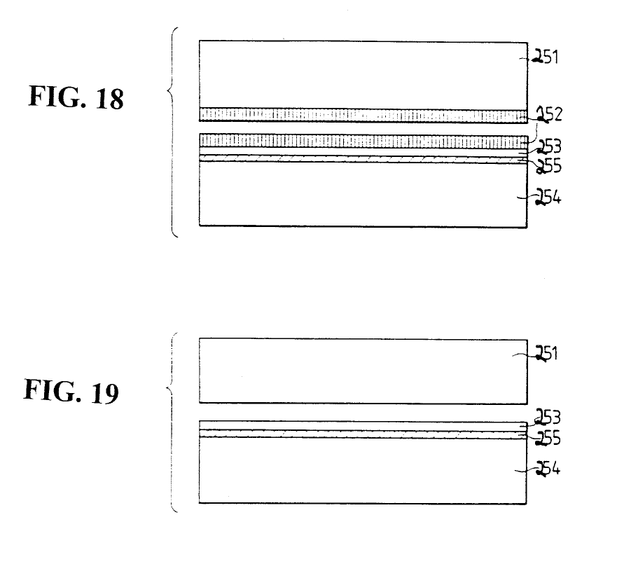

A surface layer of first Si substrate 251 is made porous to obtain a porous layer 252, a single-crystal Si layer 253 is formed thereon, and this single-crystal Si layer 253 and first Si substrate is bonded through an insulating layer 255 with a principal surface of another second Si substrate 254 (FIG. 17). After this, the bonding wafer is divided at the porous layer (FIG. 18) and the porous Si layer exposed in the surface on the second Si substrate side is selectively removed, thereby forming an SOI substrate (FIG. 19).

Division of the bonding wafer is effected by using a method for breaking the porous Si layer, for example, either one of a method for applying sufficient tension or pressure perpendicularly to and uniformly in the surface of the bonding wafer, a method for applying wave energy of ultrasonic wave or the like, a method for exposing the porous layer on the side face of wafer, etching some of the porous layer, and inserting an edge of a razor into the porous layer, a method for exposing the porous layer on the side face of wafer, infiltrating a liquid such as water into the porous Si layer, and thereafter expanding the liquid by heating or cooling the entire bonding wafer, and a method for applying force horizontally onto the second (or first) substrate relative to the first (or second) substrate, or the like.

These methods are all based on an idea that the mechanical strength of porous Si is sufficiently weaker than bulk Si, though depending upon its porosity. For example, with a porosity of 50%, the mechanical strength of porous Si may be considered to be half that of bulk Si. Namely, when compression, tension or shear force is exerted on the bonding wafer, the porous Si layer is broken first. With a greater porosity, the porous layer can be broken by a weaker force.

However, when force is exerted vertically or horizontally on the surface of wafer, the wafer is sometimes elastically deformed, thereby failing to properly exert force on the porous layer. This is because the observed semiconductor substrate is not a perfectly rigid body, but rather is an elastic body, and this also depends on the method of supporting a given wafer.

Similarly, with the method for inserting an edge of a razor or the like through the side surface of wafer, the yields were extremely lowered in some cases where the thickness of the razor was not sufficiently thin or where the razor did not have sufficiently high rigidity. Also, the razor was not able to be inserted uniformly from the periphery or the force was exerted from the outside on the bonding wafer. As a result, if the bond strength of the bonding surface was weaker than the strength of the porous Si layer or if there existed a locally weak portion, the two wafers were split at the bonding surface, thereby sometimes failing to achieve the initial purpose.

Accordingly, a desire exists for a method for fabricating SOI substrates of sufficient quality with good reproducibility and, at the same time, realizing conservation of resources and reduction of cost by re-use of a wafer or the like.

The bulletin of Japanese Laid-open Patent Application No. 5-211128 (1993) describes a proposal for a method for forming a bubble layer by ion implantation, annealing it to cause rearrangement of crystal and cohesion of bubbles, and dividing the wafer through the bubble layer, wherein optimization of annealing is not easy and is carried out at low temperatures of 400 to 600° C. Annealing at such low temperatures cannot suppress generation of voids as described above, and the voids once generated cannot be nullified even with re-annealing at high temperature after thinning. Namely, the decrease in the number and size of voids is a phenomenon that occurs when the two wafers are annealed at high temperature in the bonded state, and high-temperature annealing after thinning will increase the strength of the adhesive portion, but will not decrease the voids.

The above description concerns the problems related to the SOI technology by bonding. There are also demands as to the SOI technology regarding formation of a single-crystal layer on a light transparent substrate, formation of a compound semiconductor layer on a substrate, and so on, for the following reasons:

The light transparent substrate is important in constructing contact sensors which serve as light receiving elements, and projection type liquid crystal image display devices. Further, high-performance drive elements are necessary for realizing higher-density, higher-resolution, and higher-definition of pixels (picture elements) in the sensors and display devices. As a result, the devices provided on the light transparent substrate need to be fabricated using a single-crystal layer having excellent crystallinity. Use of the single-crystal layer enables peripheral circuits for driving the pixels and circuits for image processing to be incorporated in the same substrate as the pixels, thereby realizing size reduction and speed enhancement of a given chip.

However, the light transparent substrate typified by glass has disorderliness as to its crystal structure in general, and a thin Si layer deposited thereon is an amorphous layer or, at best, a polycrystal layer, reflecting the disorderliness of the substrate. High-performance devices cannot be fabricated of such a substrate. Namely, because of a crystal structure with many imperfections, it is not easy to fabricate drive elements of amorphous and polycrystal Si having sufficient performance that is required now or in the future. It is because the crystal structure of the substrate is amorphous, and simple deposition of Si layer will not yield a single-crystal layer with good quality.

On the other hand, substrates of compound semiconductor are necessary and indispensable for fabricating devices of compound semiconductor, but the substrates of compound semiconductor are expensive and it is very difficult to form a large area of compound semiconductor. For these reasons, attempts have been made to heteroepitaxially grow a compound semiconductor of GaAs or the like on the Si wafer, which can be fabricated as a large-area wafer.

However, the thus grown film has poor crystallinity because of differences of lattice constant and coefficient of thermal expansion and it is thus very difficult to apply it to devices.

It is, therefore, an object of the present invention to provide a process for fabricating a film with good crystallinity and to provide a process for fabricating a semiconductor substrate, which can effectively use the semiconductor substrate as a material and which can suitably achieve conservation of resources and reduction of cost.

In the present invention, the porous Si layer is oxidized from the periphery of wafer, utilizing enhanced oxidation of porous Si. Volume expansion of porous Si increases from the center toward the periphery, and the present invention thus has the same effect as porous Si as if uniformly wedged from the periphery. In that case, the internal pressure is exerted on only the porous Si layer and the wafer is divided in the porous Si layer throughout the entire surface. This provides a fabrication process for a semiconductor substrate which solves the various problems discussed previously.

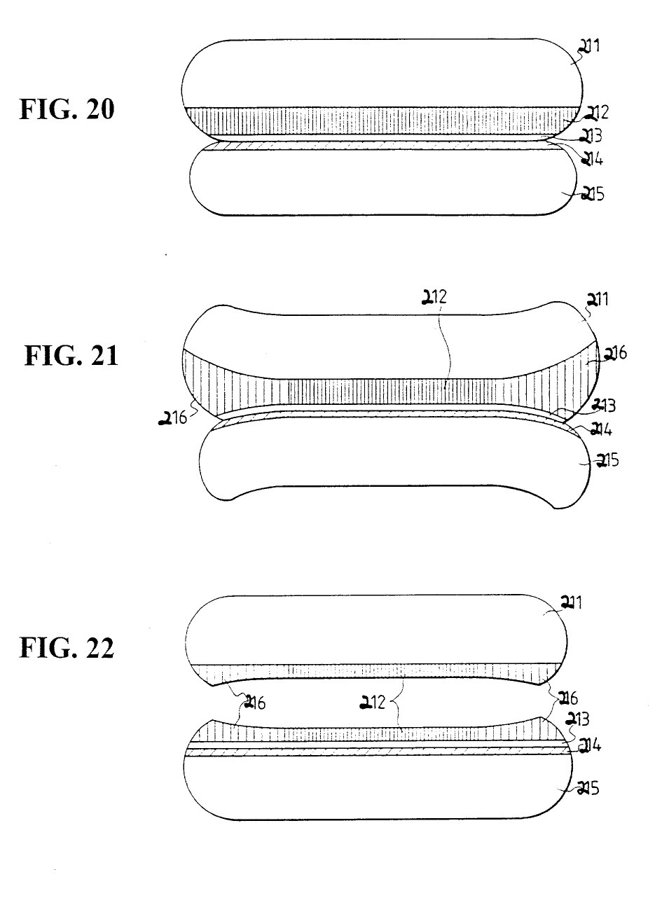

The principle of division by oxidation as a basis of the present invention will be described with reference to FIG. 20 to FIG. 22. In FIG. 20 to FIG. 22, reference numeral 211 designates a first Si single-crystal substrate; 212, a porous Si layer; 213, a non-porous thin film; 214, an insulating layer; 215, a second substrate; and 216, an oxidized porous Si layer. Although FIG. 20 to FIG. 22 illustrate an embodiment in which the insulating layer has been formed on the surface of the second substrate, it may be formed on the first substrate or both the first and second substrates. There are some cases such as GaAs on a Si p-n junction, where the insulating layer has been formed on neither of the substrates. FIG. 20 shows a bonding substrate immediately before oxidation. The side surface of porous Si is exposed. The side surface of porous Si is also normally covered by a non-porous thin film, and it is necessary to make the side surface exposed after or before bonding. When this bonding substrate is oxidized, enhanced oxidation starts from the side surface of porous Si because of the enormous surface area of porous Si. The volume expands 2.27 times when Si turns to SiO₂. Thus, if the porosity is not more than 56%, then the volume of the oxidized, porous Si layer will expand. The nearer the position to the center of the wafer, the lower the degree of oxidation. Thus, the volume expansion of the oxidized porous Si layer near the side surface of the wafer becomes greater as shown in FIG. 21. This is just the same condition as if wedges are driven into the porous Si layer from the side surface of the wafer, and the internal pressure is exerted on only the porous Si layer, so that force acts so as to divide the substrate in porous Si. In addition, since oxidation uniformly progresses at the periphery of the wafer, the bonding wafer will be split equally from the circumference of the wafer. As a result, the wafer is divided as shown in FIG. 22. This oxidation step is a step used in the normal Si—IC processes and thus requires neither special facilities nor special techniques such as careful insertion of an edged tool.

The bonding substrate has a multi-layered structure, and, thus, if it has an interface of low strength or a locally weak region, the method of splitting at porous Si by external pressure would cause splitting at the weak portion. The present invention permits the internal pressure to be exerted on only the porous Si layer, utilizing one step, oxidation, with excellent uniformity of the normal Si—IC processes and combining the enhanced oxidizability of porous Si, volume expansion of porous Si, and fragility of porous Si, whereby the wafer can be divided with good controllability in the porous Si layer.

After the residual porous Si and oxidized porous Si layer is removed from the first Si substrate thus separated by the above method of the present invention, the first Si substrate is subjected to a surface flattening process if surface flatness thereof is insufficient. Then the first Si substrate can be reused again as a first Si layer or as a next second substrate.

The surface flattening process may be the method of polishing, etching, or any other method used in the normal semiconductor processes, but may be annealing in an atmosphere containing hydrogen. By properly selecting the conditions for this annealing, the substrate can be flattened so as to expose atomic steps locally. The annealing in the atmosphere containing hydrogen may be carried out, for example, under such conditions as H₂100%, 100° C., 2 hours; H₂/Ar=20/80, 1150° C., 1 hour; or H₂ 100%, 1050° C., 2 hours.

Since the present invention permits a large area to be divided en bloc through the porous layer, it can omit the grinding, polishing, and etching steps that were conventionally essential for removing the first substrate to expose the entire surface of porous Si layer, thus decreasing processing steps.

When the substrate separated is repetitively used as a first Si substrate, this first Si substrate can be reused any number of times before it becomes unusable in the aspect of mechanical strength.

Further, since the conventional fabrication of a bonding substrate employs the method for successively removing the first Si substrate from one side thereof by grinding and etching, it is impossible to bond both surfaces of the first Si substrate to respective support substrates, thereby effectively utilizing the two surfaces. In contrast, according to the present invention, the first Si substrate, except for the surface layer, is maintained in its original state, and thus, by using both surfaces of the first Si substrate as principal surfaces and bonding the two surfaces to the respective support substrates, two substrates can be fabricated simultaneously by bonding, dividing, and thinning from one first Si substrate, thereby decreasing steps and improving productivity. Of course, the first Si substrate separated can be reused.

In other words, the present invention provides the Si single-crystal layer or the compound semiconductor single-crystal layer with the remarkably reduced number of imperfections on the insulator by using a Si single-crystal substrate in an economically desirable manner, which results in uniform flatness across a large area and excellent crystallinity, by removing the portion from its one surface to the active layer and leaving the Si or compound semiconductor active layer formed in the surface.

The present invention provides a fabrication process for a semiconductor substrate superior with respect to productivity, uniformity, controllability, and cost in obtaining the Si or compound semiconductor single-crystal layer with excellent crystallinity equivalent to that of a single-crystal wafer, on a transparent substrate (light transparent substrate).

Also, the present invention provides a fabrication process for a semiconductor substrate that can replace the expensive SOS or SIMOX for fabricating large-scale integrated circuits of the SOI structure.

The present invention can form a single-crystal compound semiconductor layer with good crystallinity on porous Si, can transfer the semiconductor layer onto an economically desirable and large-area insulating substrate, and can form the compound semiconductor layer with good crystallinity on the insulating substrate while restraining the differences in lattice constant and coefficient of thermal expansion, which were problems in the prior art.

Further, removal of the porous Si layer of the present invention can also be done by selective polishing, using the single-crystal layer as a polishing stopper because porous Si has low mechanical strength and enormous surface area.

The present invention may combine anodization with ion implantation to make the porosity of the side surface small and the porosity of the central part large, thereby making the volume expansion of the side surface greater and the strength of the central part low so as to facilitate peeling.

In the present invention, a layer of a material having a smaller coefficient of thermal expansion than that of Si is formed at least on one side of the outer surfaces of the bonding substrate before splitting by oxidation (or possibly before bonding), whereby at temperatures during oxidation, Si becomes more likely to expand and thus stress acts in the wafer peeling directions in the peripheral region of the bonding wafer, facilitating occurrence of the wedge effect by oxidation.

The present invention simultaneously solves the various problems discussed previously by the above-stated enhanced oxidation and volume expansion of porous layer effected uniformly from the periphery of wafer.

Uhlir et al. discovered porous Si during the research process on electrolytic polishing of semiconductor in 1956 (A. Uhlir, Bell Syst. Tech. J., vol. 35, 333 (1956)). Porous Si can be formed by anodizing an Si substrate in HF solution. Unagami et al. studied dissolution of Si in the anodization and reported that the anode reaction of Si in HF solution required holes and that the reaction was as follows (T. Unagami, J. Electrochem. Soc., vol. 127, 476 (1980)):

Si+2HF+(2−n)e⁺→SiF₂+2H⁺+ne⁻

SiF₂+2HF→SiF₄+H₂

SiF₄+2HF→H₂SiF₆

or

Si+4HF+(4−λ)e⁻→SiF₄+4H⁺+λe⁻

SiF₄+2HF→H₂SiF₆

Here, e⁺ and e⁻ represent a hole and an electron, respectively. Further, each of n and λ is the number of holes necessary for one atom of Si to dissolve, and it is reported that porous Si is formed when the condition of n>2 or λ>4 is satisfied.

From the foregoing, p-type Si including holes can be changed to porous Si, but n-type Si cannot. The selectivity in this porous Si formation was verified by Nagano et al. and Imai (Nagano, Nakajima, Anno, Onaka, and Kajiwara, technical research report, the Institute of Electronics, Information and Communication Engineers (IEICE), vol. 79, SSD 79-9549 (1979)) and (K. Imai, Solid-State Electronics, vol. 24, 159 (1981)).

There is, however, another report telling that heavily doped n-type Si can be changed to porous Si (R. P. Holmstrom and J. Y. Chi, Appl. Phys. Lett., vol. 42, 386 (1983)), and it is thus important to select a substrate that can realize porous Si formation without adhering to the difference between p-type and n-type.

Porous Si can be formed by anodization of the Si substrate in HF solution. The porous layer has a spongelike structure in which pores with diameters ranging approximately from 10⁻¹ to 10 nm are arranged at intervals of about 10⁻¹ to 10 nm. The density thereof can be changed in the range of 2.1 to 0.6 g/cm³ by changing the concentration of HF solution in the range of 50 to 20% or by changing the current density, in comparison with the density of single-crystal Si 2.33 g/cm³. Namely, the porosity can vary. Although the density of porous Si is below half that of single-crystal Si as described, it maintains the single crystal property and it is also possible to epitaxially grow a single-crystal Si layer on the porous layer. However, temperatures over 1000° C. cause rearrangement of internal pores, which will impair the characteristic of enhanced etching. Therefore, the epitaxial growth of a Si layer is preferably low temperature growth selected from molecular beam epitaxial growth, plasma enhanced CVD, low pressure CVD, photo assisted CVD, bias sputter process, liquid phase growth, and so on. However, high-temperature growth is also possible, if a protective film is preliminarily formed over the pore walls of the porous layer by a method of low-temperature oxidation or the like.

Since a lot of pores are formed inside the porous layer, the density of the porous layer decreases by half or more. As a result, the surface area significantly increases as compared with the volume, and thus its chemical etching rate is remarkably enhanced as compared with the etching rates of a normal single-crystal layer.

The mechanical strength of porous Si is lower than that of bulk Si, though it depends upon the porosity. For example, if the porosity is 50%, the mechanical strength can be considered to be half that of bulk. Namely, when compression, tension or shear force is exerted on the bonding wafer, the porous Si layer will be broken first. When porosity increases, the porous layer can be broken by weaker force.

It is reported that after ions of helium or hydrogen are implanted into bulk Si, followed by annealing, micro-cavities with diameters of several nm to several ten nm are formed in the density of even 10¹⁶⁻¹⁷/cm³ in the implant region (for example, A. Van Veen, C. C. Griffioen, and J. H. Evans, Mat. Res. Soc. Symp. Proc. 107 (1988, Material Res. Soc. Pittsburgh, Pa.) p. 449). Research was recently on utilization of the micro-cavities as gettering sites of metal impurities.

V. Raineri and S. U. Campisano implanted helium ions into bulk Si and annealed it to form the cavities. Thereafter, they formed a groove in the substrate to expose the side surface of the cavities and subjected it to oxidation. As a result, the cavities were selectively oxidized to form a buried, oxidized Si layer. Namely, they reported formation of the SOI structure thereby (V. Raineri, and S. U. Campisano, Appl. Phys. Lett. 66 (1995) p.3654). Their method, however, failed to form the SOI structure over the entire surface of substrate because the thicknesses of the surface Si layer and buried, oxidized Si layer are limited to those that can effect both the formation of cavities and relaxation of stress introduced due to volume expansion upon oxidation together and because formation of a groove is necessary for selective oxidation. Such formation of cavities has been reported as a phenomenon occurring with injection of a light element into metal, together with the swell and peeling phenomena of these cavities, as a part of research related to the first wall of a fusion reactor.

The second substrate may be selected, for example, from a Si substrate, a Si substrate with a oxidized Si film formed thereon, light transparent substrates such as a quartz substrate (silica glass) or a glass substrate, and metal substrates, but it is not limited particularly to these.

The thin film formed on the porous Si layer on the first substrate may be selected, for example, from metal thin films and carbon thin films as well as non-porous single-crystal Si and the compound semiconductors such as GaAs or InP, but it is not limited to these. Further, it is not essential that the thin film of these be formed over the entire surface, and it may be partially etched by a patterning process.

The bonding wafer of Si has advantages of being oxidized at high temperatures and simultaneously annealed at high temperatures for reduction of voids.

Embodiments of the present invention will be explained.

[Embodiment 14]

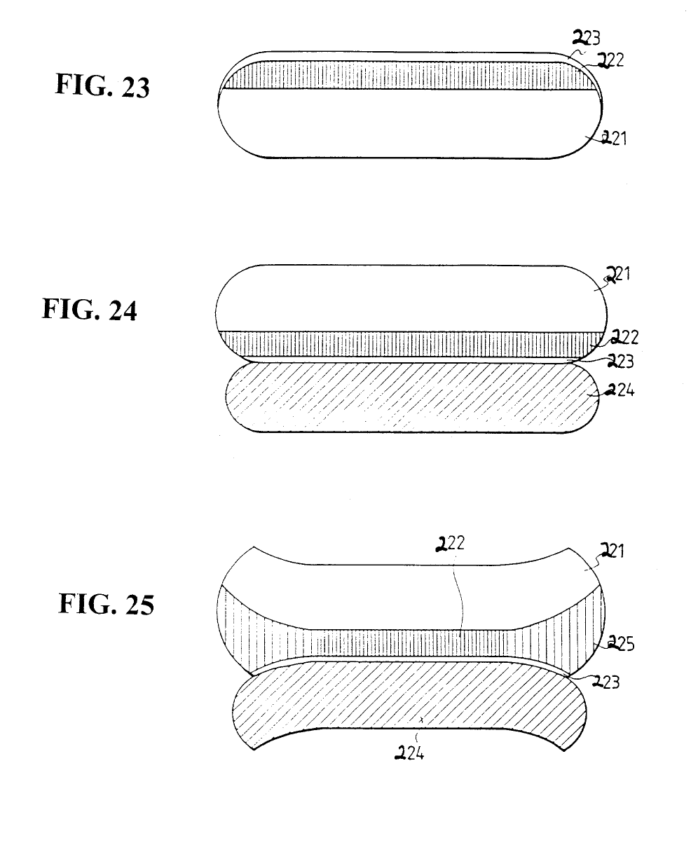

As shown in FIG. 23, a first Si single-crystal substrate 221 is first prepared and then at least one non-porous thin film 223 and a porous Si layer 222 immediately under it are formed over the outermost surface layer of the principal surface thereof. A procedure for fabricating the non-porous thin film 223 and porous Si layer 222 is either one selected from the following procedures:

a) forming the porous Si layer 222 by anodization and forming the non-porous thin film 223;

b) implanting ions of at least one element selected from rare gases, hydrogen, and nitrogen into the substrate to simultaneously form the porous Si layer 222 and the non-porous thin film 223; and

c) in addition to a), further implanting ions of at least one element selected from rare gases, hydrogen and nitrogen into the substrate to make another region with a different porosity.

The non-porous thin film 223 is arbitrarily selected from single-crystal Si, polycrystal Si, amorphous Si, or metal films, compound semiconductor thin films, superconductive thin films, and so on. Even the device structure of MOSFET or the like may be formed. Further, formation of SiO₂ as an outermost layer is preferred for the reason that the interface state of the bonding interface can be separated away from the active layer (though SiO₂ does not always have to be provided). Observation of the implant layer with a transmission electron microscope confirms that an infinite number of micro-cavities are formed. There are no specific limitations on the charge state of implant ions. The acceleration energy is so set that the projected range is coincident with the depth desired to implant. The size and density of micro-cavities formed vary depending upon an implant amount, but the density is approximately 1×10¹⁴/cm² or more, more preferably 1×10¹⁵/cm². If the projected range is desired to be set deeply, channeling ion implantation may be applied. After implantation, annealing is carried out as occasion demands. As shown in FIG. 24, the second substrate 224 is made in close contact with the surface of the first substrate at room temperature. After that, bonding may be enhanced by anodic bonding, pressing, or annealing if necessary, or a combination thereof.

If single-crystal Si is deposited, it is preferred to form oxidized Si by a method of thermal oxidation or the like over the surface of single-crystal Si and then to bond it to the second substrate. The second substrate may be selected from Si, a substrate obtained by forming an oxidized Si film on an Si substrate, light transparent substrates of quartz or the like, sapphire, and the like, but it is not limited to these. The point is that a surface thereof to be bonded is sufficiently flat.

The two substrates may be bonded in the three-plate laminate structure with an insulating thin plate therebetween.

A layer of a material having a smaller coefficient of thermal expansion than Si may be formed on at least one side of the outer surfaces of the bonding substrate before splitting by oxidation (or possibly before bonding). At temperatures during oxidation, Si becomes easier to expand and stress acts in the wafer peeling directions around the periphery of the bonding wafer, thereby supplementing the wedge effect by oxidation.

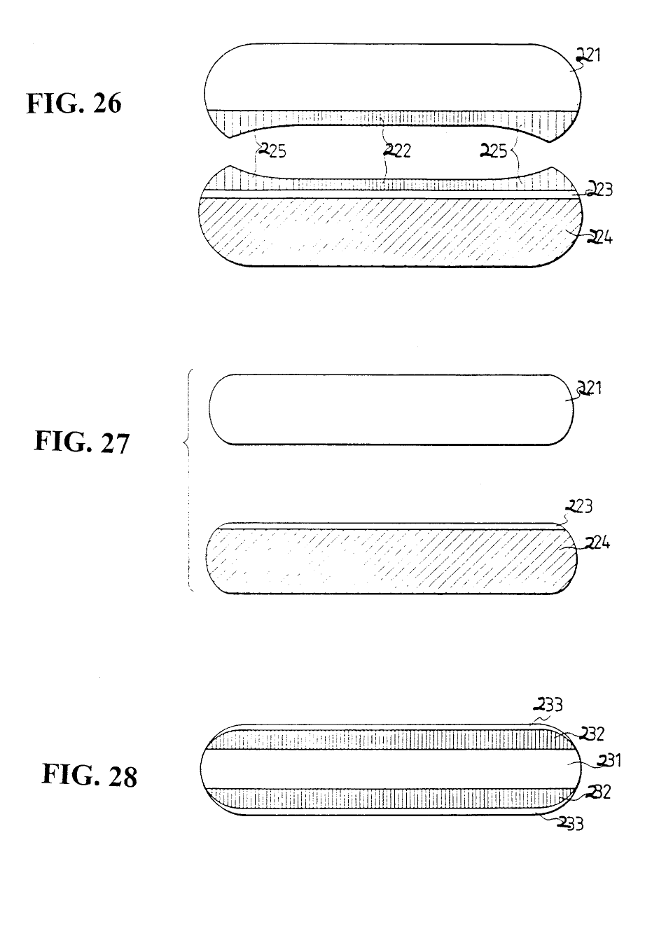

The side surface of the porous Si layer is made to be exposed by etching the non-porous thin film 223 after bonding, etching it before bonding, or preventing the non-porous thin film 223 from being formed on the side surface. The bonding substrate is oxidized to subject porous Si of the side surface to enhanced oxidation. (In the drawing, numeral 225 designates oxidized porous Si.) Then, as shown in FIG. 25, volume expansion of side-surface porous Si causes stress to act so as to peel the porous Si layer and, finally, to divide the substrate in the porous Si layer 222 (FIG. 26). The second substrate side has the structure of porous Si 222+oxidized porous Si 225/non-porous thin film (single-crystal Si layer, for example) 223/second substrate 224.

Further, the porous Si 222 and oxidized porous Si 225 is selectively removed. Oxidized porous Si 225 is etched with hydrofluoric acid solution. When the non-porous thin film is of single-crystal Si, only porous Si 222 is etched by electroless wet chemical etching with at least one etchant selected from ordinary Si etchants, hydrofluoric acid being an etchant for selective etching of porous Si, a mixture solution obtained by adding at least one of alcohol (ethyl alcohol, isopropyl alcohol, etc.) and hydrogen peroxide solution to hydrofluoric acid, buffered hydrofluoric acid, and a mixture solution obtained by adding at least one of alcohol and hydrogen peroxide to buffered hydrofluoric acid, thereby leaving the film preliminarily formed on the porous layer of the first substrate, on the second substrate. As detailed above, only porous Si can be selectively etched even with the ordinary Si etchant, because of the enormous surface area of porous Si. Alternatively, porous Si 222 is removed by selective polishing, using the non-porous thin film layer 223 as a polishing stopper.

When a compound semiconductor layer is formed on the porous layer, only porous Si 222 is chemically etched with an etchant having a faster etch rate of Si than that of the compound semiconductor, thereby leaving, and thus forming, the thinned single-crystal compound semiconductor layer 223 on the second substrate 224. Alternatively, porous Si 222 is removed by selective polishing, using the single-crystal compound semiconductor layer 223 as a polishing stopper.

FIG. 27 shows a semiconductor substrate obtained by the present invention. A non-porous thin film, for example, a single-crystal Si thin film 223, is formed, as thinned flatly and uniformly, in a large area throughout the entire region of wafer on the second substrate 224. If an insulating substrate is used as the second substrate 224, the semiconductor substrate thus obtained can be suitably used also from the viewpoint of fabrication of dielectric-isolated electronic devices.

The first Si single-crystal substrate 221 can be reused again as a first Si single-crystal substrate 221 or as a second substrate 224 after the residual porous Si and oxidized porous Si layer is removed and, if the surface thereof is too rough, after the surface thereof is flattened.

[Embodiment 15]

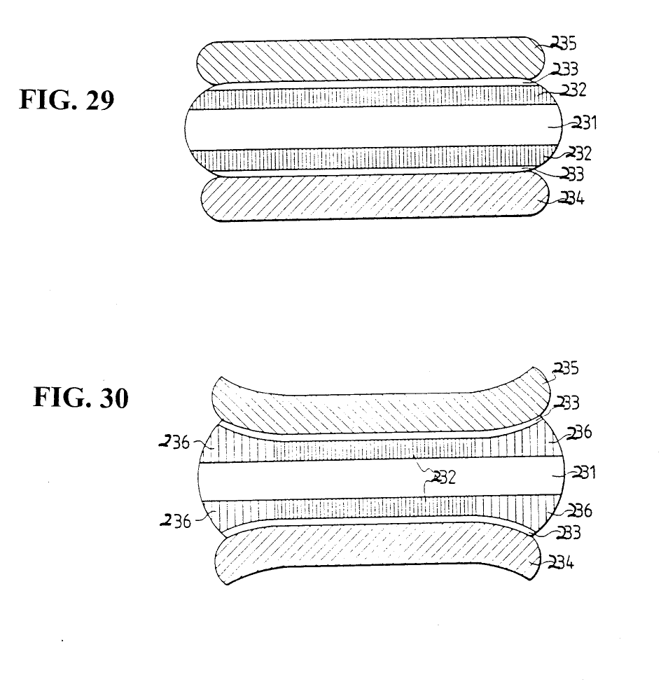

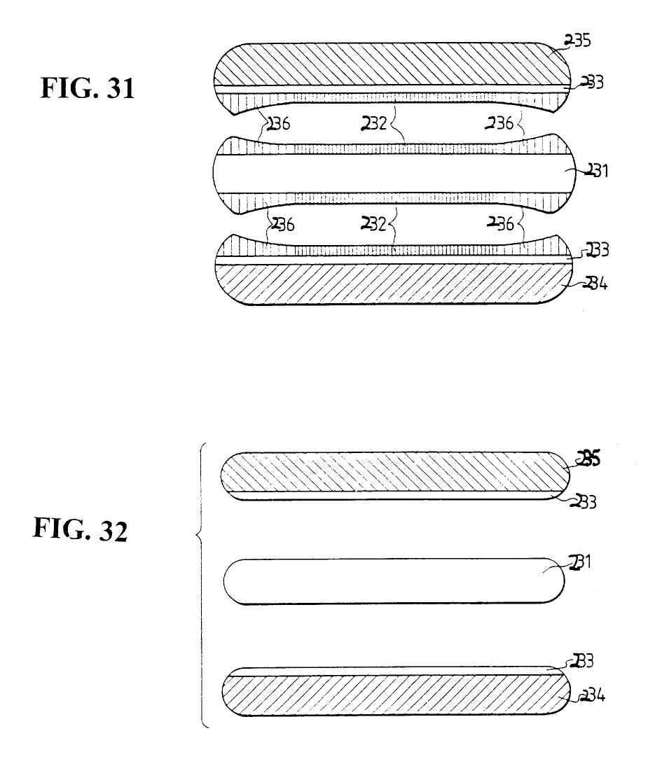

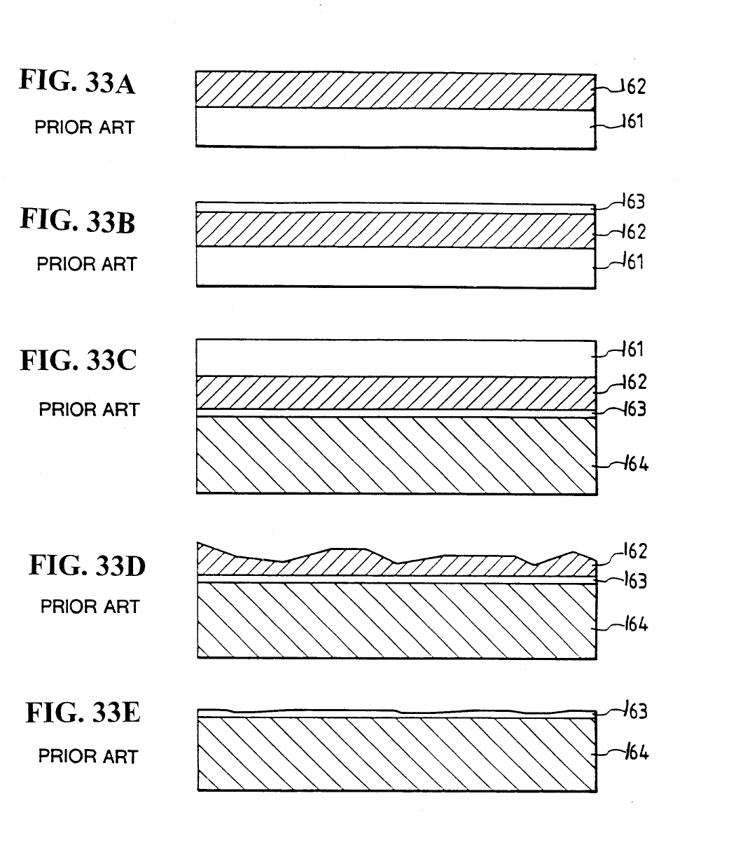

As shown in FIG. 28 to FIG. 32, the above step described in Embodiment 14 is applied to both surfaces of the first substrate with two second substrates, thereby fabricating two semiconductor substrates simultaneously.

In FIG. 28 to FIG. 32, reference numeral 231 designates a first Si single-crystal substrate; 232, porous Si layers provided on both principal surfaces of the first Si single-crystal substrate 231; 233, non-porous thin films provided on the porous Si layers 232; 234 and 235, second substrates; and 236, oxidized porous Si layers.

The first Si single-crystal substrate 231 can be reused again as a first Si single-crystal substrate 231 or as a second substrate 234 (or 235) after residual porous Si is removed or, if the surface is too rough, after the surface is flattened.

The support substrates 234, 235 do not have to be identical.

The non-porous thin-films 233 on both surfaces do not have to be identical.

### EXAMPLES

Examples of the present invention will be described.

### Example 27

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growing rate: | 0.3 μm/min |

Further, an SiO₂ layer of 100 nm was formed over the surface of this epitaxial Si layer by thermal oxidation.

The surface of this SiO₂ layer was laid on and made to contact a surface of a Si substrate (second substrate) with an SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in a mixture solution of 49% hydrofluoric acid and 30% hydrogen peroxide solution. Single-crystal Si remained without being etched, and with the single-crystal Si as a material of etch stop, the porous Si and oxidized porous Si layer were selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with an atomic force microscope and the root mean square roughness in a region 50 μm square was approximately 0.2 nm, which was equivalent to those of Si wafers commercially available.

Observation of cross section with a transmission electron microscope resulted in confirming that no new crystal defects were introduced into the Si layer and that good crystallinity was maintained.

The present example showed an example in which the oxide film was formed in the surface of the epitaxial Si layer and in which the oxide film was also formed in the surface of the second substrate (i.e., the oxide film was formed in both substrates), but the same results were attained in the cases wherein the oxide film was provided in either one substrate and wherein the oxide film was not provided in either substrate. However, as discussed previously, formation of the oxide film over the outermost layer of the epitaxial Si layer is preferable from the point that the interface state of the bonding interface is able to be separated away from the active layer.

In fact, it was also the case in the subsequent embodiments that the same results were attained in any cases wherein the oxide film was formed in both substrates, wherein the oxide film was formed in either one of the substrates, and wherein the oxide film was not formed in either substrate. Then, it is also the case that formation of the oxide film over the outermost layer of non-porous thin film (epitaxial Si layer) is preferable from the point that the interface state of the bonding interface can be separated away from the active layer.

### Example 28

Prepared was a p-type or n-type 6-inch-diameter first (100) single-crystal Si substrate having the thickness of 625 μm and the specific resistance of 0.01 Ω.cm, and a SiO₂ layer of 100 nm was formed over the surface thereof by thermal oxidation. Hydrogen ions were implanted in 1×10¹⁷/cm² into the principal surface with the acceleration voltage of 50 keV applied. This resulted in forming a porous structure in the depth of near 0.5 μm below the surface by hydrogen bubbles.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer were selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.5 μm on the Si oxide film. Film thicknesses of the single-crystal Si layer thus formed were measured at 100 points across the entire surface, and uniformity of film thickness was within 13%.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 29

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growing rate: | 0.3 μm/min |

Further, a SiO₂ layer of 100 nm was formed over the surface of this epitaxial Si layer by thermal oxidation.

Then hydrogen ions were implanted in 1×10¹⁶/cm² into the principal surface with the acceleration voltage of 180 keV applied.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly into two substrates at a position corresponding to the projected range of hydrogen ion implantation in the porous Si layer after one hour. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 30

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 3 (min) |
| Thickness of porous Si: | 3 (μm) |
| Porosity: | 15 (%) |

Further,

| Current density: | 30 (mA · cm⁻²) |
|---|---|
| Anodization solution: | HF:H₂O:C₂H₅OH = 1:1:1 |
| Time: | 3 (min) |
| Thickness of porous Si: | 10 (μm) |
| Porosity: | 45 (%) |

Further,

| Current density: | 7 (mA · cm⁻²) |
|---|---|
| Anodization solution: | HF:H₂O:C₂H₅OH = 1:1:1 |
| Time: | 3 (min) |
| Thickness of porous Si: | 3 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The portion with the higher porosity was structurally fragile, so that division started from that fragile portion. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 31

Prepared was a p-type or n-type 6-inch-diameter first (100) single-crystal Si substrate having the thickness of 625 μm and the specific resistance of 0.01 Ω.cm and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of this SiO₂ layer was laid on and made to contact a surface of a Si substrate (second substrate) with an SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new, crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 32

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

Hydrogen ions were implanted in 1×10¹⁶/cm² in a region of the principal surface except for the peripheral 10 mm of wafer with the acceleration voltage of 150 keV applied. This implantation of hydrogen ions can realize a low porosity for the peripheral portion and a high porosity for the central portion, whereby in the oxidation process, the volume expansion of the peripheral portion becomes greater. Therefore, the central portion becomes weaker in strength and is thus easy to peel.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly into two substrates at a position corresponding to the projected range of hydrogen ion implantation in the porous Si layer after 0.7 hour. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 33

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of this SiO₂ layer was laid on and made to contact a surface of a Si substrate (second substrate) with a SiO₂ layer of 500 nm formed thereover, separately prepared, after they were exposed to an oxygen plasma. After contact of the surfaces, the SiO₂ layer of 100 nm and the epitaxial Si layer were removed by etching on the side surface of the bonding wafer, which exposed the edge of porous Si. The oxygen plasma process can enhance the bonding strength, and if they are further heated at 300° C. for about one hour after being exposed to the oxygen plasma, superimposed on each other, and contacted with each other, the bonding strength becomes much higher.

The bonding wafer was pyro-oxidized at 1100° C., and it was divided perfectly in the porous Si layer into two substrates after 0.7 hour. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 34

Prepared was a p-type or n-type 6-inch-diameter first (100) single-crystal Si substrate having the thickness of 625 μm and the specific resistance of 10 Ω.cm, and an SiO₂ layer of 100 nm was formed over the surface thereof by thermal oxidation. Hydrogen ions were implanted in 1×10¹⁷/cm² into the principal surface with the acceleration voltage of 25 keV applied. This resulted in forming a porous structure in the depth of near 0.3 μm below the surface by hydrogen bubbles.

The surface of this SiO₂ layer was laid on and made to contact a surface of a Si substrate (second substrate) with a SiO₂ layer of 500 nm formed thereover, separately prepared, after they were exposed to a nitrogen plasma. After contact of the surfaces, the SiO₂ layer of 100 nm and the Si layer were removed by etching on the side surface of the bonding wafer, which exposed the edge of porous Si. The nitrogen plasma process can enhance the bonding strength, and if they are further heated at 300° C. for about one hour after being exposed to the nitrogen plasma, superimposed on each other, and contacted with each other, the bonding strength becomes much higher.

The bonding wafer was dry-oxidized at 1100° C., and it was divided perfectly in the porous Si layer into two substrates after two hours. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.2 μm on the Si oxide film. Film thicknesses of the single-crystal Si layer thus formed were measured at 100 points across the entire surface, and uniformity of film thickness was within ±3%.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 35

Prepared was a p-type or n-type 6-inch-diameter first (100) single-crystal Si substrate having the thickness of 625 μm and the specific resistance of 0.01 Ω.cm and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

Hydrogen ions were implanted in 5×10¹⁶/cm² into the principal surface with the acceleration voltage of 180 keV applied.

Then the SiO₂ layer of 100 nm and the epitaxial Si layer in the side surface were removed to expose the porous Si layer.

The surface of this SiO₂ layer was laid on and made to contact a surface of a Si substrate (second substrate) with a SiO₂ layer of 500 nm formed thereover, separately prepared, after they were exposed to a nitrogen plasma. The nitrogen plasma process can enhance the bonding strength, and if they are further heated at 300° C. for about one hour after being exposed to the nitrogen plasma, superimposed on each other, and contacted with each other, the bonding strength becomes much higher.

The bonding wafer was pyro-oxidized at 900° C., and it was divided perfectly into two substrates at a position corresponding to the projected range of hydrogen ion implantation in the porous Si layer after two hours. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 36

Prepared was a p-type or n-type 6-inch-diameter first (100) single-crystal Si substrate having the thickness of 625 μm and the specific resistance of 0.01 Ω.cm, and it was subjected to both-face anodization in HF solution. The conditions for the anodization were as follows. The both-face anodization was carried out face by face for 11 minutes each.

| Current density: | 7 (mA · cm⁻²) |
|---|---|
| Anodization solution: | HF:H₂O:C₂H₅OH = 1:1:1 |
| Time: | 11 × 2 (min) |
| Thickness of porous Si: | 12 (μm) |
| Porosity: | 15 (%) |

This substrate was oxidized at 400° C. in an oxygen ambient for one hour. This oxidation caused a thermally oxidized film to cover the internal walls of pores of porous Si. Single-crystal Si was epitaxially grown in the thickness of 0.15 μm on each porous Si layer by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of each epitaxial Si layer by thermal oxidation.

The surfaces of the SiO₂ layers were laid on and made to contact respective surfaces of two Si substrates (second substrates) with a SiO₂ layer of 500 nm formed thereover, separately prepared. After contact of the surfaces, the SiO₂ layers of 100 nm and the epitaxial Si layers were removed by etching on the side surface of the bonding wafer, which exposed the edge of porous Si.

The bonding wafer was pyro-oxidized at 1000° C., and it was divided perfectly in the porous Si layers into three substrates after one hour. The separated surfaces were observed, showing that the central portion was found to remain almost in its original state while porous Si of the wafer side surface was changed to SiO₂.

After that, the porous Si and oxidized porous Si layers left on the side of the two second substrates were subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layers were selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, two of the single-crystal Si layer were formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 37

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

Hydrogen ions were implanted in 1×10¹⁶/cm² into the principal surface with the acceleration voltage of 180 keV applied.

The surface of the SiO₂ layer was laid on and made to contact a surface of a quartz substrate (second substrate) prepared separately, after each surface was proposed to a nitrogen plasma. After contact of the surfaces, the SiO₂ layer of 100 nm and the epitaxial Si layer were removed by etching on the side surface of the bonding wafer, which exposed the edge of porous Si. The nitrogen plasma process can enhance the bonding strength, and if they are further heated at 300° C. for about one hour after exposed to the nitrogen plasma, superimposed on each other, and contacted with each other, the bonding strength becomes much higher.

The bonding wafer was low-temperature-oxidized at 700° C., and it was divided perfectly into two substrates at a position corresponding to the projected range of hydrogen ion implantation in the porous Si layer after ten hours. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was practically ignorable (about several ten angstroms).

Namely, the single-crystal Si layer was formed in the thickness of 0.1 μm on the Si oxide film on the quartz substrate. Film thicknesses of the single-crystal Si layer thus formed were measured at 100 points across the entire surface, and uniformity of film thickness was 101 nm±3 nm.

Observation of cross section with the transmission electron microscope resulted in confirming that no new crystal defects were introduced into the Si layer and that good crystallinity was maintained.

The same results were obtained without forming the oxide film on the surface of the epitaxial Si layer.

The same results were obtained with low-melting point glass.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 38

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen ambient for one hour. This oxidation caused a thermally oxidized film to cover the internal walls of pores of porous Si. Single-crystal Si was epitaxially grown in the thickness of 1.05 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to

After that, the porous Si and oxidized porous Si layer left on the second substrate side was subjected to selective polishing with single-crystal Si as a polishing stopper. Single-crystal Si was left without being polished, and with the single-crystal Si as a material of polishing stop, the porous Si and oxidized porous Si layer was selectively polished to be removed perfectly.

Namely, the single-crystal Si layer was formed in the thickness of 1 μm on the Si oxide film. Film thicknesses of the single-crystal Si layer thus formed were measured at 100 points across the entire surface, and uniformity of film thickness was ±3%.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 39

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal GaAs was epitaxially grown in the thickness of 1 μm on porous Si by the MOCVD (Metal Organic Chemical Vapor Deposition) process. The growth conditions were as follows:

| | |
|---|---|
| Source gas: | TMG/AsH₃/H₂ |
| Gas pressure: | 80 Torr |
| Temperature: | 700° C. |

The surface of the GaAs layer was laid on and made to contact a surface of a Si substrate (second substrate) prepared separately and thereafter the epitaxial layer on the side surface of the bonding wafer was removed by etching, thereby exposing the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer left on the second substrate side was subjected to etching with ethylenediamine+pyrocatechol+water (at a ratio of 17 ml:3 g:8 ml) at 110° C., after removing oxidized Si with HF. Single-crystal GaAs was left without being etched, and with the single-crystal GaAs as a material of etch stop the porous Si and oxidized porous Si layer was selectively etched to be removed completely.

The etch rate of non-porous GaAs single crystal by the etchant was extremely low and the selectivity of the etch rate of the porous layer thereto was even 10⁵ or more. Therefore, a decrease in film thickness of the non-porous layer was so small that the etch amount thereof was practically ignorable (about several ten angstroms).

Namely, the single-crystal GaAs layer was formed in the thickness of 1 μm on Si.

Observation of cross section with the transmission electron microscope resulted in confirming that no new crystal defects were introduced into the GaAs layer and that good crystallinity was maintained.

Using an Si substrate with an oxide film as a support substrate, GaAs on the insulating film was also able to be fabricated in the same manner.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 40

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal AlGaAs was epitaxially grown in the thickness of 0.5 μm on porous Si by the MBE (Molecular Beam Epitaxy) process.

The surface of the AlGaAs layer was laid on and made to contact a surface of a glass substrate (second substrate) prepared separately and thereafter the epitaxial layer on the side surface of the bonding wafer was removed by etching, thereby exposing the edge of porous Si.

The bonding wafer was low-temperature-oxidized at 700° C., and it was divided perfectly in the porous Si layer into two substrates after ten hours. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal AlGaAs remained without being etched, and with the single-crystal AlGaAs as a material of etch stop, the porous Si and oxidized porous Si layer was selectively etched to be removed completely.

The etch rate of non-porous AlGaAs single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal AlGaAs layer having the thickness of 0.5 μm was formed on the glass substrate.

Observation of cross section with the transmission electron microscope resulted in confirming that no new crystal defects were introduced into the AlGaAs layer and that good crystallinity was maintained.

After removing the residual porous Si and oxidized porous Si layer, the surface of the first Si single-crystal substrate was polished into a mirror surface and thereafter the first substrate was again used as a first Si single-crystal substrate.

### Example 41

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of the SiO₂ layer was laid on and made to contact a surface of a Si substrate (second substrate) with a SiO₂ layer of 500 nm formed thereover, prepared separately.

Si₃N₄ was deposited in the thickness of 0.5 μm at a low temperature on both outer surfaces of the bonding wafer and thereafter the Si₃N₄ layer of 0.5 μm and the SiO₂ layer of 100 nm and the epitaxial Si layer on the side surface of the bonding wafer were removed by etching, thereby exposing the edge of porous Si. When Si₃N₄ is formed in this manner, because Si is easier to expand than Si₃N₄, stress acts in the wafer peeling directions in the peripheral region of wafer, which facilitates occurrence of the wedge effect by oxidation.

The bonding wafer was pyro-oxidized at 1000° C., and it was divided perfectly in the porous Si layer into two substrates after 0.8 hour. The separated surfaces were observed, showing that the central portion was found to remain almost in its original state while porous Si of the wafer side surface was changed to SiO₂. The Si₃N₄ layer on the back surface may or may not be removed.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with an atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. Thus, the first substrate of single-crystal Si was able to be put again into the porous layer forming step.

### Example 42

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. After being polished, the first substrate was able to be put into the process as a second substrate this time.

### Example 43

Prepared was a p-type or n-type 6-inch-diameter first (100) single-crystal Si substrate having the thickness of 625 μm and the specific resistance of 0.01 Ω.cm, and it was subjected to both-face anodization in HF solution. The conditions for the anodization were as follows. The both-face anodization was carried out face by face for 11 minutes each.

| Current density: | 7 (mA · cm⁻²) |
|---|---|
| Anodization solution: | HF:H₂O:C₂H₅OH = 1:1:1 |
| Time: | 11 × 2 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on each porous Si layer by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of each epitaxial Si layer by thermal oxidation.

The surfaces of the SiO₂ layers were laid on and made to contact respective surfaces of two Si substrates (second substrates) with a SiO₂ layer of 500 nm formed thereover, separately prepared. After contact of the surfaces, the SiO₂ layers of 100 nm and the epitaxial Si layers were removed by etching on the side surface of the bonding wafer, which exposed the edge of porous Si.

The bonding wafer was pyro-oxidized at 1000° C., and it was divided perfectly in the porous Si layers into three substrates after one hour. The separated surfaces were observed, showing that the central portion was found to remain almost in its original state while porous Si of the wafer side surface was changed to

After that, the porous Si and oxidized porous Si layers left on the side of the two second substrates were subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layers were selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

At the same time, the porous Si and oxidized porous Si layer left on the first substrate side was also subjected thereafter to selective etching with agitation in the mixture solution of 49% hydrofluoric acid and 30% hydrogen peroxide solution. Single-crystal Si was left without being etched, and with the single-crystal Si as a material of etch stop, the porous Si and oxidized porous Si layer was selectively etched to be removed completely. After being polished, the first substrate was able to be put into the process as one of the second substrates this time.

### Example 44

Prepared was a p-type or n-type 6-inch-diameter first (100) single-crystal Si substrate having the thickness of 625 μm and the specific resistance of 10 Ω.cm, and an SiO₂ layer of 100 nm was formed over the surface thereof by thermal oxidation. Helium ions were implanted in 1×10¹¹/cm² into the principal surface with the acceleration voltage of 100 keV applied. This resulted in forming a porous structure in the depth of near 0.5 μm below the surface by helium bubbles.

The surface of this SiO₂ layer was laid on and made to contact a surface of a Si substrate (second substrate) with a SiO₂ layer of 500 nm formed thereover, separately prepared. After contact of the surfaces, the SiO₂ layer of 100 nm and the epitaxial Si layer were removed by etching on the side surface of the bonding wafer, which exposed the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.5 μm on the Si oxide film. Film thicknesses of the single-crystal Si layer thus formed were measured at 100 points across the entire surface, and uniformity of film thickness was within ±3%.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 45

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of the SiO₂ layer was laid on and made to contact a surface of a Si substrate (second substrate) with a SiO₂ layer of 500 nm formed thereover, prepared separately, and thereafter a pulse voltage of ±500 V and cycles of 100 msec was applied thereto to enhance the bonding strength more. Further, the SiO₂ layer of 100 nm and the epitaxial Si layer on the side surface of the bonding wafer were removed by etching, thereby exposing the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

### Example 46

Prepared was a p-type or n-type 6-inch-diameter first (100) single-crystal Si substrate having the thickness of 625 μm and the specific resistance of 0.01 Ω.cm, and it was subjected to anodization in HF solution. The conditions for the anodization were as follows:

| Current density: | 7 (mA · cm⁻²) |
|---|---|
| Anodization solution: | HF:H₂O:C₂H₅OH = 1:1:1 |
| Time: | 11 (min) |
| Thickness of porous Si: | 12 (μm) |
| Porosity: | 15 (%) |

This substrate was oxidized at 400° C. in an oxygen atmosphere for one hour. This oxidation caused a thermally oxidized film to cover the internal walls of pores of porous Si. Single-crystal Si was epitaxially grown in the thickness of 0.15 μm on porous Si by the CVD (Chemical Vapor Deposition) process. The growth conditions were as follows:

| | |
|---|---|
| Source gas: | SiH₂Cl₂/H₂ |
| Gas flow rate: | 0.5/180 l/min |
| Gas pressure: | 80 Torr |
| Temperature: | 950° C. |
| Growth rate: | 0.3 μm/min |

Further, a SiO₂ layer of 100 nm was formed over the surface of this epitaxial Si layer by thermal oxidation.

The surface of the SiO₂ layer was laid on and made to contact a surface of a Si substrate (second substrate) with a SiO₂ layer of 500 nm formed thereover, prepared separately, and thereafter a pressure of 1000 kg/cm² was applied thereto at room temperature perpendicularly to the bonding substrate to enhance the bonding strength more. Further, the SiO₂ layer of 100 nm and the epitaxial Si layer on the side surface of the bonding wafer were removed by etching, thereby exposing the edge of porous Si.

The bonding wafer was pyro-oxidized at 1000° C., and it was divided perfectly in the porous Si layer into two substrates after one hour. The separated surfaces were observed, showing that the central portion was found to remain almost in its original state while porous Si of the wafer side surface was changed to SiO₂.

After that, the porous Si and oxidized porous Si layer remaining on the second substrate side was subjected to selective etching with agitation in the mixture solution of 49% hydrofluoric acid and 30% hydrogen peroxide solution. Single-crystal Si remained without being etched, and with the single-crystal Si as a material of etch stop, the porous Si and oxidized porous Si layer was selectively etched to be removed completely.

The etch rate of non-porous Si single crystal by the etchant was extremely low and the selectivity of the etch rate of the porous layer thereto was even 10⁵ or more. Therefore, a decrease in film thickness of the non-porous layer was so small that the etch amount thereof was negligible (about several ten angstroms).

Namely, the single-crystal Si layer was formed in the thickness of 0.1 μm on the Si oxide film. Film thicknesses of the single-crystal Si layer thus formed were measured at 100 points across the entire surface, and uniformity of film thickness was 101 nm±3 nm.

Further, it was annealed at 1100° C. in hydrogen for one hour. Surface roughness was evaluated with the atomic force microscope and the root mean square roughness in a region 50 μm square was approximately 0.2 nm, which was equivalent to those of Si wafers commercially available.

Observation of cross section with the transmission electron microscope resulted in confirming that no new crystal defects were introduced into the Si layer and that good crystallinity was maintained.

In each of the examples described above, the epitaxial growth on porous Si can be carried out by various methods including the MBE process, the sputter process, the liquid phase growth process, etc. as well as the CVD process without having to be limited to the CVD process. Additionally, the selective etching solution of porous Si is not limited to the mixture solution of 49% hydrofluoric acid and 30% hydrogen peroxide, but may be a mixture solution of hydrofluoric acid and alcohol (ethyl alcohol, isopropyl alcohol, etc.), a mixture solution of buffered hydrofluoric acid and hydrogen peroxide, or a mixture solution of buffered hydrofluoric acid and alcohol. Further, porous Si can also be selectively etched with a mixture solution of hydrofluoric acid, nitric acid, and acetic acid because of its enormous surface area. Mixture ratios of the mixture solutions may be set arbitrarily and properly.

The other steps can also be carried out under various conditions without having to be limited to the conditions described in the above examples.

What is claimed is:

1. A process for producing a semiconductor substrate comprising steps of:
forming a nonporous monocrystalline semiconductor layer on a porous layer of a first substrate having the porous layer;
bonding the nonporous monocrystalline layer onto a second substrate;
separating the bonded substrates at the porous layer;
removing the porous layer on the second substrate; and
removing the porous layer constituting the first substrate.

2. A process for producing a semiconductor substrate, comprising steps of:
forming a nonporous monocrystalline semiconductor layer on a porous layer of a first substrate having the porous layer;
bonding the nonporous monocrystalline layer onto a second substrate with interposition of an insulative layer;
separating the bonded substrates at the porous layer;
removing the porous layer on the second substrate; and
removing the porous layer constituting the first substrate.

3. The process according to claim 1 or 2, wherein the porous layer is formed from silicon.

4. The process according to claim 1 or 2, wherein on the separated first substrate, after removal of the porous layer therefrom, a new porous layer is formed, and is employed repeatedly as the first substrate in the forming step of the nonporous monocrystalline semiconductor layer and subsequent steps.

5. The process according to claim 1 or 2, wherein the nonporous crystalline semiconductor layer is an Si layer.

6. The process according to claim 1 or 2, wherein the nonporous crystalline semiconductor layer is a compound semiconductor layer.

7. The process according to claim 1 or 2, wherein the first substrate is constituted from Si.

8. The process according to claim 1 or 2, wherein the second substrate is light-transmissive.

9. The process according to claim 1 or 2, wherein the step of removing the porous layer is conducted by etching.

10. The process according to claim 1 or 2, wherein the step of removing the porous layer is conducted by selective grinding of the porous layer by employing the nonporous monocrystalline semiconductor layer as a stopper.

11. The process according to claim 1 or 2, wherein the step of separating the bonded substrates at the porous layer is conducted by at least one of methods of application of a compression force to the substrate in a direction perpendicular to the bonding face of the substrate, application of a pulling force to the substrate in a direction perpendicular to the bonding face of the substrate, and application of a shear stress to the bonding face.

12. The process according to claim 2, wherein the insulative layer is formed on at least one of the nonporous monocrystalline layer and the surface of the second substrate.

13. The process according to claim 12, wherein the insulative layer is selected from thermal oxidation films, deposited SiO₂ films, and deposited Si₃N₄ films.

14. The process according to claim 1 or 2, wherein the step of bonding is conducted one or combination of anode coupling, compression, and heat treatment.

15. The process according to claim 1 or 2, wherein the porous layer is formed by anodization.

16. The process according to claim 1 or 2, wherein the anodization is conducted in an HF solution.

17. The process according to claim 1 or 2, wherein the step of separating the substrates at the porous layer is conducted by application of a wave energy.

18. The process according to claim 1 or 2, wherein the step of separating the substrates at the porous layer is conducted by inserting a separation member from an edge face of the porous layer thereinto.

19. The process according to claim 1 or 2, wherein the step of separating the substrates at the porous layer is conducted by expansion energy of a material impregnated into the porous layer.

20. The process according to claim 1 or 2, wherein the step of separating the substrates at the porous layer is conducted by selective etching at the edge face of the wafer.

21. The process according to claim 1 or 2, wherein the porosity of the porous layer ranges from 10 to 80%.

22. A semiconductor substrate producing method comprising:
a porous-forming step for forming a porous Si layer on at least a surface of an Si substrate; and
a large porosity layer forming step for forming large porosity layer at a constant depth from a surface of said porous Si in said porous Si layer.

23. The semiconductor substrate producing method according to claim 22, wherein said large porosity layer forming step has an ion implanting step for implanting ions into said porous Si layer with a given projection range.

24. The semiconductor substrate producing method according to claim 23, further comprising a non-porous layer forming step for forming a non-porous layer on a surface of said porous layer before said ion implanting step.

25. The semiconductor substrate producing method according to claim 23, wherein said ions comprises at least one kind of noble gas, hydrogen and nitrogen.

26. The semiconductor substrate producing method according to claim 24, further comprising a bonding step for bonding said non-porous layer and a support substrate together; and a separating step for separating said Si substrate into two at said large porosity layer.

27. The semiconductor substrate producing method according to claim 26, wherein said separating step is performed by heat-treating said Si substrate.

28. The semiconductor substrate producing method according to claim 26, wherein said separating step is performed by pressurizing said Si substrate in a direction perpendicular to a surface thereof.

29. The semiconductor substrate producing method according to claim 26, wherein said separating step is performed by drawing said Si substrate in a direction perpendicular to a surface thereof.

30. The semiconductor substrate producing method according to claim 26, wherein said separating step is performed by applying a shearing force to said Si substrate.

31. The semiconductor substrate producing method according to claim 24, wherein said non-porous layer is made of single-crystal Si.

32. The semiconductor substrate producing method according to claim 24, wherein said non-porous layer is made of single-crystal Si having an oxidized Si layer on a surface to be bonded.

33. The semiconductor substrate producing method according to claim 24, wherein said non-porous layer is made of a single-crystal compound semiconductor.

34. The semiconductor substrate producing method according to claim 26, wherein said support substrate is an Si substrate.

35. The semiconductor substrate producing method according to claim 26, wherein said support substrate is an Si substrate having an oxidized Si layer on a surface to be bonded.

36. The semiconductor substrate producing method according to claim 26, wherein said support substrate is a light transmittable substrate

37. The semiconductor substrate producing method according to claim 26, wherein said bonding step is performed by anode bonding, pressurization, heat treatment or a combination thereof.

38. The semiconductor substrate producing method according to claim 26, further comprising a porous Si removing step, after said separating step, for removing the porous Si layer exposed on a surface of said support substrate and exposing said non-porous layer.

39. The semiconductor substrate producing method according to claim 38, wherein said porous Si removing step is performed by an electroless wet etching using at least one of hydrofluoric acid, a mixed liquid obtained by adding at least one of alcohol and hydrogen peroxide water to hydrofluoric acid, buffered hydrofluoric acid, and a mixed liquid obtained by adding at least one of alcohol and hydrogen peroxide water to buffered hydrofluoric acid.

40. The semiconductor substrate producing method according to claim 38, further comprising a flattening step for flattening a surface of said non-porous layer after said porous Si removing step.

41. The semiconductor substrate producing method according to claim 40, wherein said flattening step is performed by heat treatment in the atmosphere including hydrogen.

42. The semiconductor substrate producing method according to claim 26, wherein said porous-forming step forms porous Si layers on both sides of said Si substrate, and said bonding step bonds two support substrates to said porous Si layer formed on both sides of said Si substrate.

43. The semiconductor substrate producing method according to claim 26, further comprising a second non-porous layer forming step, after said separating step, for forming non-porous layer again on the surface of said porous Si layer, and a second ion implanting step, after said second non-porous layer forming step, for implanting ions into said porous Si layer with a given projection range and forming large porosity layer in said porous Si layer.

44. The semiconductor substrate producing method according to claim 22, wherein said porous-forming step is performed by anodization.

45. The semiconductor substrate producing method according to claim 44, wherein said anodization is performed in an HF solution or a mixture of an HF solution and alcohol.

46. The semiconductor substrate producing method according to claim 22, wherein said large porosity layer forming step is performed by changing a current density of anodization in said porous-forming step.

47. A semiconductor substrate comprising:
a porous Si layer formed at a surface layer of an Si substrate; and
a large porosity layer formed in said porous Si layer wherein said large porosity layer exists in a region located at a constant depth from a surface of said porous Si layer.

48. The semiconductor substrate according to claim 47, wherein non-porous si layer exists on surface of said porous si layer, and electrodes are formed on surface of said non-porous Si layer and on surface of said Si substrate, in order that said semiconductor substrate becomes an EL element.

49. A fabrication process of semiconductor substrate comprising:
a step of bonding a principal surface of a first substrate to a principal surface of a second substrate, said first substrate being an Si substrate in which at least one layer of non-porous thin film is formed through a porous Si layer;
a step of exposing said porous Si layer in a side surface of a bonding substrate comprised of said first substrate and said second substrate;
a step of dividing said bonding substrate in said porous Si layer by oxidizing said bonding substrate; and
a step of removing a porous Si and oxidized porous Si layer on said second substrate separated by the division of said bonding substrate in said porous Si layer.

50. A fabrication process of semiconductor substrate comprising:
a step of bonding a principal surface of a first substrate to a principal surface of a second substrate, said first substrate being an Si substrate in which at least one layer of non-porous thin film is formed through a porous Si layer and in which said porous Si layer is exposed in a side surface thereof;
a step of dividing said bonding substrate in said porous Si layer by oxidizing a bonding substrate comprised of said first substrate and said second substrate; and
a step of removing a porous Si and oxidized porous Si layer on said second substrate separated by the division of said bonding substrate in said porous Si layer.

51. The fabrication process of semiconductor substrate according to claim 49 or claim 50, wherein after removing the porous Si and oxidized porous Si layer on the first substrate separated by said division of the porous Si layer, the first substrate is again used as a raw material for said first substrate before bonding.

52. The fabrication process of semiconductor substrate according to claim 49 or claim 50, wherein after removing the porous Si and oxidized porous Si layer on the first substrate separated by said division of the porous Si layer, the first substrate is again used as a raw material for said second substrate before bonding.

53. The fabrication process of semiconductor substrate according to claim 49 or 50, wherein at least one layer of non-porous thin film is formed through a porous Si layer on each of two principal surfaces of said first substrate and said second substrate is bonded to each of said two principal surfaces.

54. The fabrication process of semiconductor substrate according to claim 49 or 50 wherein said non-porous thin film is a single-crystal Si layer.

55. The fabrication process of semiconductor substrate according to claim 49 or 50, wherein said non-porous thin film comprises an oxidized Si layer and a single-crystal Si layer.

56. The fabrication process of semiconductor substrate according to claim 49 or 50, wherein s aid non-porous thin film is a single-crystal compound semiconductor layer.

57. The fabrication process of semiconductor substrate according to claim 49 or 50, wherein said second substrate is an Si substrate.

58. The fabrication process of semiconductor substrate according to claim 49 or 50, wherein said second substrate is an Si substrate in which an oxidized Si film is formed at least on a principal surface to be bonded.

59. The fabrication process of semiconductor substrate according to claim 49 or 50, wherein said second substrate is a light transparent substrate.

60. The fabrication process of semiconductor substrate according to claim 53, wherein said second substrates respectively bonded to the two principal surfaces of said first substrate are those selected from Si substrate, Si substrate with an oxidized Si film formed at least on a principal surface to be bonded, and light transparent substrate.

61. The fabrication process of semiconductor substrate according to claim 60, wherein the second substrate bonded to one principal surface of said first substrate and the second substrate bonded to the other principal surface thereof are made of respective materials different from each other.

62. The fabrication process of semiconductor substrate according to claim 49 or 50, wherein a surface flattening process in a direction spreaded with the principal surface of the second substrate is carried out after removing said porous Si and oxidized porous Si layer.

63. The fabrication process of semiconductor substrate according to claim 62, wherein said surface flattening process is annealing in an ambient containing hydrogen.

64. The fabrication process of semiconductor substrate according to claim 49 or 50, wherein removal of said porous Si and oxidized porous Si layer is selectively carried out by soak in either one of hydrofluoric acid, a mixture solution in which at least one of alcohol and hydrogen peroxide solution is added to hydrofluoric acid, buffered hydrofluoric acid, and a mixture solution in which at least one of alcohol and hydrogen peroxide solution is added to buffered hydrofluoric acid.

65. The fabrication process of semiconductor substrate according to claim 56, wherein removal of said porous Si and oxidized porous Si layer is carried out by selective chemical etching of porous Si with an etchant having a faster etch rate of porous Si against a compound semiconductor.

66. The fabrication process of semiconductor substrate according to claim 49 or 50, wherein removal of said porous Si and oxidized porous Si layer is carried out by polishing the layer, using said non-porous thin film as a stopper.

67. The fabrication process of semiconductor substrate according to claim 49 or 50, wherein bonding of said first substrate to said second substrate is making the substrates into close contact with each other.

68. The fabrication process of semiconductor substrate according to claim 49 or 50, wherein bonding of said first substrate to said second substrate is carried out by a method selected from anodic bonding, pressing, annealing, and combinations thereof.

69. The fabrication process of semiconductor substrate according to claim 49 or 50, wherein formation of the non-porous thin film on the porous Si layer is carried out by performing anodization of an Si substrate to form porous Si and thereafter forming a non-porous thin film on said porous Si.

70. The fabrication process of semiconductor substrate according to claim 49 or 50, wherein formation of the non-porous thin film on the porous Si layer is carried out by implanting ions of at least one element of rare gases, hydrogen, and nitrogen into an Si substrate to form a porous layer in a certain depth from a surface thereof.

71. The fabrication process of semiconductor substrate according to claim 49 or 50, wherein formation of the non-porous thin film on the porous Si layer is carried out by anodizing an Si substrate to form a porous Si layer, thereafter forming a non-porous thin film on said porous Si layer, and then implanting ions of at least one element of rare gases, hydrogen, and nitrogen through the non-porous thin film into said porous Si layer so as to have a projected range thereof in said porous Si layer.

72. The fabrication process of semiconductor substrate according to claim 69, wherein said anodization is carried out in an HF solution.

73. The fabrication process of semiconductor substrate according to claim 49 or 50, wherein prior to the oxidation of said bonding substrate, a layer of a material having a smaller coefficient of thermal expansion than Si is formed on at least one of outer surfaces of said bonding substrate.
